(19) United States
(12) Patent Application Publication
(10) Pub. No.: US 2012/0164573 A1
(43) Pub. Date: Jun. 28, 2012

(54) ACTINIC-RAY-SENSITIVE OR RADIATION-SENSITIVE RESIN COMPOSITION, AND RESIST FILM AND PATTERN FORMING METHOD USING THE SAME

(75) Inventors: Naohiro Tango, Shizuoka (JP); Yusuke Iizuka, Shizuoka (JP); Akinori Shibuya, Shizuoka (JP); Shuhei Yamaguchi, Shizuoka (JP); Shohei Kataoka, Shizuoka (JP)

(73) Assignee: FUJIFILM Corporation, Tokyo (JP)

(21) Appl. No.: 13/323,179

(22) Filed: Dec. 12, 2011

(30) Foreign Application Priority Data
Dec. 27, 2010 (JP) 2010-291380

(51) Int. Cl. G03F 7/20; G03F 7/027

(52) U.S. Cl. 430/281.1; 430/325

(57) ABSTRACT

An actinic-ray-sensitive or radiation-sensitive resin composition capable of forming a pattern having excellent critical dimension uniformity (CDU) in the line width, and a pattern forming method using the same are provided.

The actinic-ray-sensitive or radiation-sensitive resin composition of the present invention includes (A) a resin containing a repeating unit having a specific lactone structure and a repeating unit having a specific monocyclic alicyclic structure, which increases a solubility in an alkaline developer by the action of an acid, and (B) a compound having a specific structure, which generates an acid upon irradiation with an actinic-ray or a radiation.

### BACKGROUND OF THE INVENTION

1. Field of the Invention

The present invention relates to an actinic-ray-sensitive or radiation-sensitive resin composition, and a resist film and a pattern forming method using the same. More specifically, the present invention relates to an actinic-ray-sensitive or radiation-sensitive resin composition applicable to a production process of a semiconductor such as IC, a production process of a circuit board for a liquid crystal, a thermal head, or the like, and other lithography processes of photofabrication, and a resist film and a pattern forming method using the same. Particularly, the present invention relates to an actinic-ray-sensitive or radiation-sensitive resin composition which is suitable when far ultraviolet radioactive rays at a wavelength of 250 nm or less, an electron beam, or the like is used as an irradiation source, and a resist film and a pattern forming method using the same.

2. Description of the Related Art

A chemical amplification type resist composition is a material for pattern formation, which generates an acid in the exposed areas upon irradiation with radiation such as far ultraviolet rays and the like, and undergoes a reaction catalyzed by this acid, and as a result, comes to have a variance in the solubility in a developer between the areas irradiated with the actinic radioactive ray and the unirradiated areas, thereby forming a pattern on the substrate.

In the case where a KrF excimer laser is employed as an exposure light source, a resin having a poly(hydroxystyrene) skeleton which shows reduced absorption mainly in a 248-nm region, is used as the main component in the chemical amplification resist composition. Consequently, the composition has high sensitivity and high resolution, and forms a good pattern, and it is hence a better system, as compared with a conventional naphthoquinonediazide/novolak resin system.

On the other hand, in the case where a light source having a shorter wavelength, for example, an ArF excimer laser (193 nm), is employed as an exposure light source, compounds having aromatic groups used in the chemical amplification resist composition intrinsically show considerable absorption in a 193-nm region, and thus, this composition cannot be said to be a favorable system.

Consequently, resist compositions for an ArF excimer laser, which contain a resin with an alicyclic hydrocarbon structure, have been developed.

Furthermore, in accordance with the miniaturization of semiconductor elements, the wavelength shortening of the exposure light source and the realization of high numerical apertures (high NA) for projector lenses have been advanced. In this regard, a high resolving power due to the wavelength shortening has been required. As one of the methods for realizing a high resolving power, it is heretofore known to employ a so-called liquid immersion technique, that is, a method in which the space between a projector lens and a sample is filled with a liquid with a high refractive index (hereinafter also referred to as a “liquid for liquid immersion”). The liquid immersion method is effective for any of pattern shapes at present, and can be combined with a super-resolution technology such as a phase shift method, a modified illumination method, and the like now under study.

A resist composition for an ArF excimer laser (193 nm) using such the chemical amplification mechanism is mainly used at present. However, in case of a fine pattern having a line width of 110 nm or less is formed, the resist composition has been required to be further improved from the viewpoint of the comprehensive performances.

From the viewpoint of improvement of the comprehensive performances as the resist composition, resist compositions including repeating units having various lactone structures are known (see, for example, JP2008-257198A, JP2005-31624A, JP2010-159393A, JP2006-18229A, JP2009-86445A, JP2005-234330A, and JP2005-234119A).

However, even with the use of a resist composition including repeating units having various lactone structures, critical dimension uniformity (CDU) in the line width of a pattern which is one of the comprehensive performances as a resist has been required to be further improved. In particular, when forming a fine pattern having a line width of 110 nm or less, there are demands for a resist composition having excellent CDU.

### SUMMARY OF THE INVENTION

An object of the present invention to provide an actinic-ray-sensitive or radiation-sensitive resin composition capable of forming a pattern having excellent critical dimension uniformity (CDU) in the line width, and a resist film and a pattern forming method using the same.

An actinic-ray-sensitive or radiation-sensitive resin composition of the present invention obtained by solving the above-described problems is characterized in that it includes (A) a resin which increases a solubility in an alkaline developer by the action of an acid, including a repeating unit represented by the following general formula (A-I) and a repeating unit represented by the following general formula (1), and (B) a compound represented by the following general formula (ZI-3), which generates an acid upon irradiation with an actinic-ray or a radiation.

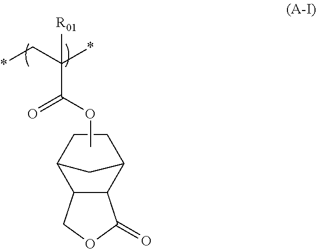

In the general formula (A-I),
R₀₁ represents a hydrogen atom or an alkyl group.

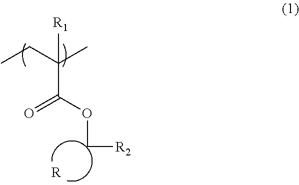

In the general formula (1),
R₁ represents a hydrogen atom or an alkyl group,
R₂ represents an alkyl group or a cycloalkyl group, and
R represents an atomic group required for forming a monocyclic alicyclic structure in cooperation with a carbon atom.

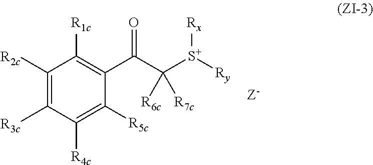

In the general formula (ZI-3),
each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,
each of R_{6c}, and R_{7c} independently represents a hydrogen atom, an alkyl group, a cycloalkyl group, a halogen atom, a cyano group, or an aryl group,
each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group,
at least any two or more of R_{1c} to R_{5c}, R_{5c} and R_{6c}, R_{6c} and R_{7c}, R_{5c} and Rₓ, and Rₓ and R_{y} may be bonded to each other to form a ring structure, and this ring structure may contain an oxygen atom, a sulfur atom, a ketone group, an ester bond, or an amide bond, and
Z⁻ represents a sulfonate anion.

It is a preferable embodiment of the composition of the present invention that the composition further includes a hydrophobic resin (C), a low-molecular-weight compound (D) having a group which is cleaved by the action of an acid, and further includes, which is different from the compound represented by the general formula (ZI-3), a compound which generates an acid upon irradiation with an actinic-ray or a radiation.

It is another preferable embodiment of the composition of the present invention that the repeating unit represented by the general formula (I) is a repeating unit represented by the following general formula (1-1).

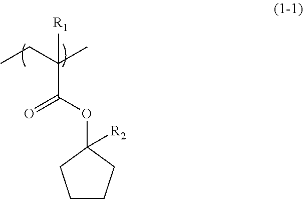

In the general formula (1-1),
R₁ represents a hydrogen atom or an alkyl group, and
R₂ represents an alkyl group or a cycloalkyl group.

It is still another preferable embodiment of the composition of the present invention that the resin (A) further has a repeating unit having an alicyclic hydrocarbon structure substituted with a hydroxyl group.

The present invention further includes a resist film formed using the actinic-ray-sensitive or radiation-sensitive resin composition.

The present invention still further includes a pattern forming method including exposing the above-described resist film and developing the exposed resist film.

It is another preferable embodiment of the pattern forming method of the present invention that the exposure is a liquid immersion exposure.

The present invention preferably has the following configuration.

That is, in the composition of the present invention, the sulfonate anion Z⁻ in the general formula (ZI-3) is represented by the following general formula (III).

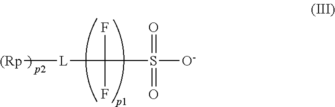

In the general formula (III),
each Rₚ independently represents an alkyl group, a cycloalkyl group, or an aryl group,
L represents a single bond or a linking group, and
p1 represents an integer of 1 to 8, and p2 represents 1 or 2.

In the case where p2 is 2, two Rₚ's may be the same as or different from each other and two Rₚ's may be bonded to each other to form a ring structure.

Furthermore, besides the compound represented by the general formula (ZI-3), the compound which generates an acid upon irradiation with an actinic-ray or a radiation is a triarylsulfonium compound.

Furthermore, the low-molecular-weight compound (D) containing a nitrogen atom and containing a group which is cleaved by the action of an acid preferably has a structure represented by the following general formula (A).

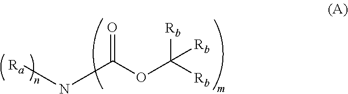

In the general formula (A), Ra represents a hydrogen atom, an alkyl group, a cycloalkyl group, an aryl group, or an aralkyl group. Further, with n=2, two Ra's may be the same as or different from each other, or the two Ra's may be bonded to each other to form a divalent heterocyclic hydrocarbon group or a derivative thereof.

Rb represents a hydrogen atom, an alkyl group, a cycloalkyl group, an aryl group, an aralkyl group, or an alkoxyalkyl group. However, in —C(Rb)(Rb)(Rb), when one or more Rb's are hydrogen atoms, at least one of the remaining Rb's is a cyclopropyl group, a 1-alkoxyalkyl group, or an aryl group.

Two Rb's may be bonded to each other to form an alicyclic hydrocarbon group, aromatic hydrocarbon group, a heterocyclic hydrocarbon group, or a derivative thereof.

n represents an integer of 0 to 2, and m represents an integer of 1 to 3, with n+m=3

In the pattern forming method of the present invention, the exposure is preferably an exposure by an ArF excimer laser.

According to the present invention, it is possible to provide an actinic-ray-sensitive or radiation-sensitive resin composition capable of forming a pattern having excellent critical dimension uniformity (CDU) in the line width, and a resist film and a pattern forming method using the same.

### DESCRIPTION OF THE PREFERRED EMBODIMENTS

Preferable embodiments of the present invention are described in detail below.

Incidentally, a group or atomic group as denoted herein without specifying whether substituted or unsubstituted includes both a group having no substituent and a group having a substituent. For example, the “alkyl group” includes, when whether substituted or unsubstituted is unspecified, not only an alkyl group having no substituent (unsubstituted alkyl group) but also an alkyl group having a substituent (substituted alkyl group).

Furthermore, the “actinic-ray” or the “radiation” in the present specification mean, for example, bright line spectra from a mercury lamp, far ultraviolet radioactive rays typically such as an excimer laser, extreme ultraviolet rays (EUV radiation), X-rays, an electron beam (EB), or the like. Further, the “light” as used in the present invention means an actinic-ray or a radiation.

In addition, the “exposure” in the present specification includes not only light irradiation with a mercury lamp, far ultraviolet radioactive rays typically such as an excimer laser, X-rays, EUV radiation, or the like but also the lithography by means of particle beams such as an electron beam, an ion beam, and the like, unless otherwise specified.

The actinic-ray-sensitive or radiation-sensitive resin composition of the present invention includes:
(A) a resin which increases a solubility in an alkaline developer by the action of an acid, including a repeating unit represented by the following general formula (A-I) and a repeating unit represented by the following general formula (1), and
(B) a compound represented by the following general formula (ZI-3), which generates an acid upon irradiation with an actinic-ray or a radiation.

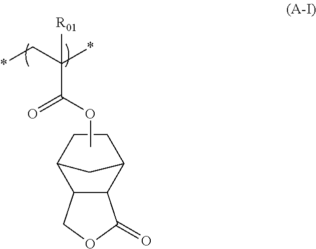

In the general formula (A-I),
R₀₁ represents a hydrogen atom or an alkyl group.

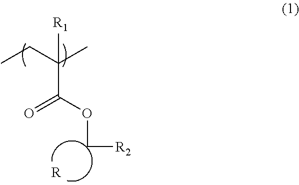

In the general formula (I),
R₁ represents a hydrogen atom or an alkyl group,
R₂ represents an alkyl group or a cycloalkyl group, and
R represents an atomic group required for forming a monocyclic alicyclic structure in cooperation with a carbon atom.

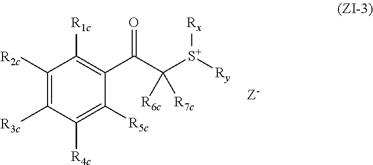

In the general formula (ZI-3),
each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,
each of R_{6c} and R_{7c} independently represents a hydrogen atom, an alkyl group, a cycloalkyl group, a halogen atom, a cyano group, or an aryl group,
each of Rₓ and R_{y} independently represents an alkyl group, a cycloalkyl group, a 2-oxoalkyl group, a 2-oxocycloalkyl group, an alkoxycarbonylalkyl group, an allyl group or vinyl group,
at least any two or more of R_{1c} to R_{5c}, R_{5c} and R_{6c}, R_{6c} and R_{7c}, R_{5c} and Rₓ, and Rₓ and R_{y} may be bonded to each other to form a ring structure, and this ring structure may contain an oxygen atom, a sulfur atom, a ketone group, an ester bond, or an amide bond, and
Z⁻ represents a sulfonate anion.

[1] (A) Resin which increases a solubility in an alkaline developer by the action of an acid, including a repeating unit represented by the following general formula (A-I) and a repeating unit represented by the following general formula (1) (which is also simply referred to as a “resin (A)”)

In the present invention, the resin (A) has a repeating unit represented by the following general formula (A-I).

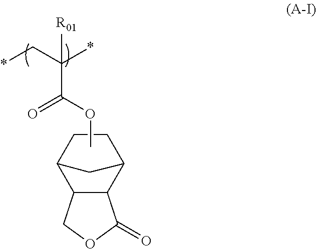

In the general formula (A-I),
R₀₁ represents a hydrogen atom or an alkyl group.

The alkyl group of R₀₁ is preferably an alkyl group having 1 to 4 carbon atoms, more preferably a methyl group or an ethyl group, and particularly preferably a methyl group. The alkyl group in R₀₁ may be substituted, and examples of the substituent include a halogen atom such as a fluorine atom, a chlorine atom, a bromine atom, and the like; a mercapto group; a hydroxyl group; an alkoxy group such as a methoxy group, an ethoxy group, an isopropoxy group, a t-butoxy group, a benzyloxy group, and the like; and an acyloxy group such as an acetyloxy group, a propionyloxy group, and the like. R₀₁ is preferably a hydrogen atom, a methyl group, a trifluoromethyl group, or a hydroxymethyl group, more preferably a hydrogen atom or a methyl group, and still more preferably a methyl group.

The repeating unit represented by the general formula (A-I) group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90% or more, and more preferably 95% or more.

The content of the repeating unit represented by the general formula (A-I), the sum thereof when a plurality of repeating units are contained, is preferably in the range of 15 to 70 mol %, more preferably 20 to 65 mol %, and most preferably 30 to 60 mol %, based on all the repeating units in the resin (A).

In the present invention, the resin (A) further has a repeating unit represented by the following general formula (1).

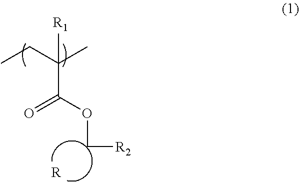

In the general formula (1),
R₁ represents a hydrogen atom or an alkyl group,
R₂ represents an alkyl group or a cycloalkyl group, and
R represents an atomic group required for forming a monocyclic alicyclic structure in cooperation with a carbon atom.

The repeating unit represented by the general formula (1) may correspond to a repeating unit which decomposes by the action of an acid to cause an alkali-soluble group (which is also referred to as an “acid-decomposable group”).

Specific examples and preferable examples of the alkyl group with respect to R₁ include the specific examples and the preferable examples of R₀₁ of the general formula (A-I). R₁ preferably a represents a hydrogen atom, a methyl group, a trifluoromethyl group, or a hydroxymethyl group.

The alkyl group in R₂ may be linear or branched, and may have a substituent. Examples of the alkyl group in R₂ include a methyl group, an ethyl group, an n-propyl group, an isopropyl group, an n-butyl group, an isobutyl group, a t-butyl group, and the like.

The cycloalkyl group in R₂ may be monocyclic or polycyclic, and may have a substituent. Examples of the cycloalkyl group in R₂ include a monocyclic cycloalkyl group such as a cyclopentyl group, a cyclohexyl group, and the like.

R₂ is preferably an alkyl group, more preferably one having 1 to 10 carbon atoms, and still more preferably one having 1 to 5 carbon atoms, and examples thereof include a methyl group and an ethyl group.

R represents an atomic group required for forming an alicyclic structure in cooperation with a carbon atom. The alicyclic structure formed by cooperation of R with a carbon atom is a monocyclic alicyclic structure (for example, a cyclopentyl group, a cyclohexyl group, a cycloheptyl group, and a cyclooctyl group), and the number of carbon atoms is preferably 3 to 8, more preferably 3 to 7, and most preferably 5 or 6.

Furthermore, the repeating unit represented by the general formula (1) is preferably a repeating unit represented by the following general formula (1-1).

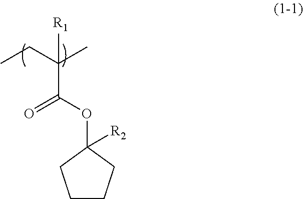

In the general formula (1-1), R₁ and R₂ have the same meanings as in the general formula (1).

The repeating unit represented by the general formula (1) may be used singly or in combination of two or more kinds thereof.

The content of the repeating unit represented by the general formula (1) (the sum thereof when a plurality of repeating units are contained), is preferably in the range of 15 to 70 mol %, more preferably 20 to 65 mol %, and most preferably 30 to 65 mol %, based on all the repeating units in the resin (A).

The repeating unit represented by the general formula (1) can be used in combination with other repeating units having an acid-decomposable group.

Examples of such other repeating units having an acid-decomposable group that can be used in combination include those in which the group corresponding to R₂ in the general formula (1) is a methyl group or an ethyl group, and the a ring formed by R is an adamantane ring.

In the present invention, in one embodiment in which other repeating units having an acid-decomposable group are used in combination, the repeating units in which a group corresponding to R₂ in the general formula (1-1) is a methyl group or an ethyl group, and the repeating units in which a group corresponding to R₂ in the general formula (1) is a methyl group or an ethyl group, and the a ring formed by R is an adamantane ring, are preferably used in combination with each other.

In the case where other repeating unit having an acid-decomposable group is used in addition to the repeating unit represented by the general formula (1), the total content of the repeating unit represented by the general formula (1) and other repeating units having an acid-decomposable group is preferably 15 to 70 mol %, more preferably 20 to 65 mol %, and most preferably 30 to 65 mol %, based on all the repeating units in the resin (A).

It is preferable for the resin (A) to have a repeating unit having a hydroxyl group or a cyano group. The possession of this repeating unit realizes enhancements of adhesion of a resist film to a substrate, and developer affinity. The repeating unit having a hydroxyl group or a cyano group is preferably a repeating unit with a structure of an alicyclic hydrocarbon substituted with a hydroxyl group or a cyano group. In the alicyclic hydrocarbon structure substituted with a hydroxyl group or a cyano group, the alicyclic hydrocarbon structure preferably consists of an adamantyl group, a diamantyl group, or a norbornyl group. Preferable examples of the alicyclic hydrocarbon structures substituted with a hydroxyl group or a cyano group include a monohydroxyadamantyl group, a dihydroxyadamantyl group, a monohydroxydiamantyl group, a dihydroxydiamantyl group, a cyano group-substituted norbornyl group, and the like.

Examples of the repeating unit having the atomic group include repeating units represented by the following general formulae (AIIa) to (AIId).

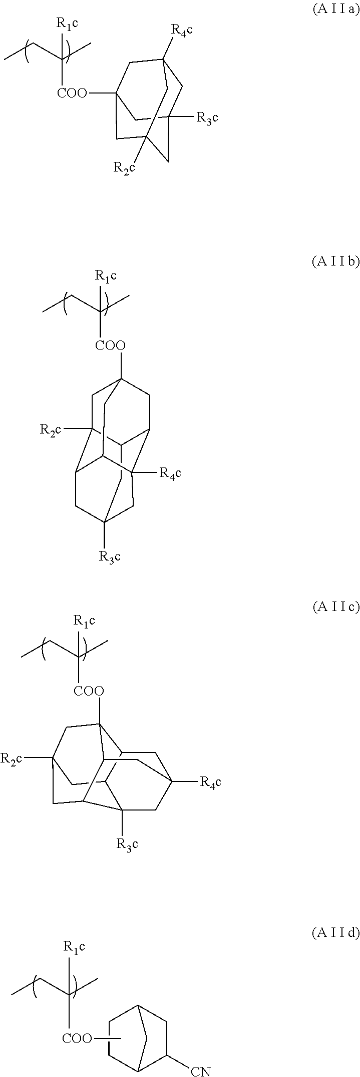

In the general formulae (AIIa) to (AIId),
R_{1c} represents a hydrogen atom, a methyl group, a trifluoromethyl group, or hydroxymethyl group, and
each of R_{2c} to R_{4c} independently represents a hydrogen atom, a hydroxyl group, or cyano group, provided that at least one of R_{2c} to R_{4c} represents a hydroxyl group or cyano group. Preferably, one or two of R_{2c} to R_{4c} are hydroxyl groups, and the rest are hydrogen atoms. In the general formula (VIIa), more preferably, two of R_{2c} to R_{4c} are hydroxyl groups, and the reset are hydrogen atoms.

The content of the repeating unit having a hydroxyl group or a cyano group is preferably 5 to 40 mol %, more preferably 5 to 30 mol %, and most preferably 10 to 25 mol %, based on all the repeating units in the resin (A).

Specific examples of the repeating unit having a hydroxyl group or a cyano group will be shown below, but the present invention is not limited thereto.

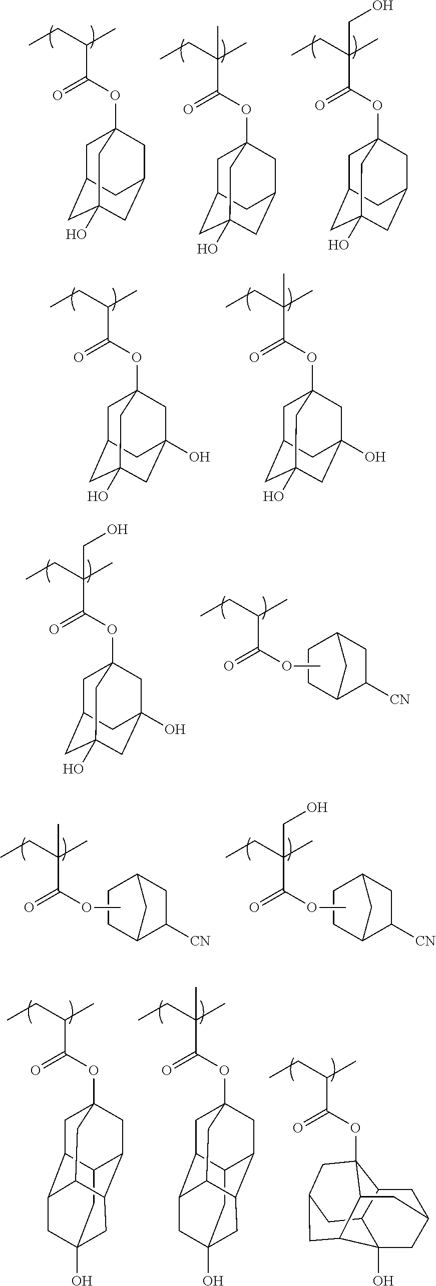

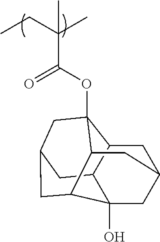

The resin used in the actinic-ray-sensitive or radiation-sensitive resin composition of the present invention may include a repeating unit having an alkali-soluble group. Examples of the alkali-soluble group include a carboxyl group, a sulfonamido group, a sulfonylimido group, a bissulfonylimido group, and an aliphatic alcohol substituted at its α-position with an electron-withdrawing group (for example, a hexafluoroisopropanol group). The possession of a repeating unit having a carboxyl group is more preferred. The possession of the repeating unit having an alkali-soluble group increases the resolving power in contact hole usage.

The repeating unit having an alkali-soluble group is preferably any of a repeating unit wherein the alkali-soluble group is directly bonded to the main chain of a resin such as a repeating unit of acrylic acid or methacrylic acid, a repeating unit wherein the alkali-soluble group is bonded via a linking group to the main chain of a resin and a repeating unit wherein the alkali-soluble group is introduced in a terminal of a polymer chain by the use of a chain transfer agent or polymerization initiator having the alkali-soluble group in the stage of polymerization. The linking group may have a monocyclic or polycyclic cyclohydrocarbon structure. The repeating unit of an acrylic acid or a methacrylic acid is particularly preferred.

The resin (A) in the present invention may not contain a repeating unit having an alkali-soluble group, but in the case where it contains a repeating unit having an alkali-soluble group, the content of the repeating unit having an alkali-soluble group is preferably from 1 to 20 mol %, more preferably from 3 to 15 mol %, and most preferably from 5 to 10 mol %, based on all the repeating units of the resin (A).

Specific examples of the repeating units having an alkali-soluble group will be shown below, but the present invention is not limited thereto.

In the specific examples, Rx represents H, CH₃, CH₂OH, or CF₃.

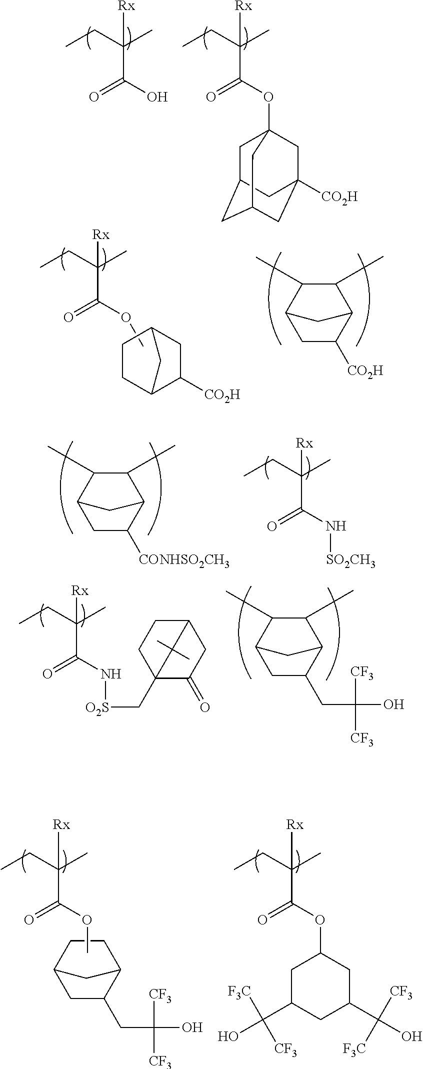

The resin (A) in the present invention can further contain a repeating unit that has a structure of an alicyclic hydrocarbon structure having no polar group (for example, the alkali-soluble group, the hydroxyl group, and the cyano group as described above), exhibiting no acid decomposability. Examples of such a repeating unit include a repeating unit represented by the general formula (IV) below.

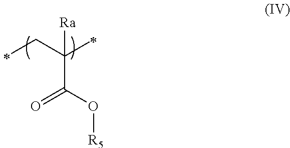

In the general formula (IV), R₅ represents a hydrocarbon group having at least one cyclic structure and having no polar group.

Ra represents a hydrogen atom, an alkyl group, or a —CH₂—O—Ra₂ group, in which Ra₂ represents a hydrogen atom, an alkyl group, or an acyl group. Ra preferably represents a hydrogen atom, a methyl group, a hydroxymethyl group, or a trifluoromethyl group, and particularly preferably a hydrogen atom or a methyl group.

The cyclic structures contained in R₅ include a monocyclic hydrocarbon group and a polycyclic hydrocarbon group. Examples of the monocyclic hydrocarbon group include a cycloalkyl group having 3 to 12 carbon atoms, such as a cyclopentyl group, a cyclohexyl group, a cycloheptyl group, a cyclooctyl group, and the like, or a cycloalkenyl group having 3 to 12 carbon atoms, such as a cyclohexenyl group and the like. Examples of the monocyclic hydrocarbon group preferably include a monocyclic hydrocarbon group having 3 to 7 carbon atoms, and more preferably a cyclopentyl group and a cyclohexyl group.

Examples of the polycyclic hydrocarbon group include a ring-assembly hydrocarbon group and a crosslinked-ring hydrocarbon group. Examples of the ring-assembly hydrocarbon group include a bicyclohexyl group, a perhydronaphthalene group, and the like. Examples of the crosslinked-ring hydrocarbon ring include a bicyclic hydrocarbon ring, such as a pinane ring, a bornane ring, a norpinane ring, a norbornane ring, a bicyclooctane ring (for example, a bicyclo[2.2.2]octane ring, a bicyclo[3.2.1]octane ring, and the like), etc.; a tricyclic hydrocarbon ring such as a homopaddlane ring, an adamantane ring, a tricyclo[5.2.1.0^{2,6}]decane ring, a tricyclo[4.3.1.1^{2,5}]undecane ring, and the like; and a tetracyclic hydrocarbon ring such as a tetracyclo[4.4.0.1^{2,5}.1^{7,10}]dodecane ring a perhydro-1,4-methano-5,8-methanonaphthalene ring, and the like. Further, the crosslinked-ring hydrocarbon rings include a condensed-ring hydrocarbon ring, for example, condensed rings formed by condensation of a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring, a perhydrophenarene ring, and the like.

Examples of the preferable crosslinked-ring hydrocarbon ring include a norbornyl group, an adamantyl group, a bicyclooctanyl group, a tricyclo[5,2,1,0^{2,6}]decanyl group, and the like. Examples of the more preferable crosslinked-ring hydrocarbon ring include a norbornyl group and an adamantyl group.

Such an alicyclic hydrocarbon group may have a substituent, and preferable examples of the substituents include a halogen atom, an alkyl group, a hydroxyl group substituted with a hydrogen atom, an amino group substituted with a hydrogen atom, and the like. Preferable examples of the halogen atom include a bromine atom, a chlorine atom, and a fluorine atom, and preferable examples of the alkyl group include a methyl group, an ethyl group, a butyl group, and a t-butyl group. The alkyl group may further have a substituent, and examples of the substituent include a halogen atom, an alkyl group, a hydroxyl group substituted with a hydrogen atom, and an amino group substituted with a hydrogen atom.

Examples of the substituent of the hydrogen atom include an alkyl group, a cycloalkyl group, an aralkyl group, a substituted methyl group, a substituted ethyl group, an alkoxycarbonyl group, and an aralkyloxycarbonyl group. Preferable examples of the alkyl group include an alkyl group having 1 to 4 carbon atoms, preferable examples of the substituted methyl group include a methoxymethyl group, a methoxythiomethyl, group a benzyloxymethyl group, a t-butoxymethyl group, and a 2-methoxyethoxymethyl group, and preferable examples of the substituted ethyl group include a 1-ethoxyethyl group and a 1-methyl-1-methoxyethyl group. Preferable examples of the acyl group include an aliphatic acyl group having 1 to 6 carbon atoms, such as a formyl group, an acetyl group, a propionyl group, a butyryl group, an isobutyryl group, a valeryl group, a pivaloyl group, and the like. Examples of the alkoxycarbonyl group include an alkoxycarbonyl group having 1 to 4 carbon atoms, and the like.

The resin (A) may or may not contain the repeating units that have a structure of an alicyclic hydrocarbon having no polar group and exhibiting no acid decomposability, but in the case where the resin (A) may contain such repeating units, the content of the repeating units is preferably from 1 to 40 mol %, and more preferably from 2 to 20 mol %, based on all the repeating units of resin (B).

Specific examples of the repeating units that have a structure of an alicyclic hydrocarbon having no polar group, and exhibiting no acid decomposability will be shown below, but the present invention is not limited thereto. In the formulae, Ra represents H, CH₃, CH₂OH, or CF₃.

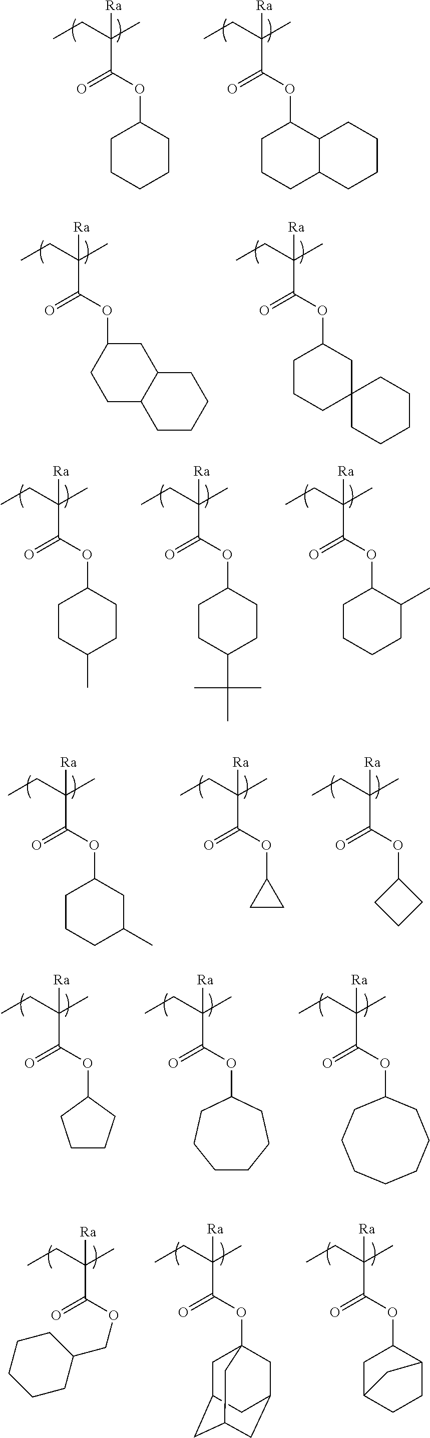

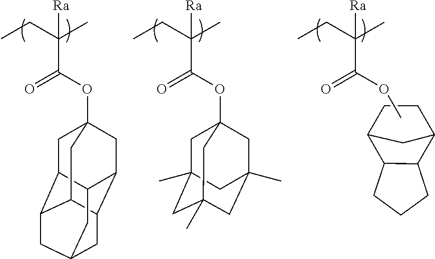

The Resin (A) used in the actinic-ray-sensitive or radiation-sensitive resin composition of the present invention may have, in addition to the above-described repeating structural units, various repeating structural units for the purpose of regulating the dry etching resistance, standard developer adaptability, substrate adhesion, resist profile and generally required properties of the resist such as resolving power, heat resistance, sensitivity, and the like.

Examples of such a repeating structural unit include the repeating structural units corresponding to the following monomers, which however are nonlimiting.

The use of such repeating structural units would enable fine regulation of the required properties of the resin used in the actinic-ray-sensitive or radiation-sensitive resin composition of the present invention, in particularly, (1) solubility in applied solvents, (2) film forming easiness (glass transition point), (3) alkali developability, (4) film thinning (selection of hydrophilicity/hydrophobicity and alkali-soluble groups), (5) adhesion of unexposed area to a substrate, (6) dry etching resistance, and the like.

Examples of such a monomer include a compound having an unsaturated bond, capable of addition polymerization, which is selected from acrylic esters, methacrylic esters, acrylamides, methacrylamides, allyl compounds, vinyl ethers, vinyl esters, and the like; etc.

In addition, any unsaturated compound capable of addition polymerization that is copolymerizable with monomers corresponding to the above various repeating structural units may be copolymerized therewith.

The molar ratios of the respective repeating structural units in the resin (A) used in the actinic-ray-sensitive or radiation-sensitive resin composition of the present invention are appropriately determined from the viewpoint of regulation of not only the dry etching resistance of the resist but also the standard developer adaptability, substrate adhesion, resist profile, and generally required performances of the resist, such as the resolution power, heat resistance, sensitivity, and the like. It is ensured that the content of the respective repeating structural units is no more than 100 mol % in total.

When the actinic-ray-sensitive or radiation-sensitive resin composition of the present invention is one for ArF exposure, it is preferable for the resin (A) used in the actinic-ray-sensitive or radiation-sensitive resin composition of the present invention to have substantially no aromatic group from the viewpoint of transparency to an ArF beam. More specifically, the proportion of the repeating units having an aromatic group is preferably 5 mol % or less, more preferably 3 mol % or less, or ideally 0 mol %, that is, the repeating unit having an aromatic group is not contained, in total in all the repeating units of the resin (A). Further, the resin (A) preferably has a monocyclic or polycyclic alicyclic hydrocarbon structure.

Further, from the viewpoint of the compatibility with the hydrophobic resin (C) as described later, it is preferable for the resin (A) to contain neither a fluorine atom nor a silicon atom.

Further, in the resin (A) used in the actinic-ray-sensitive or radiation-sensitive resin composition of the present invention, preferably, all the repeating units consist of (meth)acrylate-based repeating units. In this case, use can be made of any of resins (A), wherein all the repeating units consist of methacrylate-based repeating units, wherein all the repeating units consist of acrylate-based repeating units, and wherein all the repeating units consist of methacrylate-based repeating units and acrylate-based repeating units. However, it is preferable for the acrylate-based repeating units to account for 50 mol % or less of all the repeating units.

The resin (A) in the present invention may be a commercially available product, if available, but can be synthesized by conventional techniques (for example, radical polymerization). Examples of the general synthetic methods include a batch polymerization method in which a monomer species and an initiator are dissolved in a solvent and heated so as to accomplish polymerization, a dropping polymerization method in which a solution of monomer species and initiator is added by dropping to a heated solvent over 1 to 10 hours, and the like, with the dropping polymerization method being preferred. Examples of the reaction solvent include ethers such as tetrahydrofuran, 1,4-dioxane, diisopropyl ether, and the like; ketones such as methyl ethyl ketone, methyl isobutyl ketone, and the like; ester solvents such as ethyl acetate; amide solvents such as dimethylformamide, dimethylacetamide, and the like; solvents capable of dissolving the actinic-ray-sensitive or radiation-sensitive resin composition, such as propylene glycol monomethyl ether acetate, propylene glycol monomethyl ether, and cyclohexanone, as described hereinafter. It is preferable to perform the polymerization with the use of the same solvent as employed in the actinic-ray-sensitive or radiation-sensitive resin composition, whereby any particle generation during storage can be inhibited.

The polymerization reaction is preferably carried out in an atmosphere of inert gas, such as nitrogen or argon. The polymerization is initiated by the use of a commercially available radical initiator (an azo-based initiator, peroxide, and the like) as a polymerization initiator. As the radical initiators, an azo-based initiator is preferable. An azo-based initiator having an ester group, a cyano group or a carboxyl group is particularly preferable. Preferable examples of the initiators include azobisisobutyronitrile, azobisdimethylvaleronitrile, dimethyl 2,2′-azobis(2-methylpropionate), and the like. According to necessity, the initiator is added additionally or in separate portions, and after completion of the reaction, the initiator is put into a solvent and a polymer is collected, for example, in the powder or solid form. The concentration during the reaction is from 5 to 50% by mass, and preferably from 10 to 30% by mass. The reaction temperature is generally from 10° C. to 150° C., preferably from 30° C. to 120° C., and more preferably from 60° C. to 100° C.

In addition, in order to inhibit aggregation of the resin after preparation of the composition, or the like, a step in which a resin synthesized is dissolved in a solvent to give a solution, and the solution is heated at about 30° C. to 90° C. for approximately 30 minutes to 4 hours, as described in, for example, JP2009-037108A.

The weight average molecular weight of the resin (A) of the present invention is preferably 1,000 to 200,000, more preferably 2,000 to 20,000, still more preferably 3,000 to 15,000, and particularly preferably 3,000 to 12,000 in terms of a polystyrene standard as measured by means of GPC. The regulation of the weight average molecular weight to 1,000 to 200,000 increases the viscosity of the composition, to prevent deterioration of film-forming property. Further, deterioration of heat resistance and dry etching resistance, as well as deterioration of developability can be prevented by using the composition of the present invention.

Use is made of the resin (A) whose dispersity (molecular weight distribution) is generally from 1.0 to 3.0, preferably from 1.0 to 2.6, more preferably from 1.0 to 2.0, and most 1.4 to 2.0. The lower the molecular weight distribution, the more excellent the resolving power and resist profile, and the smoother the side wall of the resist pattern to thereby attain an excellence in roughness.

In the present invention, the content ratio of resin (A) based on the total solid content of the whole composition is preferably from 30 to 99% by mass, and more preferably from 60 to 95% by mass.

Furthermore, the resin (A) of the present invention may be used singly or in combination of two or more kinds thereof.

[2] (B) Compound Represented by Following General Formula (ZI-3), Which Generates Acid upon Irradiation with Actinic-ray or radiation.

The actinic-ray-sensitive or radiation-sensitive resin composition of the present invention includes a compound which generates an acid upon irradiation with an actinic-ray or a radiation (which is also referred to as an “acid generator”), which is a compound represented by the following general formula (ZI-3) (which is also referred to as a “compound (ZI-3)”).

The compound (ZI-3) in the present invention is a compound having a phenacylsulfonium structure.

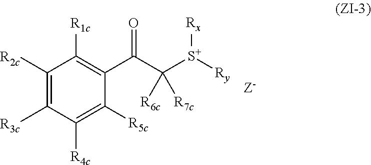

In the general formula (ZI-3),
each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,
each of R_{6c} and R_{7c} independently represents a hydrogen atom, an alkyl group, a cycloalkyl group, a halogen atom, a cyano group, or an aryl group,
each of Rₓ and R_{y} independently represents an alkyl group, a cycloalkyl group, a 2-oxoalkyl group, a 2-oxocycloalkyl group, an alkoxycarbonylalkyl group, an allyl group or vinyl group, and
any two or more of R_{1c} to R_{5c}, R_{5c} and R_{6c}, R_{6c} and R_{7c}, R_{5c} and Rₓ, and R_{c} and R_{y} may be bonded to each other to form a ring structure, and this ring structure may contain an oxygen atom, a sulfur atom, a ketone group, an ester bond, or an amide bond.

The ring structure includes an aromatic or non-aromatic hydrocarbon ring, an aromatic or non-aromatic heterocyclic ring, and a polycyclic condensed ring formed by combination of two or more of these rings. The ring structure includes a 3- to 10-membered ring, and is preferably a 4- to 8-membered ring, and more preferably a 5- or 6-membered ring.

Examples of the group formed by bonding of any two or more of R_{1c} to R_{5c}, R_{6c} and R_{7c}, and Rₓ and R_{y} include a butylene group, a pentylene group, and the like.

The group formed by bonding of R_{5c} and R_{6c}, and R_{5c} and Rₓ is preferably a single bond or an alkylene group, and examples of the alkylene group include a methylene group, an ethylene group, and the like.

Z⁻ represents a sulfonate anion.

The alkyl group as R_{1c} to R_{7c} may be either linear or branched, and examples thereof include an alkyl group having 1 to 20 carbon atoms, and preferably a linear or branched alkyl group having 1 to 12 carbon atoms (for example, a methyl group, an ethyl group, a linear or branched propyl group, a linear or branched butyl group, and a linear or branched pentyl group), and examples of the cycloalkyl group include a cycloalkyl group having 3 to 8 carbon atoms (for example, a cyclopentyl group and a cyclohexyl group).

The aryl group as R_{1c} to R_{7c} preferably has 5 to 15 carbon atoms, and examples thereof include a phenyl group and a naphthyl group.

The alkoxy group as R_{1c} to R_{5c} may be any of linear, branched, and cyclic, and examples thereof include an alkoxy group having 1 to 10 carbon atoms, preferably a linear and branched alkoxy group having 1 to 5 carbon atoms (for example, a methoxy group, an ethoxy group, a linear or branched propoxy group, a linear or branched butoxy group, and a linear or branched pentoxy group), and cyclic alkoxy group having 3 to 8 carbon atoms (for example, a cyclopentyloxy group and a cyclohexyloxy group).

Specific examples of the alkoxy group in the alkoxycarbonyl group as R_{1c} to R_{5c} include the same as those of the alkoxy group as R_{1c} to R_{5c}.

Specific examples of the alkyl group in the alkylcarbonyloxy group and the alkylthio group as R_{1c} to R_{5c} include the same as those of the alkyl group as R_{1c} to R_{5c}.

Specific examples of the aryl group in the aryloxy group and the arylthio group as R_{1c} to R_{5c} include the same as those of the aryl group as R_{1c} to R_{5c}.

Preferably, any one of R_{1c} to R_{5c} is a linear or branched alkyl group, a cycloalkyl group, or a linear, branched, or cyclic alkoxy group, and R_{1c} to R_{5c} more preferably has 2 to 15 carbon atoms, due to which the solvent solubility is more enhanced and production of particles during storage is be suppressed.

The ring structure formed by bonding of any two or more of R_{1c} to R_{5c} preferably includes a 5- or 6-membered ring, and particularly preferably a 6-membered ring (such as a phenyl ring).

The ring structure formed by the mutual bonding of R_{5c} and R_{6c} preferably includes a 4 or greater-membered ring (preferably a 5- or 6-membered ring) formed with the carbonyl carbon atom and carbon atom in the general formula (I) by the mutual bonding of R_{5c} and R_{6c} to constitute a single bond or an alkylene group (a methylene group, an ethylene group, and the like).

The aryl group as any of R_{6c} and R_{7c} is an alkyl group having 5 to 15 carbon atoms, and examples thereof include a phenyl group and a naphthyl group.

Furthermore, in the case where R_{6c} and R_{7c} are combined to form a ring, the group formed by bonding of R_{6c} and R_{7c} is preferably an alkylene group having 2 to 10 carbon atoms, and examples thereof include an ethylene group, a propylene group, a butylene group, a pentylene group, a hexylene group, and the like. Further, the ring formed by bonding of R_{6c} and R_{7c} may contain a heteroatom such as an oxygen atom and the like in the ring.

Examples of the alkyl group and the cycloalkyl group as Rₓ and R_{y} include the same as those of the alkyl group and the cycloalkyl group as in R_{1c} to R_{7c}.

Examples of the 2-oxoalkyl group and the 2-oxocycloalkyl group as Rₓ and R_{y} include a group containing >C═O at the 2-position of the alkyl group and the cycloalkyl group as R_{1c} to R_{7c}.

Examples of the alkoxy group in the alkoxycarbonylalkyl group as Rₓ and R_{y} are the same as those of the alkoxy group in R_{1c} to R_{5c}. Examples of the alkyl group include an alkyl group having 1 to 12 carbon atoms, and preferably a linear alkyl group having 1 to 5 carbon atoms (for example, a methyl group and an ethyl group).

The allyl group as Rₓ and R_{y} is not particularly limited but is preferably an unsubstituted allyl group or an allyl group substituted with a monocyclic or polycyclic cycloalkyl group (preferably a cycloalkyl group having 3 to 10 carbon atoms).

The vinyl group as Rₓ and R_{y} is not particularly limited but is preferably an unsubstituted vinyl group or a vinyl group substituted with a monocyclic or polycyclic cycloalkyl group (preferably a cycloalkyl group having 3 to 10 carbon atoms).

The ring structure which may be formed by the mutual bonding of Rₓ and R_{y} include a 5- or 6-membered ring, and preferably a 5-membered ring (that is, a tetraydrothiophene ring), formed together with the sulfur atom in the general formula (ZI-3) by divalent Rₓ and R_{y} (for example, a methylene group, an ethylene group, a propylene group, and the like).

Rₓ and R_{y} are each preferably an alkyl group, or a cycloalkyl group having 4 or more carbon atoms, more preferably an alkyl group, or a cycloalkyl group having 6 or more carbon atoms, and still more preferably an alkyl group, or a cycloalkyl group having 8 or more carbon atoms.

R_{1c} to R_{7c}, Rₓ and R_{y} may further contain a substituent, and examples of such a substituent include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group, and the like.

Examples of the alkyl group include a linear or branched alkyl group having 1 to 12 carbon atoms, such as a methyl group, an ethyl group, an n-propyl group, an i-propyl group, an n-butyl group, a 2-methylpropyl group, a 1-methylpropyl group, a t-butyl group, and the like.

Examples of the cycloalkyl group include a cycloalkyl group having 3 to 10 carbon atoms, such as a cyclopentyl group, a cyclohexyl group, and the like.

Examples of the aryl group include an aryl group having 6 to 15 carbon atoms, such as a phenyl group, a naphthyl group, and the like.

Examples of the alkoxy group include a linear, branched, or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, a cyclohexyloxy group, and the like.

Examples of the aryloxy group include an aryloxy group having 6 to 10 carbon atoms, such as a phenyloxy group, a naphthyloxy group, and the like.

Examples of the acyl group include a linear or branched acyl group having 2 to 12 carbon atoms, such as an acetyl group, a propionyl group, an n-butanoyl group, an i-butanoyl group, an n-heptanoyl group, a 2-methylbutanoyl group, a 1-methylbutanoyl group, a t-heptanoyl group, and the like.

Examples of the arylcarbonyl group include an aryloxy group having 6 to 10 carbon atoms, such as a phenylcarbonyl group, a naphthylcarbonyl group, and the like.

Examples of the alkoxyalkyl group include a linear, branched, or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group, a 2-ethoxyethyl group, and the like.

Examples of the aryloxyalkyl group include an aryloxy group having 7 to 12 carbon atoms, such as a phenyloxymethyl group, phenyloxyethyl group, a naphthyloxymethyl group, a naphthyloxyethyl group, and the like.

Examples of the alkoxycarbonyl group include a linear, branched, or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, a cyclohexyloxycarbonyl, and the like.

Examples of the aryloxycarbonyl group include an aryloxycarbonyl group having 7 to 11 carbon atoms, such as a phenyloxycarbonyl group, a naphthyloxycarbonyl group, and the like.

Examples of the alkoxycarbonyloxy group include a linear, branched, or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, a cyclohexyloxycarbonyloxy, and the like.

Examples of the aryloxycarbonyloxy group include an aryloxycarbonyloxy group having 7 to 11 carbon atoms, such as a phenyloxycarbonyloxy group, a naphthyloxycarbonyloxy group, and the like.

In the general formula (ZI-3), it is more preferable that each of R_{1c}, R_{2c}, R_{4c}, and R_{5c} independently represent a hydrogen atom, and R_{3c} represent a group except for a hydrogen atom, that is, represent an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Z⁻ represents a sulfonate anion as a non-nucleophilic anion.

The non-nucleophilic anion is an anion having an exceedingly low ability of causing a nucleophilic reaction, and is also an anion capable of suppressing the decomposition over time by the nucleophilic reaction in the molecule, which thus leads to improvement of the stability over time of the resist.

Examples of the sulfonate anion include an aliphatic sulfonate anion, an aromatic sulfonate anion, a camphor sulfonate anion, and the like.

The aliphatic moiety in the aliphatic sulfonate anion may be an alkyl group or a cycloalkyl group, and preferable examples thereof include an alkyl group having 1 to 30 carbon atoms and a cycloalkyl group having 3 to 30 carbon atoms, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group, and the like.

Preferable examples of the aromatic group in the aromatic sulfonate anion and the aromatic carboxylate anion include an aryl group preferably having 6 to 14 carbon atoms, such as a phenyl group, a tolyl group, a naphthyl group, and the like.

The alkyl group, the cycloalkyl group, and the aryl group of the aliphatic sulfonate anion and the aromatic sulfonate anion may have a substituent. Examples of the substituent of the alkyl group, the cycloalkyl group, and the aryl group of the aliphatic sulfonate anion and the aromatic sulfonate anion include a nitro group, a halogen atom such as a fluorine atom and the like, a carboxyl group, a hydroxyl group, an amino group, a cyano group, an alkoxy group (preferably having 1 to 15 carbon atoms), an a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), an a cycloalkylaryloxysulfonyl group (preferably having 10 to 20 carbon atoms), an alkyloxyalkyloxy group (preferably having 5 to 20 carbon atoms), an a cycloalkylalkyloxyalkyloxy group (preferably having 8 to 20 carbon atoms), and the like. The aryl group or the ring structure which may be further contained in these groups has an alkyl group (preferably having 1 to 15 carbon atoms) as its substituent.

The non-nucleophilic anion of Z⁻ is preferably an aliphatic sulfonate anion substituted at its α-position of sulfonic acid with a fluorine atom, or an aromatic sulfonate anion substituted with a fluorine atom or a group having a fluorine atom. The non-nucleophilic anion is more preferably a perfluoroaliphatic sulfonate anion having 4 to 8 carbon atoms, and still more preferably a nonafluorobutane sulfonate anion, a perfluorooctane sulfonate anion, a pentafluorobenzene sulfonate anion, or a 3,5-bis(trifluoromethyl)benzene sulfonate anion.

Specific examples of the cation moiety of the compound (ZI-3) will be shown below.

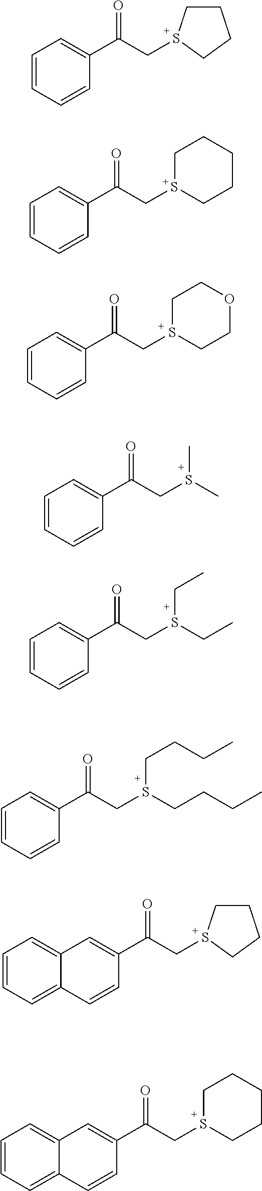

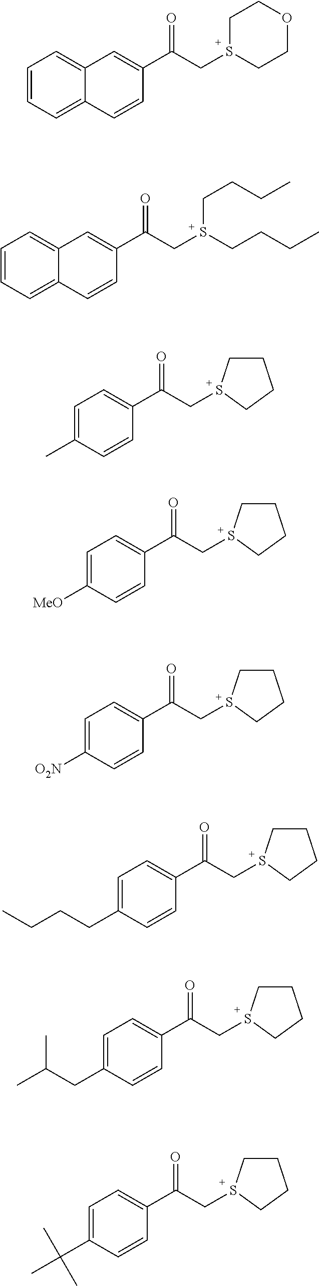

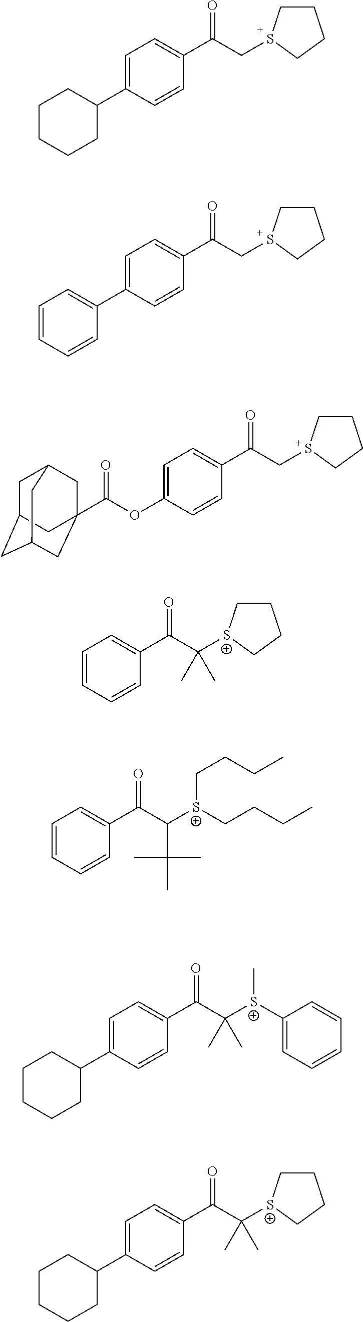

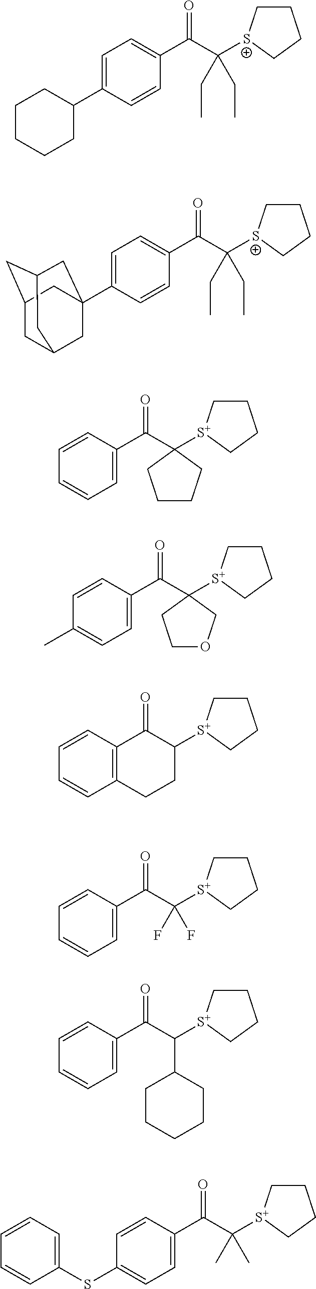

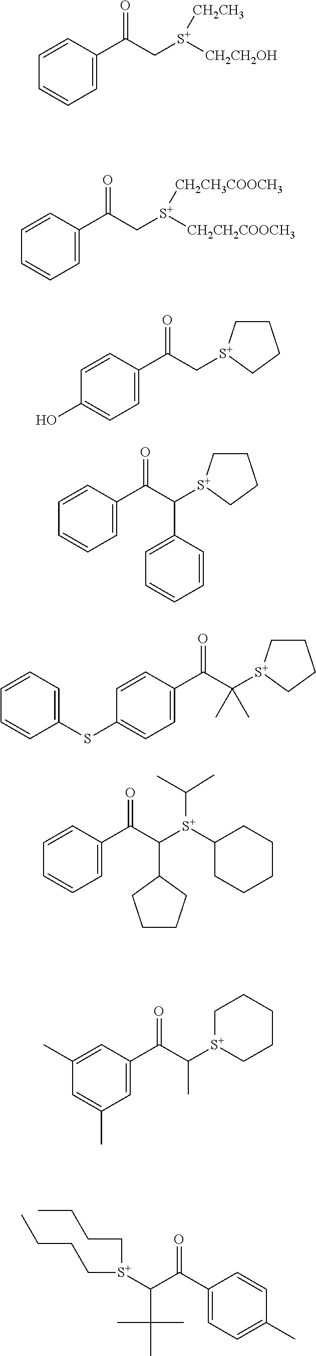

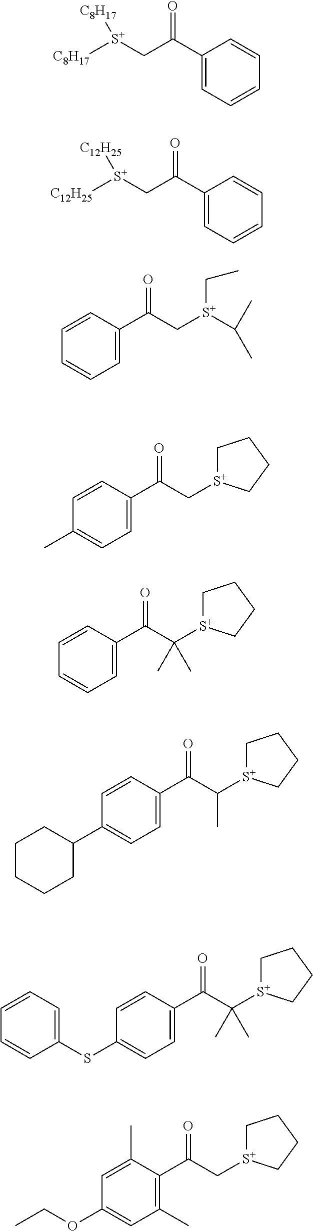

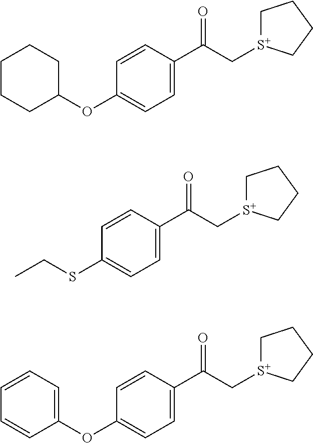

The sulfonate anion for Z⁻ is particularly preferably represented by the following general formula (III) from the viewpoint of the sensitivity.

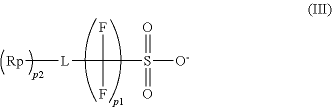

In the general formula (III),
in the case where a plurality of Rₚ's are present, each of them independently represents an alkyl group, a cycloalkyl group, or an aryl group.

L represents a single bond or a linking group.

p1 represents an integer of 1 to 8, and p2 represents 1 or 2.

In the case where p2 is 2, two Rₚ's may be the same as or different from each other and two Rₚ's may be bonded to each other to form a ring structure.

Specific examples of the alkyl group, the cycloalkyl group, and the aryl group represented by Rₚ include a chained alkyl group, a monocyclic alkyl group, a polycyclic hydrocarbon group, and a monocyclic aryl group, and the chained alkyl group, the monocyclic alkyl group, the polycyclic hydrocarbon group, or the monocyclic aryl group may have a substituent. The substituent may have a fluorine atom.

The chained alkyl group may be linear or branch chained, and examples thereof include methyl, ethyl, propyl, butyl, pentyl, hexyl, heptyl, octyl, dodecyl, 2-ethylhexyl, isopropyl, sec-butyl, t-butyl, iso-amyl, and the like.

The alkyl group may have a substituent, and examples of the substituent include a hydroxyl group, a halogen atom (fluorine, chlorine, bromine, and iodine), a nitro group, a cyano group, an amido group, a sulfonamido group, an alkyl group (a methyl group, an ethyl group, a propyl group, an n-butyl group, a sec-butyl group, a hexyl group, a 2-ethylhexyl group, an octyl group, and the like), an alkoxy group (a methoxy group, an ethoxy group, a hydroxyethoxy group, a propoxy group, a hydroxypropoxy group, a butoxy group, and the like), an alkoxycarbonyl group (a methoxycarbonyl group, an ethoxycarbonyl group, and the like), an acyl group (a formyl group, an acetyl group, a benzoyl group, and the like), an acyloxy group (an acetoxy group, a butyryloxy group, and the like), and a carboxy group.

Examples of the monocyclic alkyl group include cyclopropyl, cyclobutyl, cyclopentyl, cyclohexyl, cycloheptyl, cyclooctyl, cyclododecanyl, cyclopentenyl, cyclohexenyl, cyclooctadienyl, and the like, and particularly preferably cyclopropyl, cyclopentyl, cyclohexyl, and cyclooctyl.

The monocyclic alkyl group may have a substituent, and examples of the substituent include a halogen atom (fluorine, chlorine, bromine, and iodine), a nitro group, a cyano group, an amido group, a sulfonamido group, a methyl group, an alkyl group (an ethyl group, a propyl group, an n-butyl group, a sec-butyl group, a hexyl group, a 2-ethylhexyl group, an octyl group, and the like), an alkoxy group (a methoxy group, an ethoxy group, a hydroxyethoxy group, a propoxy group, a hydroxypropoxy group, a butoxy group, and the like), an alkoxycarbonyl group (a methoxycarbonyl group, an ethoxycarbonyl group, and the like), an acyl group (a formyl group, an acetyl group, a benzoyl group, and the like), an acyloxy group (an acetoxy group, a butyryloxy group, and the like), and a carboxy group.

Examples of the polycyclic hydrocarbon group include bicyclo[4.3.0]nonanyl, decahydronaphthalenyl, tricyclo[5.2.1.0(2,6)]decanyl, bornyl, isobornyl, norbornyl, adamantyl, noradamantyl, 1,7,7-trimethyltricyclo[2.2.1.0^{2,6}]heptanyl, 3,7,7-trimethylbicyclo[4.1.0]heptanyl, and the like, and particularly preferably norbornyl, adamantyl, and noradamantyl.

The monocyclic aryl group means a substituted or substituted phenyl group, and examples of the substituent include a hydroxyl group, a halogen atom (fluorine, chlorine, bromine, and iodine), a nitro group, a cyano group, an amido group, a sulfonamido group, an alkyl group (a methyl group, an ethyl group, a propyl group, an n-butyl group, a sec-butyl group, a hexyl group, a 2-ethylhexyl group, an octyl group, and the like), an alkoxy group (a methoxy group, an ethoxy group, a hydroxyethoxy group, a propoxy group, a hydroxypropoxy group, a butoxy group, and the like), an alkoxycarbonyl group (a methoxycarbonyl group, an ethoxycarbonyl group, and the like), an acyl group (a formyl group, an acetyl group, a benzoyl group, and the like), an acyloxy group (an acetoxy group, a butyryloxy group, and the like), and a carboxy group.

Further, Rₚ preferably has no fluorine atom from the viewpoint of a low fluorine content.

Examples of the linking group for L include a divalent linking group when p2 is 1, and a trivalent linking group when p2 is 2.

Examples of the divalent linking group for L include an oxygen atom (—O—), a sulfur atom (—S—), a nitrogen atom (—NH—), a carboxyl group (—OC═O—, —CO(═O)—), an amido group (—NHC(═O)—), a sulfonamido group (—NHSO₂—), and the like.

Examples of the trivalent linking group for L include a nitrogen atom (>N—), an amido group (>NC(═O)—), a sulfonamido group (>NSO₂—), and the like. Particularly, in the case where p2 is 2 and two Rₚ's are bonded to each other to form a ring, L is preferably a nitrogen atom-containing linking group such as an amido group, a sulfonamido group, and the like. Here, two Rₚ's may be bonded to each other to form a cyclic amine residue having a nitrogen atom on L in the ring.

Examples of the cyclic amine residue structure include aziridine, azetidine, pyrrolidine, piperidine, hexamethyleneimine, heptamethyleneimine, piperazine, decahydroquinoline, 8-azabicyclo[3.2.1]octane, indole, oxazolidine, thiazolidine, 2-azanorbornane, 7-azanorbornane, morpholine, thiamorpholine, and the like. The groups may have a substituent. Examples of the substituent include a hydroxyl group, a halogen atom (fluorine, chlorine, bromine, and iodine), a nitro group, a cyano group, an amido group, a sulfonamido group, an alkyl group (a methyl group, an ethyl group, a propyl group, an n-butyl group, a sec-butyl group, a hexyl group, a 2-ethylhexyl group, an octyl group, and the like), an alkoxy group (a methoxy group, an ethoxy group, a hydroxyethoxy group, a propoxy group, a hydroxypropoxy group, a butoxy group, and the like), an alkoxycarbonyl group (a methoxycarbonyl group, an ethoxycarbonyl group, and the like), an acyl group (a formyl group, an acetyl group, a benzoyl group, a carbonyl group on carbon as a constituent of a ring, and the like), an acyloxy group (acetoxy group, butyryloxy group, and the like), and a carboxy group.

As for the sulfonate anion represented by the general formula (III), it is a preferable embodiment that Rₚ is a cycloalkyl group or an aryl group, or that when p2 is 2, two Rₚ's are bonded to each other to form a ring.

Examples of the sulfonate anion as Z⁻ include specific examples below.

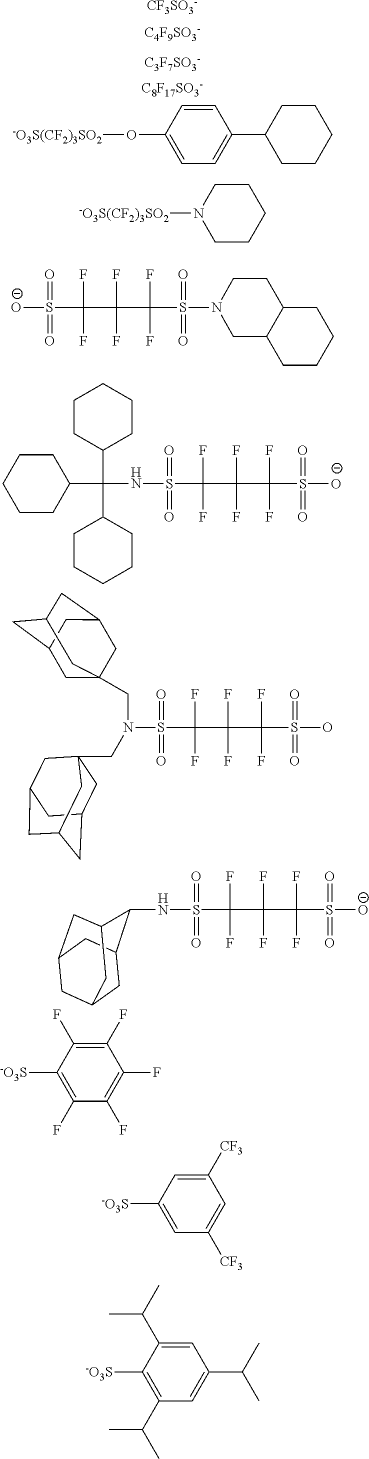

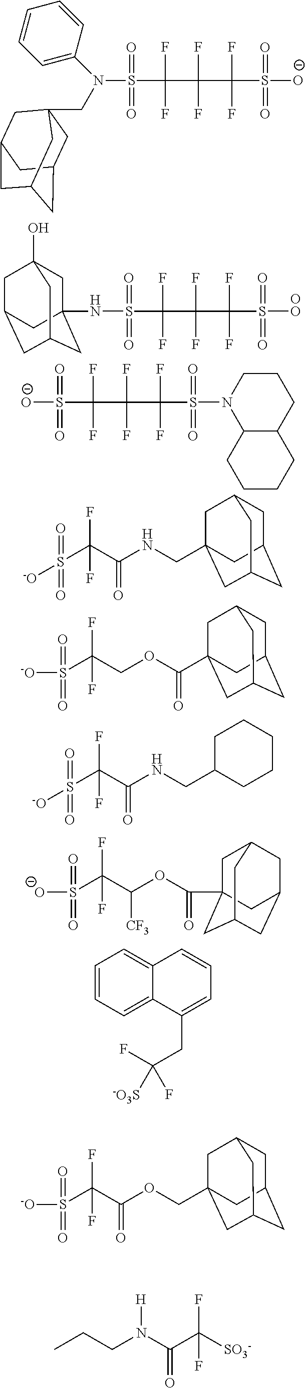

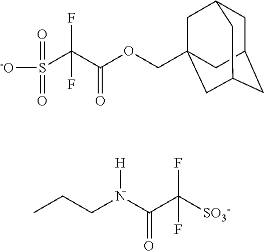

Specific examples of the compound (ZI-3) will be shown below, but the present invention is not limited thereto.

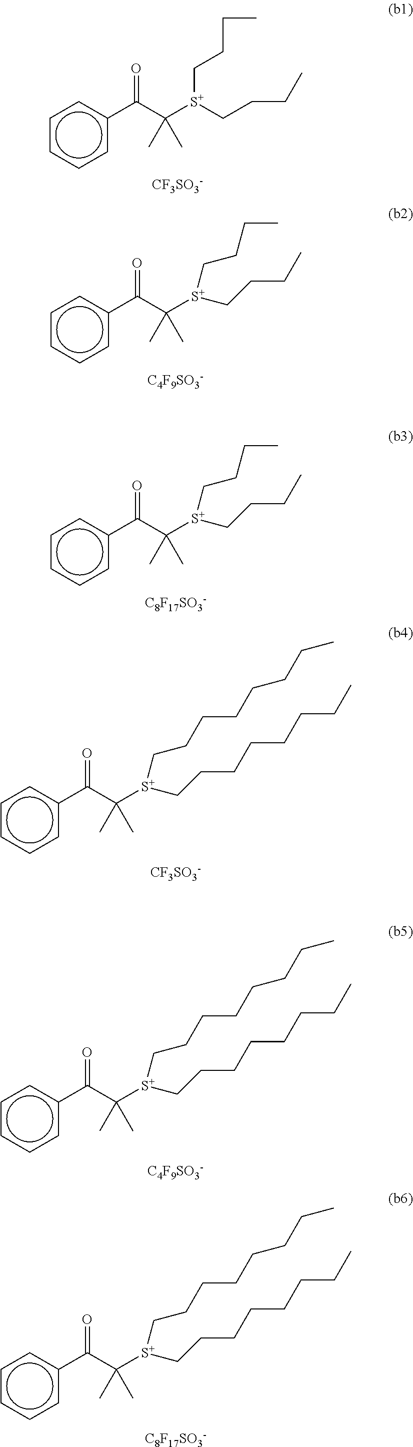

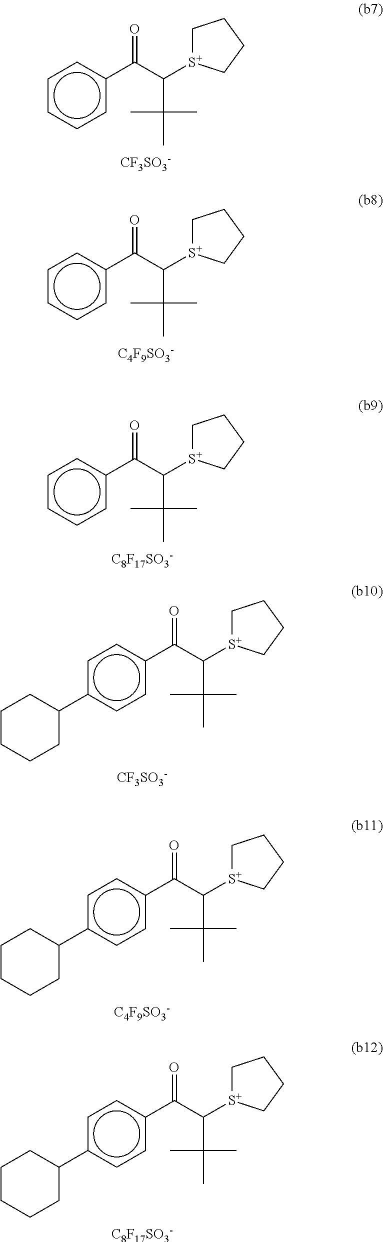

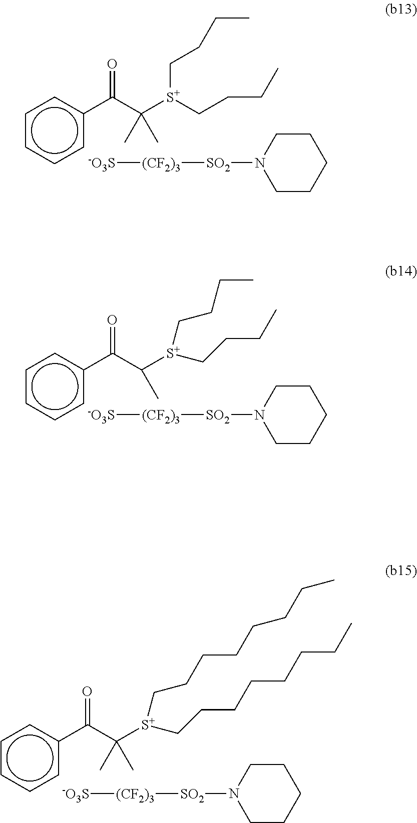

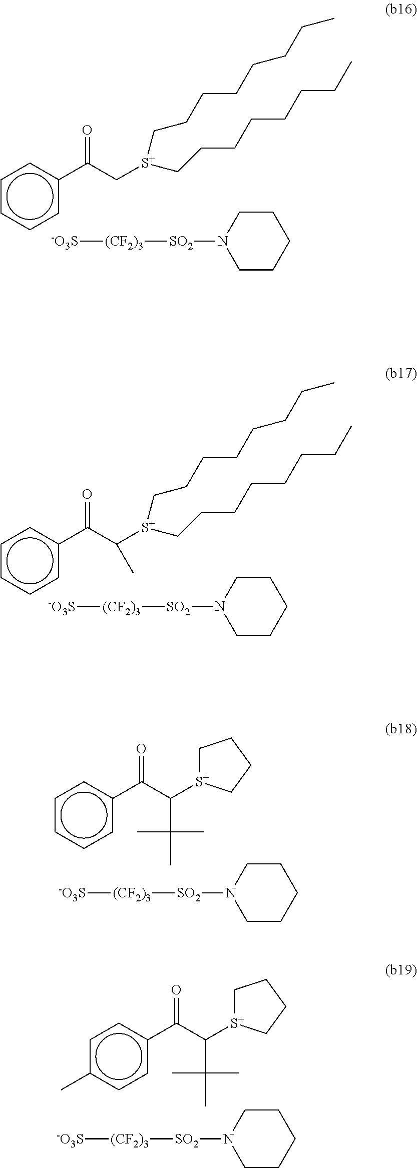

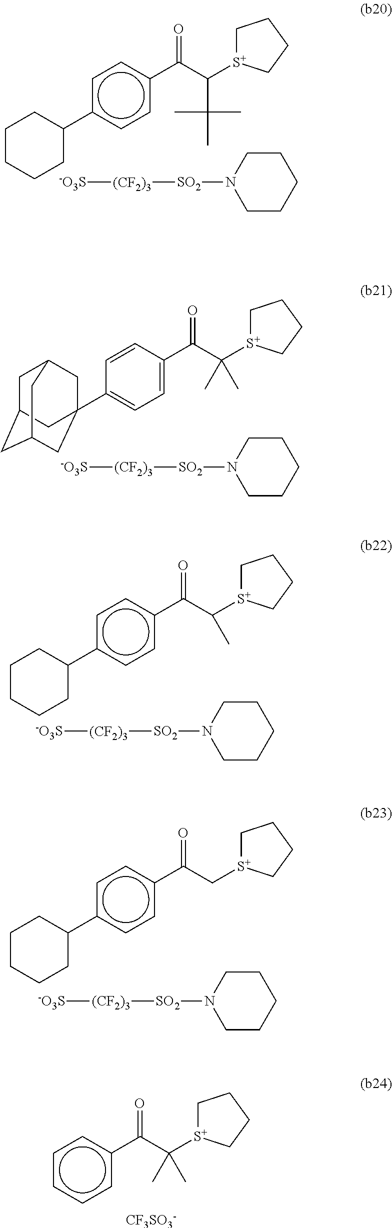

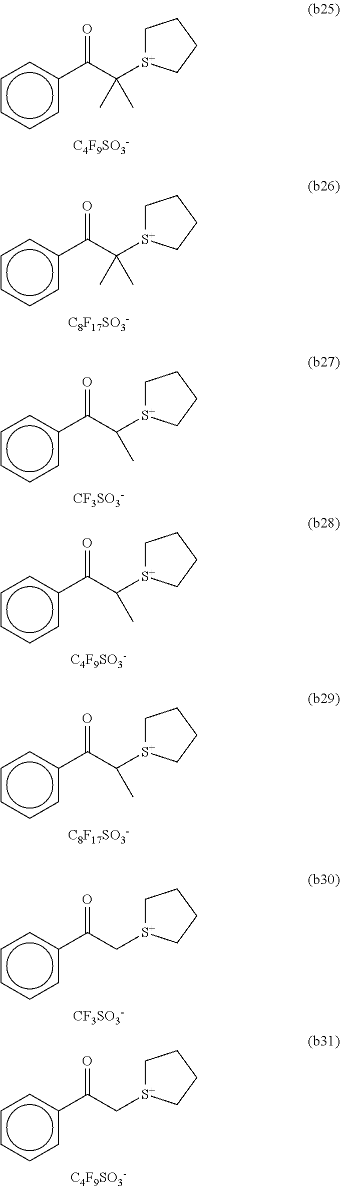

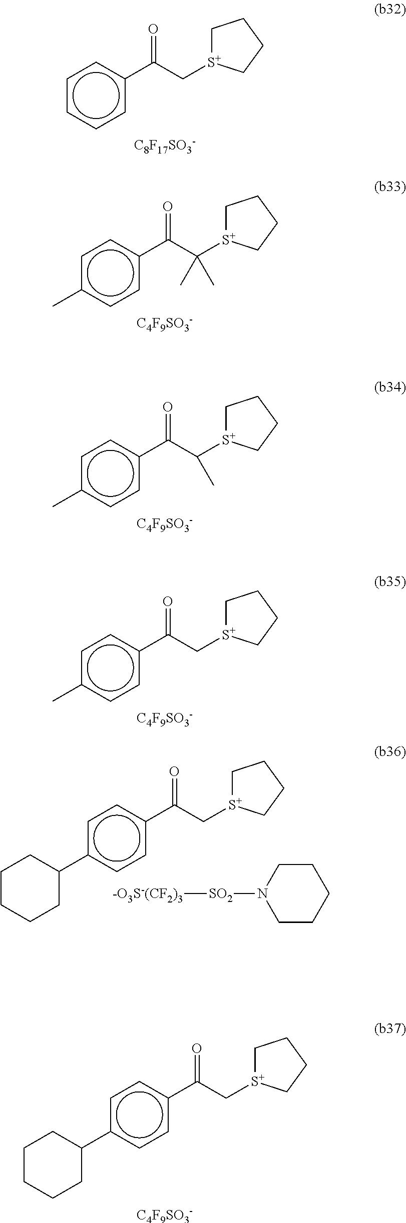

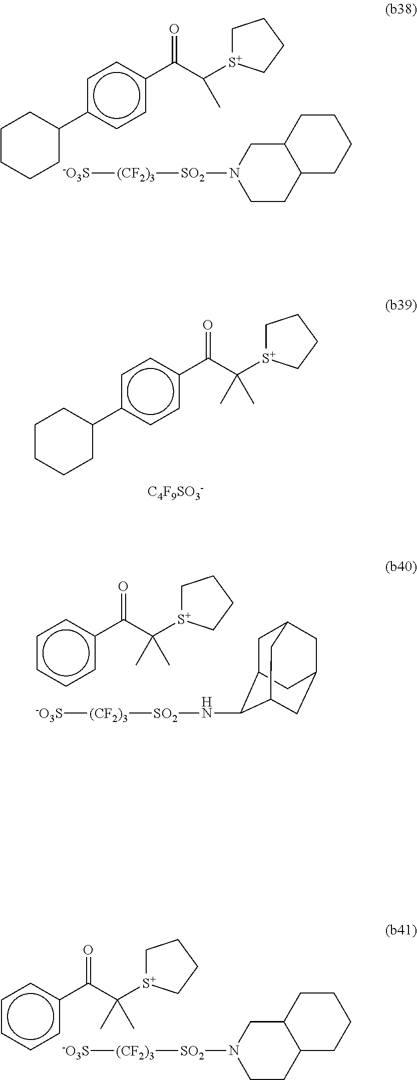

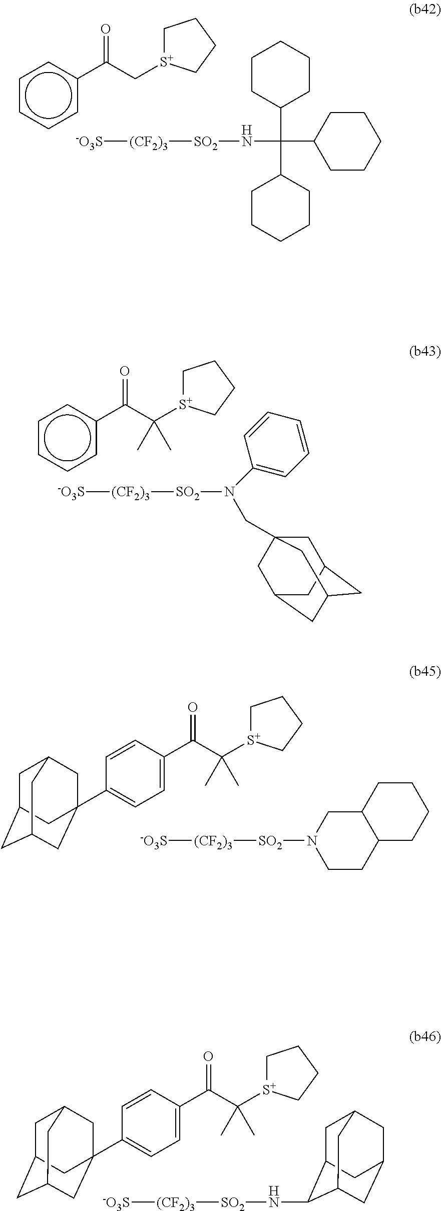

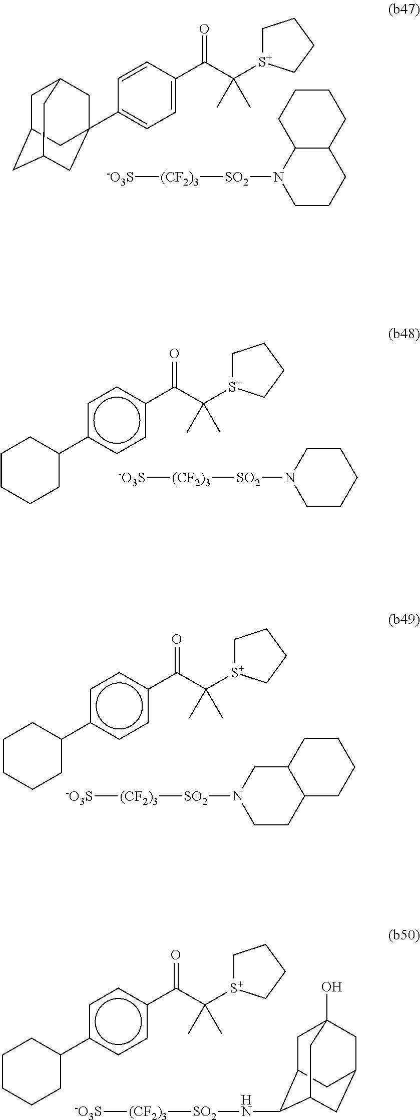

The compound (ZI-3) is used singly or in combination of two or more kinds thereof.

The compound (ZI-3) can be prepared in accordance with any method, for example, the method described in [0157] of JP2002-236359A, the method described in [0316] of JP2004-139014A, or the like. Particularly, the sulfonate anion represented by the general formula (III) can be prepared in accordance with the method described in, for example, [0362] to [0372] of JP2005-266766A.

The content of the compound (ZI-3) is preferably 3 to 30% by mass, more preferably 7 to 30% by mass, and still more preferably 7 to 25% by mass, based on all the solids of the composition.

Furthermore, the compound (ZI-3) in the present invention may also be used in combination with an acid generator (which is also referred to as an acid generator to be used with the other components), which is different form the compound (ZI-3).

The acid generator to be used with the other components is not particularly limited, but preferable examples thereof include compounds represented by the following general formulae (ZI′), (ZII′), and (ZIII′).

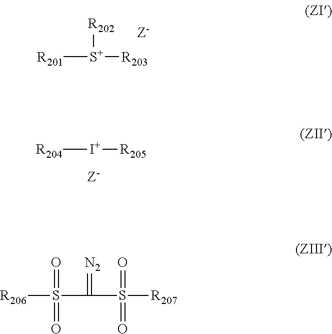

In the general formula (ZI′), each of R₂₀₁, R₂₀₂, and R₂₀₃ represents an organic group.

The number of carbon atoms of the organic group as any of R₂₀₁, R₂₀₂, and R₂₀₃ is generally 1 to 30, and preferably 1 to 20.

Furthermore, two of R₂₀₁ to R₂₀₃ may be bonded to form a ring structure, and an oxygen atom, a sulfur atom, an ester bond, an amide bond, or a carbonyl group may be contained in the ring. Examples of the ring formed by the mutual bonding of two of R₂₀₁ to R₂₀₃ include an alkylene group (for example, a butylene group and a pentylene group).

Z⁻ represents a non-nucleophilic anion (anion having an exceedingly low ability of causing a nucleophilic reaction).

Examples of Z⁻ include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, a tris(alkylsulfonyl)methide anion, and the like.

Specific examples and preferable examples of the sulfonate anion include the same as those of the sulfonate anion described above with respect to the sulfonate anion in the general formula (ZI-3).

Examples of the aliphatic moiety in the aliphatic carboxylate anion include the same as those in the sulfonate anion described above with respect to the sulfonate anion in the general formula (ZI-3).

Examples of the aromatic moiety in the aromatic carboxylate anion include the same as those in the sulfonate anion described above with respect to the sulfonate anion in the general formula (ZI-3).

Preferable examples of the aralkyl group in the aralkylcarboxylate anion include an aralkyl group having 6 to 12 carbon atoms, such as a benzyl group, a phenethyl group, a naphthylmethyl group, a naphthylethyl group, a naphthylbutyl group, and the like.

Examples of the sulfonylimide anion include a saccharin anion. The alkyl group of the bis(alkylsulfonyl)imido anion and the tris(alkylsulfonyl)methyl anion is preferably an alkyl group having 1 to 5 carbon atoms. Examples of the substituent of the alkyl group include a halogen atom, an alkyl group substituted with a halogen atom, an alkoxy group, an alkylthio group, an alkyloxysulfonyl group, an aryloxysulfonyl group, a cycloalkylaryloxysulfonyl group, and the like, with a fluorine atom or an alkyl group substituted with a fluorine atom being preferred.

Examples of the other Z⁻ include phosphorus fluoride (for example, PF₆⁻), boron fluoride (for example, BF₄⁻), antimony fluoride (for example, SbF₆⁻), and the like.

Z⁻ is preferably an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom, or a tris(alkylsulfonyl)methide anion whose alkyl group is substituted with a fluorine atom. The nonnucleophilic anion is more preferably a perfluorinated aliphatic sulfonate anion (more preferably having 4 to 8 carbon atoms) or a benzene sulfonate anion having a fluorine atom, and still more preferably a nonafluorobutane sulfonate anion, a perfluorooctane sulfonate anion, a pentafluorobenzene sulfonate anion, or a 3,5-bis(trifluoromethyl)benzene sulfonate anion.

From the viewpoint of acid strength, the pKa of the acid generated is preferably −1 or less in order to improve the sensitivity.

Examples of the organic groups represented by R₂₀₁, R₂₀₂, and R₂₀₃ include groups corresponding to the following compounds (ZI′-1) and (ZI′-2) as described later.

Further, a compound having a plurality of the structures of the general formula (ZI′) may be used. For example, a compound may have a structure wherein at least one of R₂₀₁ to R₂₀₃ of the compound of the general formula (ZI′) is bonded with at least one of R₂₀₁ to R₂₀₃ of another compound of the general formula (ZI′) via a single bond or a linking group.

More preferable examples of the (ZI′) component include the following compounds (ZI′-1) and (ZI′-2).

The compound (ZI′-1) is the arylsulfonium compound of the general formula (ZI′) wherein at least one of R₂₀₁ to R₂₀₃ is an aryl group, that is, a compound containing an arylsulfonium as a cation.

In the arylsulfonium compounds, all of R₂₀₁ to R₂₀₃ may be aryl groups, or R₂₀₁ to R₂₀₃ may be partially aryl groups and the remainder thereof may be alkyl groups or cycloalkyl groups, but it is preferable that all of R₂₀₁ to R₂₀₃ be aryl groups.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound, with the triarylsulfonium compound being preferred.

The aryl group of the arylsulfonium compound is preferably a phenyl group or a naphthyl group, and more preferably a phenyl group. The aryl group may be an aryl group having a heterocyclic structure, containing an oxygen atom, a nitrogen atom, a sulfur atom, or the like. Examples of the heterocyclic structure include a pyrrole residue, a furan residue, a thiophene residue, an indole residue, a benzofuran residue, a benzothiophene residue, and the like. In the case where the arylsulfonium compound has two or more aryl groups, the two or more aryl groups may be the same as or different from each other.

The alkyl group, or a cycloalkyl group which the arylsulfonium compound may have, if necessary, is preferably a linear or branched alkyl group having 1 to 15 carbon atoms or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, a cyclohexyl group, and the like.

The aryl group, the alkyl group, or the cycloalkyl group of R₂₀₁ to R₂₀₃ may have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group as a substituent. Examples of the preferable substituent include a linear or branched alkyl group having 1 to 12 carbon atoms, a cycloalkyl group having 3 to 12 carbon atoms, and a linear, branched, or cyclic alkoxy group having 1 to 12 carbon atoms, and more preferably an alkyl group having 1 to 4 carbon atoms and an alkoxy group having 1 to 4 carbon atoms. The substituent may be substituted with any one of the three groups, R₂₀₁ to R₂₀₃, or may be substituted with all of the three groups. Further, in the case where R₂₀₁ to R₂₀₃ are aryl groups, the substituent is preferably substituted at the p-position of the aryl group.

Next, the compound (ZI′-2) will be described.

The compound (ZI′-2) is a compound in which each of R₂₀₁ to R₂₀₃ in the formula (ZI′) independently represents an organic group having no aromatic ring. Here, the aromatic ring also includes an aromatic ring containing a heteroatom.

The organic group containing no aromatic ring as R₂₀₁ to R₂₀₃ generally contains 1 to 30 carbon atoms, and preferably 1 to 20 carbon atoms.

R₂₀₁ to R₂₀₃ each independently preferably represent an alkyl group, a cycloalkyl group, an allyl group, or a vinyl group, still more preferably a linear or branched 2-oxoalkyl group, a 2-oxocycloalkyl group, or an alkoxycarbonylmethyl group, and particularly preferably a linear or branched 2-oxoalkyl group.

Preferable examples of the alkyl group and the cycloalkyl group of R₂₀₁ to R₂₀₃ include a linear or branched alkyl group having 1 to 10 carbon atoms (for example, a methyl group, an ethyl group, a propyl group, a butyl group, and a pentyl group), and a cycloalkyl group having 3 to 10 carbon atoms (a cyclopentyl group, a cyclohexyl group, and a norbornyl group). More preferable examples of the alkyl group include a 2-oxoalkyl group and an alkoxycarbonylmethyl group, and more preferable examples of the cycloalkyl group include a 2-oxocycloalkyl group.

The 2-oxoalkyl group may be either linear or branched, and examples thereof include a group containing >C═O at the 2-position of the alkyl group.

The 2-oxocycloalkyl group is preferably the group containing >C═O at the 2-position of the cycloalkyl group.

Examples of the alkoxy group in the alkoxycarbonylmethyl group preferably include an alkoxy group having 1 to 5 carbon atoms (a methoxy group, an ethoxy group, a propoxy group, a butoxy group, and a pentoxy group).

R₂₀₁ to R₂₀₃ may be further substituted with a halogen atom, an alkoxyl group (for example, having 1 to 5 carbon atoms), a hydroxyl group, a cyano group, or a nitro group.

Next the general formulae (ZII′) and (ZIII′) will be described.

In the general formulae (ZII′) and (ZIII′),
each of R₂₀₄ to R₂₀₇ independently represents an aryl group, an alkyl group, or a cycloalkyl group.

The aryl group, the alkyl group, and the cycloalkyl group of R₂₀₄ to R₂₀₇ are the same as the aryl group described as the aryl group, the alkyl group, and the cycloalkyl group of R₂₀₁ to R₂₀₃ of the compound (ZI′-1) as described above.

The aryl group, the alkyl group, and the cycloalkyl group of R₂₀₄ to R₂₀₇ may have a substituent. Examples of the substituent include those which may be contained in the aryl group, the alkyl group, and the cycloalkyl group of R₂₀₁ to R₂₀₃ of the compound (ZI′-1).

Z⁻ represents a non-nucleophilic anion, and examples thereof include the same as those in Z⁻ in the general formula (ZI′).

Further examples of the acid generator to be used with the other components, which can be used in combination with the compound (ZI-3) in the present invention include compounds represented by the following general formulae (ZIV′), (ZV′), and (ZVI′).

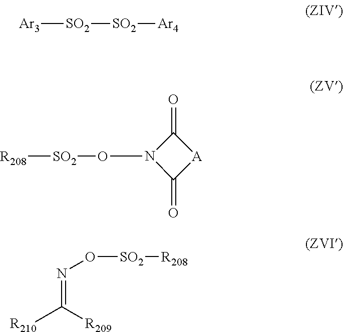

In the general formulae (ZIV′) to (ZVI′),
each of Ar₃ and Ar₄ independently represents an aryl group,
each of R₂₀₈, R₂₀₉, and R₂₁₀ independently represents an alkyl group, a cycloalkyl group, or an aryl group, and
A represents an alkylene group, an alkenylene group, or an arylene group.

Specific examples of the aryl group of Ar₃, Ar₄, R₂₀₈, R₂₀₉, and R₂₁₀ include the same as those of the aryl group as R₂₀₁, R₂₀₂, and R₂₀₃ in the general formula (ZI′-1).

Specific examples of the alkyl group and the cycloalkyl group of R₂₀₈, R₂₀₉, and R₂₁₀ include the same as those of the alkyl group and the cycloalkyl group as R₂₀₁, R₂₀₂, and R₂₀₃ in the general formula (ZI′-2).

Examples of the alkylene group of A include an alkylene group having 1 to 12 carbon atoms (for example, a methylene group, an ethylene group, a propylene group, an isopropylene group, a butylene group, an isobutylene group, and the like); examples of the alkenylene group of A include an alkenylene group having 2 to 12 carbon atoms (for example, an ethenylene group, a propenylene group, a butenylene group, and the like); and examples of the arylene group of A include an arylene group having 6 to 10 carbon atoms (for example, a phenylene group, a tolylene group, a naphthylene group, and the like).

Particularly preferable examples of the acid generator to be used in combination with the other components, which can be used in combination with the compound (ZI′-3) of the present invention will be shown below.

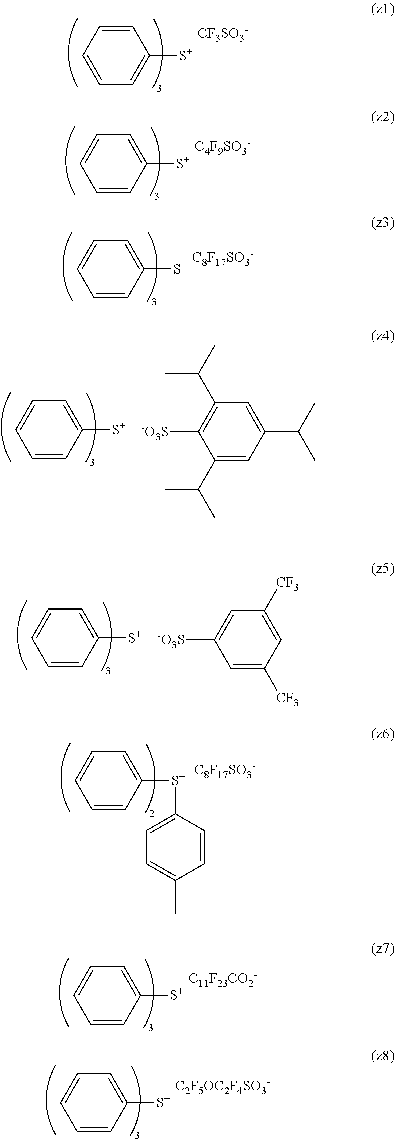

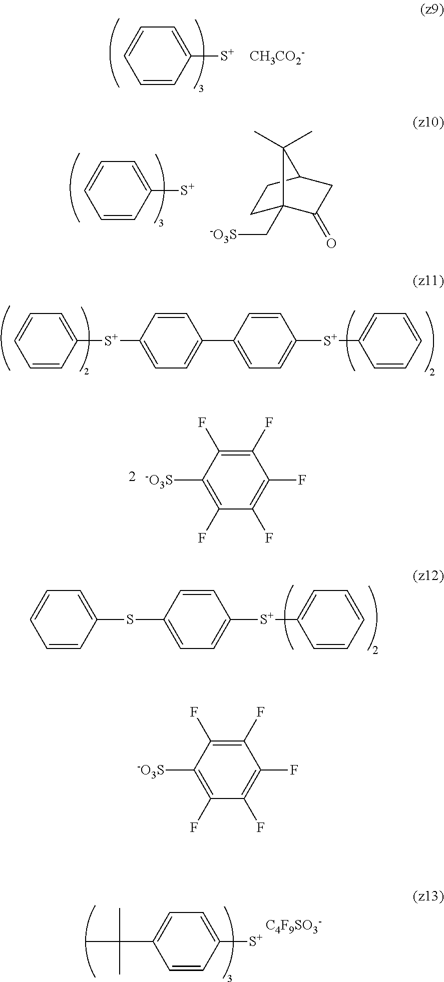

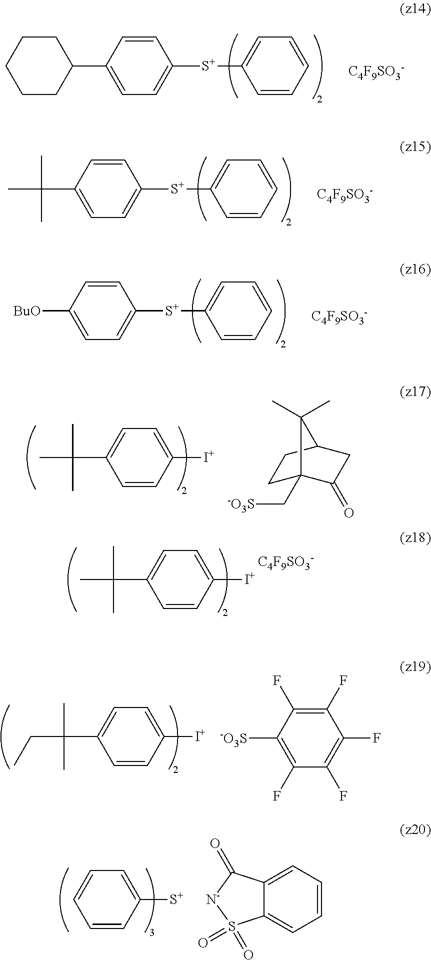

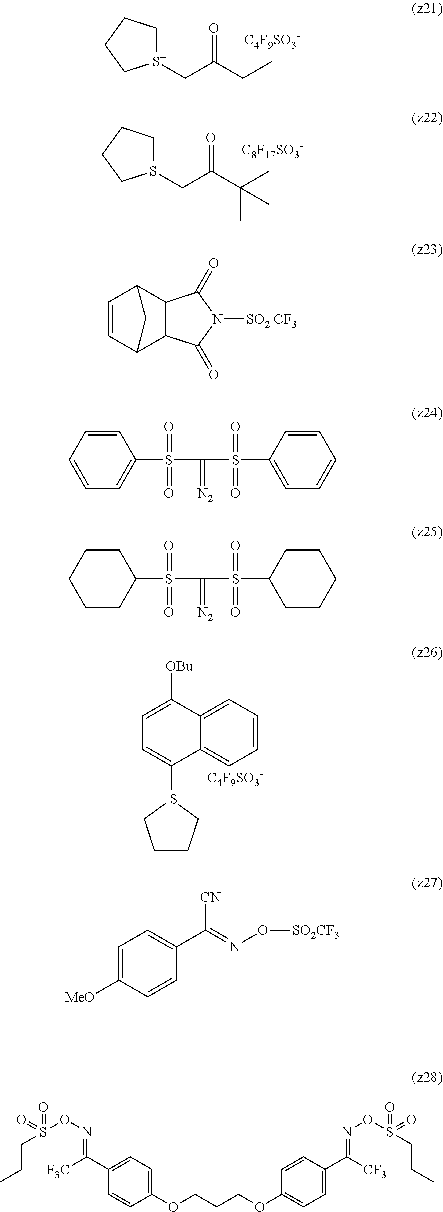

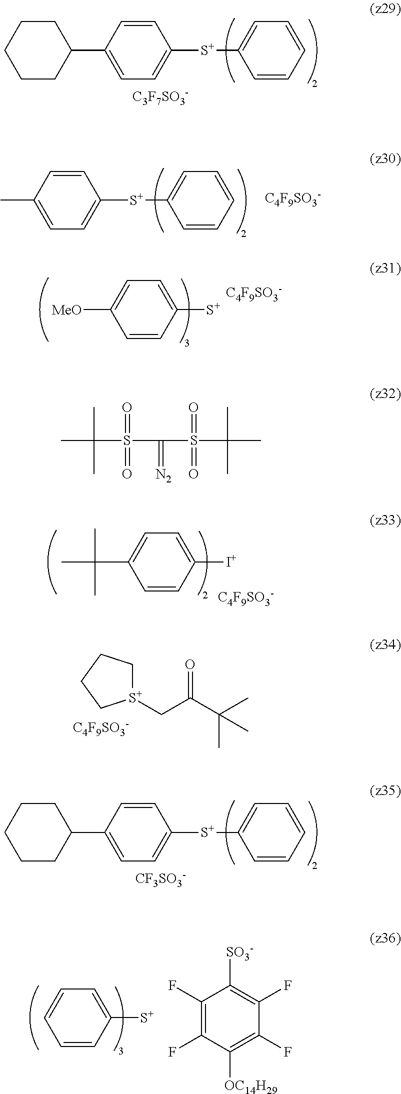

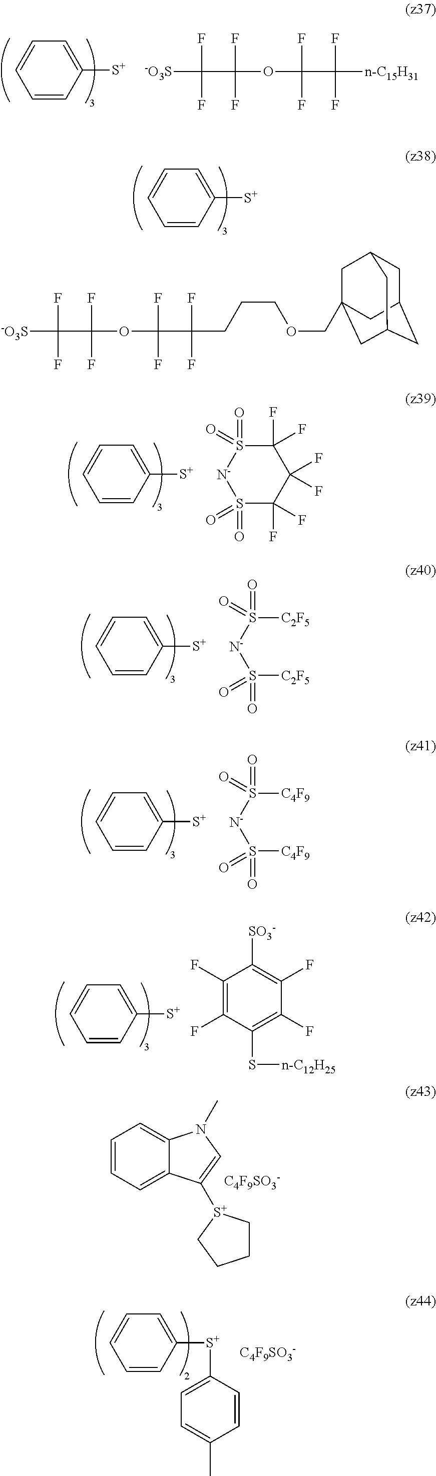

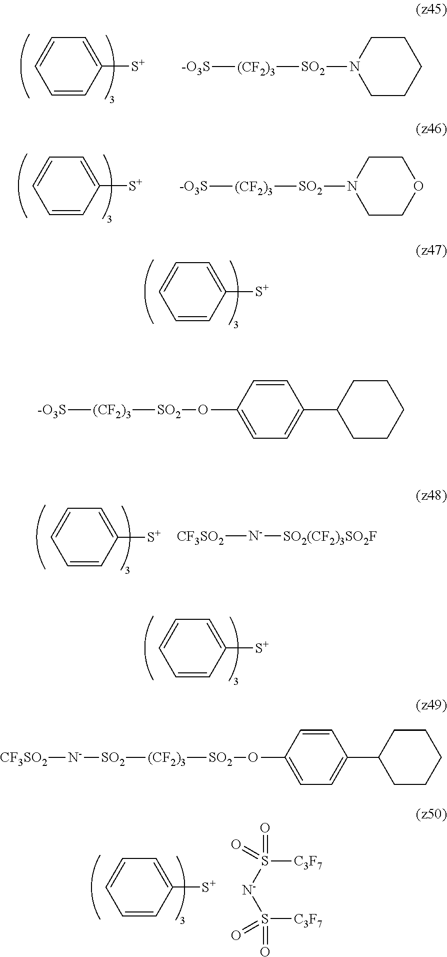

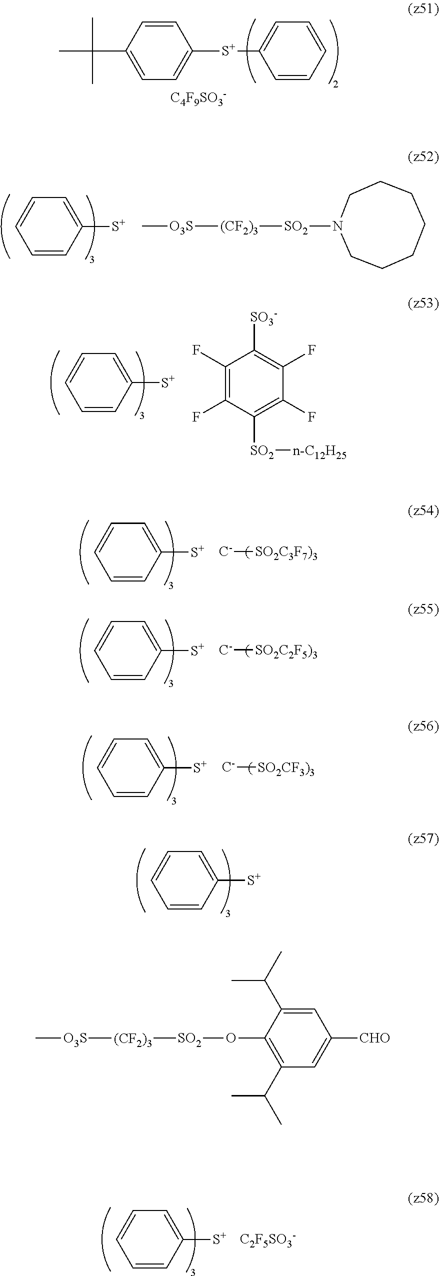

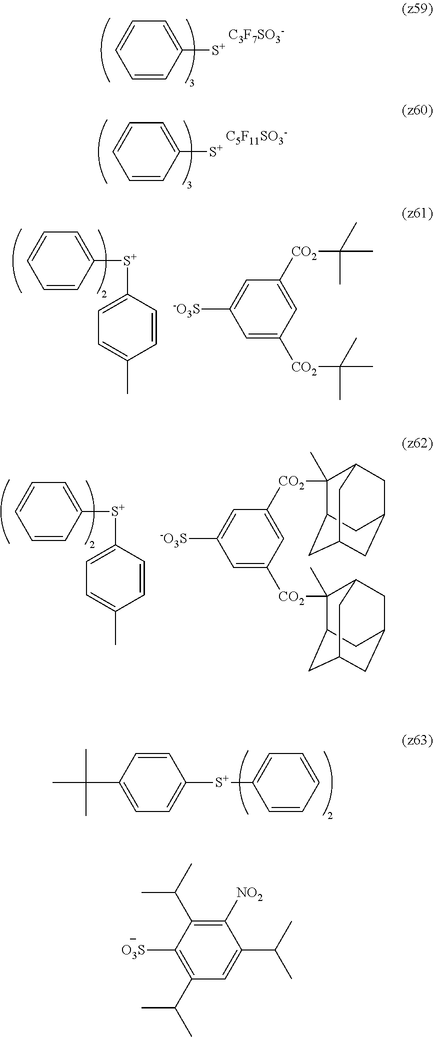

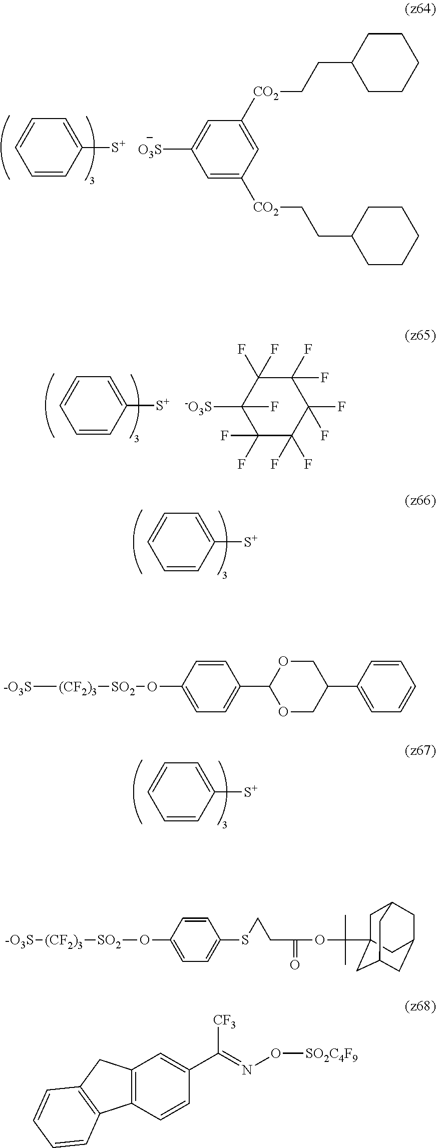

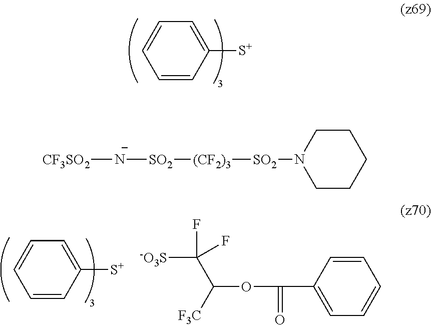

The content of the acid generator which can be used in combination of the compound (ZI-3) in the present invention in the entire composition is preferably from 0.1 to 30% by mass, more preferably from 0.5 to 25% by mass, and still more preferably 5 to 20% by mass, based on all the solids.

The amount of the acid generator when an acid generator to be used in combination with the other components, besides the compound (ZI-3) and the compound (ZI-3) is usually from 99/1 to 20/80, preferably 99/1 to 40/60, and still more preferably 99/1 to 50/50, in terms of a molar ratio (compound (ZI-3)/acid generator to be used in combination with the other components).

[3] Hydrophobic Resin (C)

The actinic-ray-sensitive or radiation-sensitive resin composition of the present invention may include a hydrophobic resin (C).

The resin (C) preferably contains at least any one of a fluorine atom and a silicon atom. At least any one of such a fluorine atom and a silicon atom in the resin (C) may be contained in the main chain or the side chain of the resin.

In the case where the resin (C) contains a fluorine atom, the fluorine atom-containing partial structure is preferably a resin having a fluorine atom-containing alkyl group, a fluorine atom-containing cycloalkyl group, or a fluorine atom-containing aryl group.

The alkyl group containing a fluorine atom is a linear or branched alkyl group in which at least one hydrogen atom is substituted with a fluorine atom, preferably having 1 to 10 carbon atoms, and more preferably 1 to 4 carbon atoms, and may have another substituent.

The cycloalkyl group containing a fluorine atom is a monocyclic or polycyclic cycloalkyl group in which at least one hydrogen atom is substituted with a fluorine atom, and may have another substituent.

Examples of the fluorine atom-containing aryl group include an aryl group such as a phenyl, a naphthyl group, and the like, in which at least one hydrogen atom is substituted with a fluorine atom, and may have another substituent.

Preferable examples of the fluorine atom-containing alkyl group, the fluorine atom-containing cycloalkyl group, and the fluorine atom-containing aryl group include a group represented by any one of the following general formulae (F2) to (F4), but the present invention is not limited thereto.

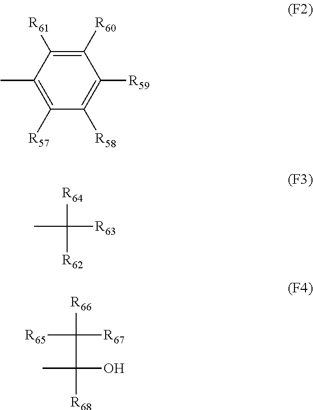

In the general formulae (F2) to (F4),
each of R₅₇ to R₆₈ independently represents a hydrogen atom, a fluorine atom, or an (linear or branched) alkyl group, provided that at least one of R₅₇ to R₆₁, at least one of R₆₂ to R₆₄, and at least one of R₆₅ to R₆₈ represents a fluorine atom, or an alkyl group (preferably having 1 to 4 carbon atoms) having at least one hydrogen atom thereof substituted with a fluorine atom.

It is preferable that all of R₅₇ to R₆₁ and R₆₅ to R₆₇ be fluorine atoms. R₆₂, R₆₃, and R₆₈ are preferably fluoroalkyl groups (preferably having 1 to 4 carbon atoms), and more preferably perfluoroalkyl groups having 1 to 4 carbon atoms. When R₆₂ and R₆₃ are perfluoroalkyl groups, R₆₄ is preferably a hydrogen atom. R₆₂ and R₆₃ may be bonded to each other to form a ring.

Specific examples of the group represented by the general formula (F2) include a p-fluorophenyl group, a pentafluorophenyl group, a 3,5-di(trifluoromethyl)phenyl group and the like.

Specific examples of the group represented by the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. A hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferred, and a hexafluoroisopropyl group and a heptafluoroisopropyl group are more preferred.

Specific examples of the group represented by the general formula (F4) include —C(CF₃)₂OH, —C(C₂F₅)₂OH, —C(CF₃)(CF₃)OH, —CH(CF₃)OH, and the like, and —C(CF₃)₂OH is preferred.

The fluorine atom-containing partial structure may be bonded directly to the main chain or may be bonded to the main chain through a group selected from the group consisting of an alkylene group, a phenylene group, an ether bond, a thioether bond, a carbonyl group, an ester bond, an amide bond, a urethane bond, and a ureylene bond, or a group formed by combination of two or more of these groups and bonds.

Examples of the preferable fluorine atom-containing repeating unit will be shown below.

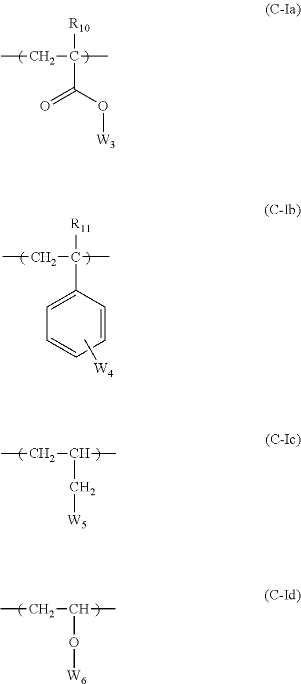

In the formulae, each of R₁₀ and R₁₁ independently represents a hydrogen atom, a fluorine atom, or an alkyl group. The alkyl group is preferably a linear or branched alkyl group having 1 to 4 carbon atoms, and may have a substituent, and examples of the alkyl group having a substituent includes, in particular, a fluorinated alkyl group.

Each of W₃ to W₆ independently represents an organic group having at least one or more fluorine atoms. Specific examples thereof include the atomic groups of (F2) to (F4) above.

Furthermore, the resin (C) may further contain, in addition to these, the units as shown below, as a fluorine atom-containing repeating unit.

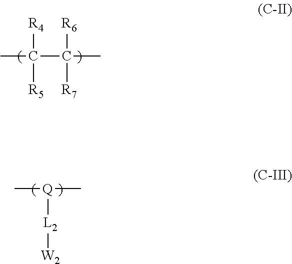

In the formulae, each of R₄ to R₇ independently represents a hydrogen atom, a fluorine atom, or an alkyl group. The alkyl group is preferably a linear or branched alkyl group having 1 to 4 carbon atoms and may have a substituent, and examples of the alkyl group having a substituent includes, in particular, a fluorinated alkyl group.

However, at least one of R₄ to R₇ represents a fluorine atom. R₄ and R₅ or R₆ and R₇ may form a ring.

W₂ represents an organic group containing at least one fluorine atom. Specific examples thereof include the atomic groups of (F2) to (F4) above.

L₂ represents a single bond or a divalent linking group. The divalent linking group is a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or an alkyl group), —NHSO₂—, or a divalent linking group formed by combination of a plurality of these groups.

Q represents an alicyclic structure. The alicyclic structure may have a substituent and may be monocyclic or polycyclic, and in the case of a polycyclic structure, the structure may be a crosslinked structure. The monocyclic structure is preferably a cycloalkyl group having 3 to 8 carbon atoms, and examples thereof include a cyclopentyl group, a cyclohexyl group, a cyclobutyl group, a cyclooctyl group, and the like. Examples of the polycyclic structure include a group containing a bicyclo structure, a tricyclo structure, a tetracyclo structure, and the like, having 5 or more carbon atoms. A cycloalkyl group having 6 to 20 carbon atoms is preferred, and examples thereof include an adamantyl group, a norbornyl group, a dicyclopentyl group, a tricyclodecanyl group, a tetracyclododecyl group, and the like. A part of carbon atoms in the cycloalkyl group may be substituted with a heteroatom such as an oxygen atom and the like. Particularly preferable examples of Q include a norbornyl group, a tricyclodecanyl group, a tetracyclododecyl group, and the like.

The resin (C) may contain a silicon atom.

The resin preferably has an alkylsilyl structure (preferably a trialkylsilyl group) or a cyclic siloxane structure as the silicon atom-containing partial structure.

Specific examples of the alkylsilyl structure and the cyclic siloxane structure include the groups represented by the following general formulae (CS-1) to (CS-3), and the like.

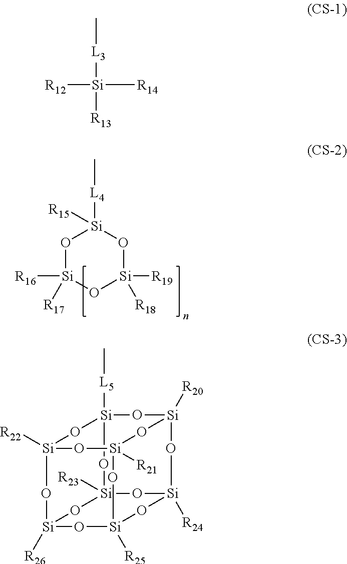

In the general formulae (CS-1) to (CS-3),
each of R₁₂ to R₂₆ independently represents a linear or branched alkyl group (preferably having 1 to 20 carbon atoms) or a cycloalkyl group (preferably having 3 to 20 carbon atoms),
each of L₃ to L₅ represents a single bond or a divalent linking group, and examples of the divalent linking group include a sole group or a combination of two or more groups selected from the group consisting of an alkylene group, a phenylene group, an ether bond, a thioether bond, a carbonyl group, an ester bond, an amide bond, a urethane bond, and a ureylene bond, and
n represents an integer of 1 to 5, and n is preferably an integer of 2 to 4.

The repeating unit having at least either a fluorine atom or a silicon atom is preferably a (meth)acrylate-based repeating unit.

Specific examples of the repeating unit having at least either a fluorine atom or a silicon atom will be shown below, but the present invention is not limited thereto. Further, in the specific examples, X₁ represents a hydrogen atom, —CH₃, —F, or —CF₃, and X₂ represents —F or —CF₃.

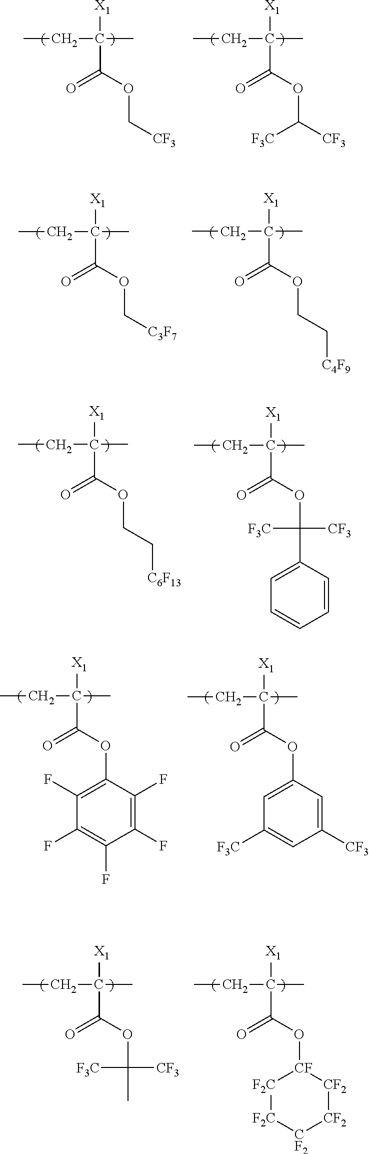

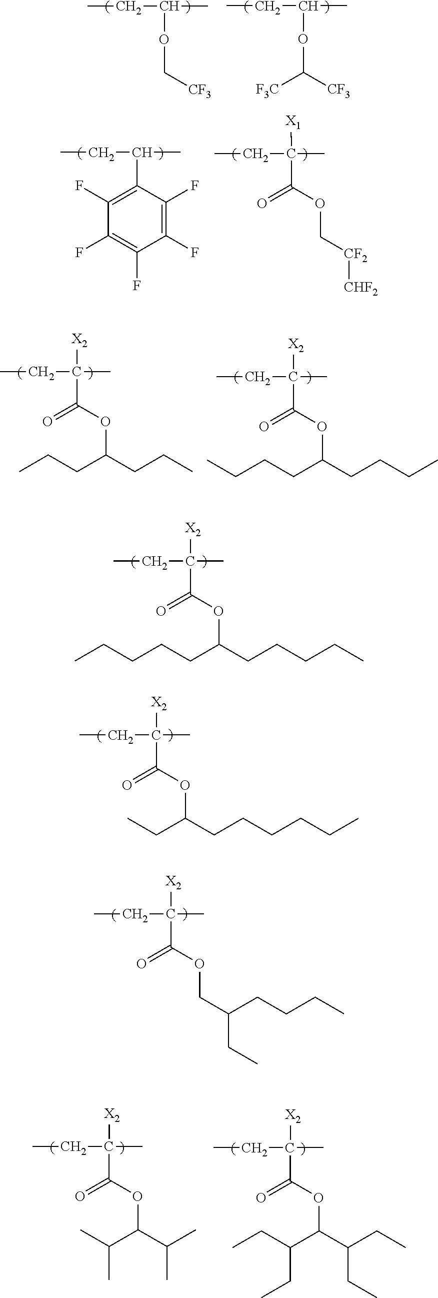

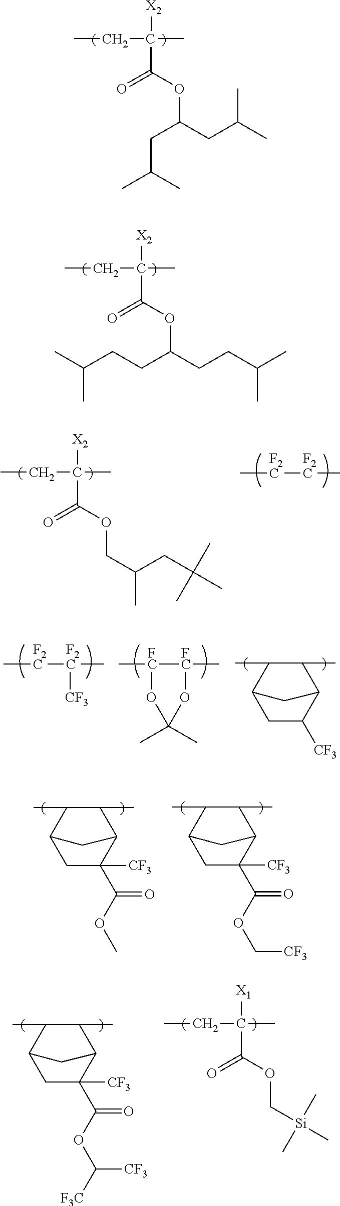

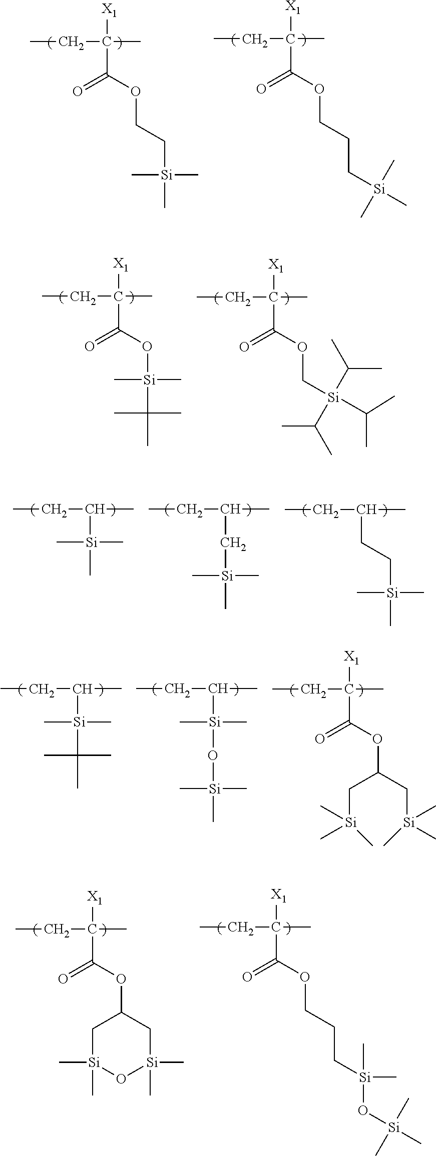

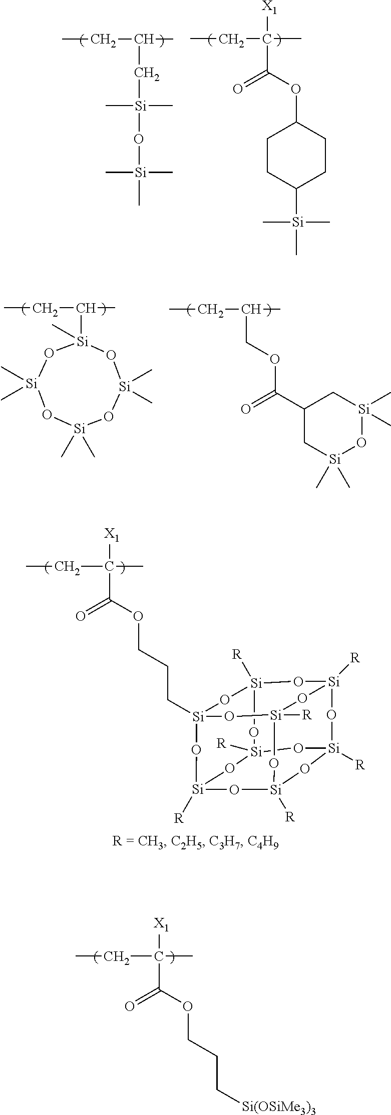

The resin (C) preferably contains (b) a repeating unit having at least one group selected from the group consisting of following (x) to (z):
(x) an alkali-soluble group,
(y) a group which decomposes by the action of an alkaline developer to increase the solubility in an alkaline developer (hereinafter also referred to as “polarity converting group”), and
(z) a group which decomposes by the action of an acid to increase the solubility in an alkaline developer.

The repeating unit (b) includes the following types.
(b′) a repeating unit having at least either a fluorine atom or a silicon atom and at least one group selected from the group consisting of (x) to (z) above, on one side chain,
   (b*) a repeating unit having at least one group selected from the group consisting of (x) to (z) above and having neither a fluorine atom nor a silicon atom, and
   (b″) a repeating unit having at least one group selected from the group consisting of (x) to (z) above on one side chain and at the same time, having at least either a fluorine atom or a silicon atom on a side chain different from the side chain above in the same repeating unit.

The resin (C) more preferably contains a repeating unit (b′) as the repeating unit (b). That is, it the repeating unit (b) having at least one group selected from the group consisting of (x) to (z) above still more preferably has at least either a fluorine atom or a silicon atom.

In the case where the resin (C) contains the repeating unit (b*), the resin is preferably a copolymer with a repeating unit having at least either a fluorine atom or a silicon atom (a repeating unit different from the repeating units (b′) and (b″) above). Further, in the repeating unit (b″), the side chain having at least one group selected from the group consisting of (x) to (z) and the side chain having at least either a fluorine atom or a silicon atom are preferably bonded to the same carbon atom in the main chain, that is, have a positional relationship like the following formula (K1).

In the formula, B1 represents a partial structure having at least one group selected from the group consisting of (x) to (z), and B2 represents a partial structure having at least either a fluorine atom or a silicon atom.

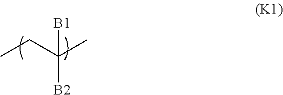

The group selected from the group consisting of (x) to (z) is preferably (x) an alkali-soluble group or a polarity converting group (y), and more preferably a polarity converting group (y).

Examples of the alkali-soluble group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group, and the like.

Preferred alkali-soluble groups include a fluorinated alcohol group (preferably hexafluoroisopropanol), a sulfonimido group and a bis(carbonyl)methylene group.

The repeating unit (bx) having (x) an alkali-soluble group contains a repeating unit where an alkali-soluble group is directly bonded to the main chain of the resin, such as a repeating unit of an acrylic acid or a methacrylic acid; a repeating unit where an alkali-soluble group is bonded to the main chain of the resin through a linking group; and the like. Further, an alkali-soluble group may be introduced into the polymer chain terminal by using an alkali-soluble group-containing polymerization initiator or chain transfer agent at the polymerization. All of these cases are preferable.

In the case where the repeating unit (bx) is a repeating unit having at least either a fluorine atom or a silicon atom (that is, a repeating unit corresponding to the repeating unit (b′) or (b″)), examples of the fluorine atom-containing partial structure in the repeating unit (bx) are the same as those in the above-described repeating unit having at least either a fluorine atom or a silicon atom, and the groups represented by the general formulae (F2) to (F4) are preferred. Further, examples of the silicon atom-containing partial structure in the repeating unit (bx) include the same as those in the above-described repeating unit having at least either a fluorine atom or a silicon atom, and the groups represented by the general formulae (CS-1) to (CS-3) are preferred.

The content of the repeating unit (bx) having an alkali-soluble group (x) is preferably from 1 to 50 mol %, more preferably from 3 to 35 mol %, and still more preferably from 5 to 20 mol %, based on all the repeating units in the resin (C).

Specific examples of the repeating unit (bx) having (x) an alkali-soluble group are illustrated below, but the present invention is not limited thereto
In the formulae, Rx represents H, CH₃, CF₃, or CH₂OH

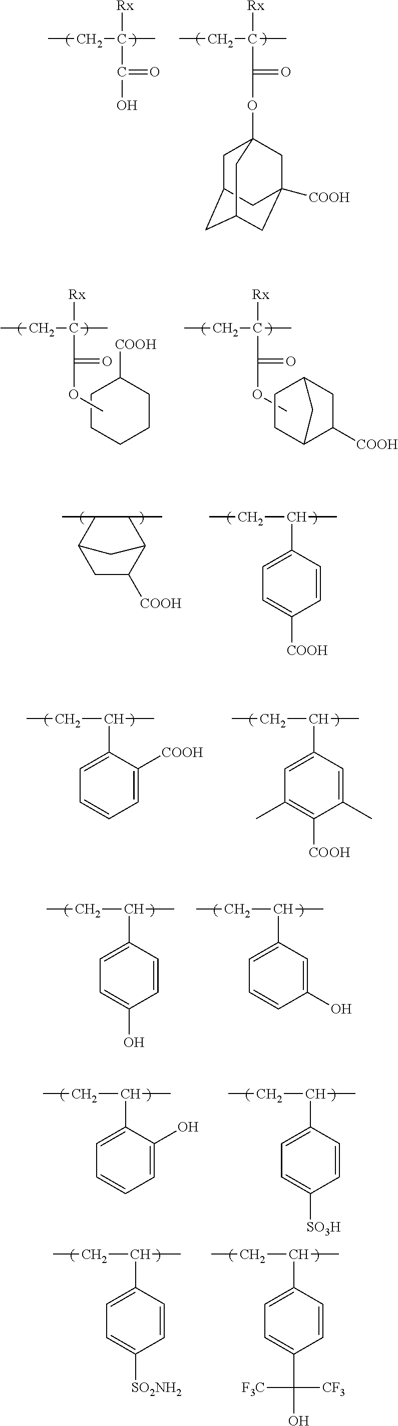

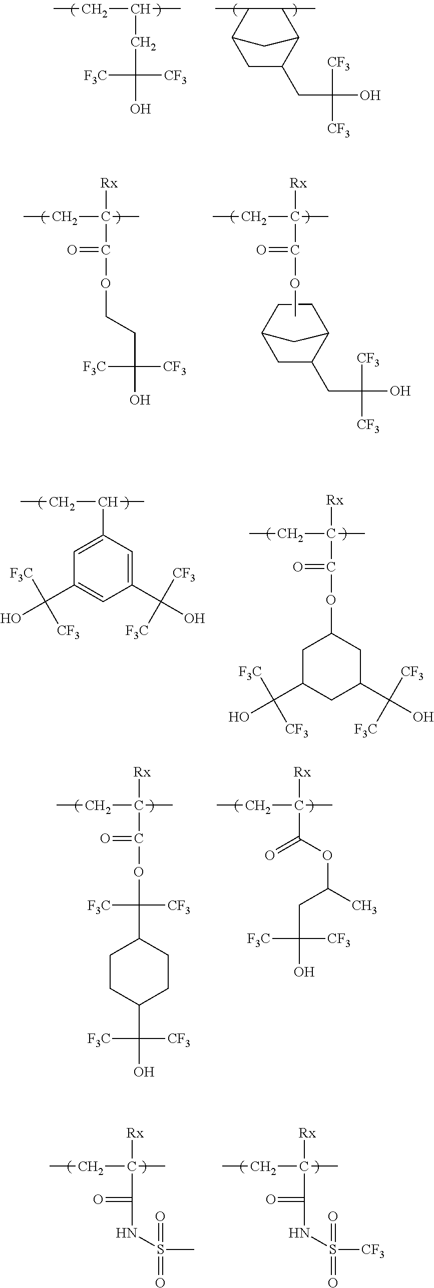

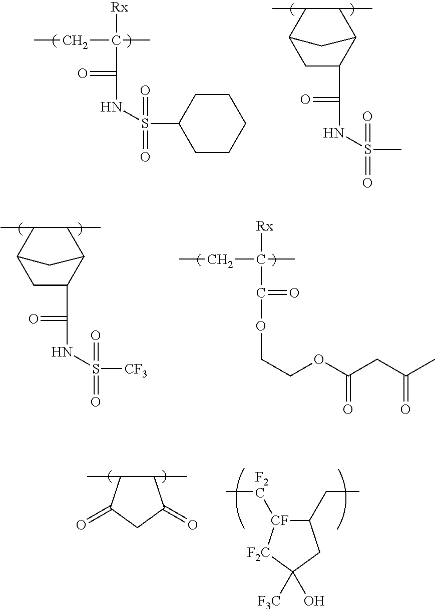

In the following formulae, X₁ represents H, CH₃, CF₃, or CH₂OH.

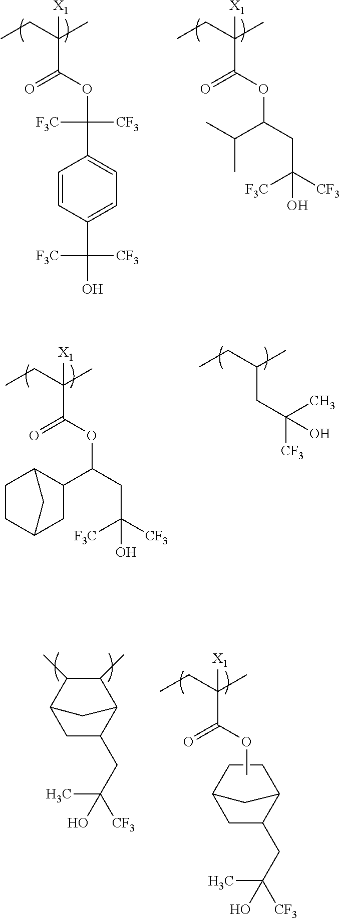

Examples of the polarity converting group (y) include a lactone group, a carboxylic ester group (—COO—), an acid anhydride group (—C(O)OC(O)—), an acid imido group (—NHCONH—), a carboxylic acid thioester group (—COS—), a carbonic ester group (—OC(O)O—), a sulfuric ester group (—OSO₂O—), a sulfonic ester group (—SO₂O), and the like, with a lactone group being preferred.

As for the polarity converting group (y), both of an embodiment where the group is contained, for example, in a repeating unit of an acrylic ester or a methacrylic ester and thereby is introduced into the side chain of the resin, and an embodiment where the group is introduced into the terminal of the polymer chain by using a polymerization initiator or chain transfer agent having a polarity converting group (y), are preferable.

Specific examples of the repeating unit (by) having a polarity converting group (y) include repeating units having a lactone structure represented by formulae (KA-1-1) to (KA-1-17) described later.

The repeating unit (by) having a polarity converting group (y) is preferably a repeating unit having at least either a fluorine atom or a silicon atom (that is, a repeating unit corresponding to the repeating unit (b′) or (b″)). The resin containing the repeating unit (by) has hydrophobicity, and this is preferable, particularly in view of reduction of development defect.

Examples of the repeating unit (by) include a repeating unit represented by the general formula (K0).

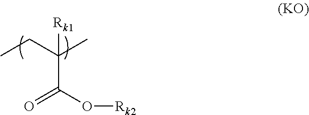

In the formula, Rₖ₁ represents a hydrogen atom, a halogen atom, a hydroxyl group, an alkyl group, a cycloalkyl group, an aryl group, or a polarity converting group-containing group, and
Rₖ₂ represents an alkyl group, a cycloalkyl group, an aryl group, or a polarity converting group-containing group.

However, at least either one of Rₖ₁ and Rₖ₂ represents a polarity converting group-containing group.

The polarity converting group indicates a group which decomposes by the action of an alkaline developer to increase the solubility in an alkaline developer, as described above. The polarity converting group is preferably a group X in a partial structure represented by the general formula (KA-1) or (KB-1)

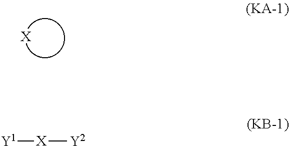

In general formulae (KA-1) and (KB-1),
X represents a carboxylic ester group: —COO—, an acid anhydride group: —C(O)OC(O)—, an acid imido group: —NHCONH—, a carboxylic acid thioester group: —COS—, a carbonic ester group: —OC(O)O—, a sulfuric ester group: —OSO₂O—, or a sulfonic ester group: —SO₂O—, and
each of Y¹ and Y² which may be the same as or different from each other, represents an electron-withdrawing group.

Moreover, the repeating unit (by) contains a group having a partial structure represented by the general formula (KA-1) or (KB-1) and thereby has a preferable group capable of increasing the solubility in an alkaline developer, and as in the case of the partial structure represented by the general formula (KA-1) or the partial structure represented by (KB-1) where Y¹ and Y² are monovalent, when the partial structure does not have a bond, the group having the partial structure is a group having a monovalent or higher valent group formed by removing at least one arbitrary hydrogen atom in the partial structure.

The partial structure represented by the general formula (KA-1) or (KB-1) is connected to the main chain of the resin (C) at an arbitrary position through a substituent.

The partial structure represented by the general formula (KA-1) is a structure forming a ring structure together with the group as X.

In the formula (KA-1), X is preferably a carboxylic ester group (that is, a case of forming a lactone ring structure as KA-1), an acid anhydride group or a carbonic ester group, and more preferably a carboxylic ester group.

The ring structure represented by the general formula (KA-1) may have a substituent and, for example, may have nka substituents Zₖₐ₁.

When a plurality of Zₖₐ₁'s are present, each of them independently represents a halogen atom, an alkyl group, a cycloalkyl group, an ether group, a hydroxyl group, an amido group, an aryl group, a lactone ring group or an electron-withdrawing group.

Zₖₐ₁'s may be combined with each other to form a ring. Examples of the ring formed by mutual linking of Zₖₐ₁'s include a cycloalkyl ring and a heterocyclic ring (for example, a cyclic ether ring, a lactone ring, and the like).

nka represents an integer of 0 to 10, preferably an integer of 0 to 8, more preferably an integer of 0 to 5, still more preferably an integer of 1 to 4, and most preferably an integer of 1 to 3.

The electron-withdrawing group as Zₖₐ₁ has the same meaning as the electron-withdrawing group of Y¹ and Y² as described later. The electron-withdrawing group above may be substituted with another electron-withdrawing group.

Zₖₐ₁ is preferably an alkyl group, a cycloalkyl group, an ether group, a hydroxyl group or an electron-withdrawing group, more preferably an alkyl group, a cycloalkyl group or an electron-withdrawing group. The ether group is preferably an ether group substituted, for example, with an alkyl group or a cycloalkyl group, that is, an alkyl ether group, or the like. The electron-withdrawing group has the same meaning as above.

Examples of the halogen atom as Zₖₐ₁ include a fluorine atom, a chlorine atom, a bromine atom, an iodine atom, and the like with a fluorine atom being preferred.

The alkyl group as Zₖₐ₁ may have a substituent and may be either linear or branched. The linear alkyl group is preferably an alkyl group having 1 to 30 carbon atoms, and more preferably 1 to 20 carbon atoms, and examples thereof include a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group, and the like. The branched alkyl group is preferably an alkyl group having 3 to 30 carbon atoms, and more preferably 3 to 20 carbon atoms, and examples thereof include an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanoyl group, and the like. An alkyl group having 1 to 4 carbon atoms, such as a methyl group, an ethyl group, an n-propyl group, an i-propyl group, an n-butyl group, an i-butyl group, a t-butyl group, and the like, is preferable.

The cycloalkyl group as Zₖₐ₁ may have a substituent and may be monocyclic or polycyclic, and in the case of polycyclic, the cycloalkyl group may be a crosslinked cycloalkyl group. That is, in this case, the cycloalkyl group may have a bridged structure. The monocyclic cycloalkyl group is preferably a cycloalkyl group having 3 to 8 carbon atoms, and examples thereof include a cyclopropyl group, a cyclopentyl group, a cyclohexyl group, a cyclobutyl group, a cyclooctyl group, and the like. The polycyclic cycloalkyl group includes a group having a bicyclo structure, a tricyclo structure, a tetracyclo structure, and the like and having 5 or more carbon atoms, and a cycloalkyl group having 6 to 20 carbon atoms is preferable. Examples thereof include an adamantyl group, a norbornyl group, an isobornyl group, a camphanyl group, a dicyclopentyl group, an α-pinel group, a tricyclodecanyl group, a tetracyclododecyl group, and an androstanyl group. As the cycloalkyl group, structures shown below are also preferable. Incidentally, a part of carbon atoms in the cycloalkyl group may be substituted for by a heteroatom such as an oxygen atom and the like.

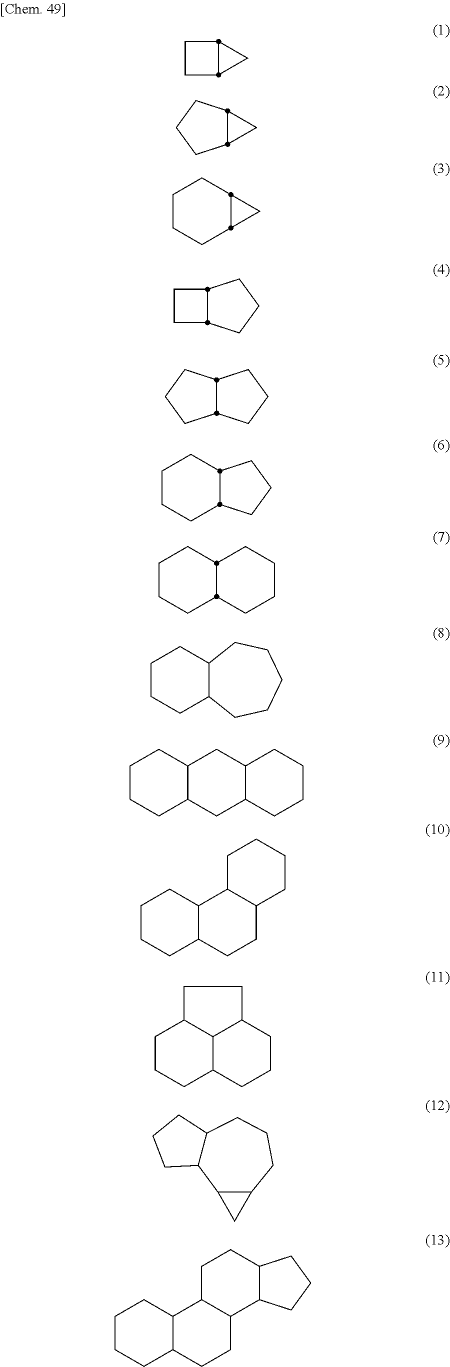

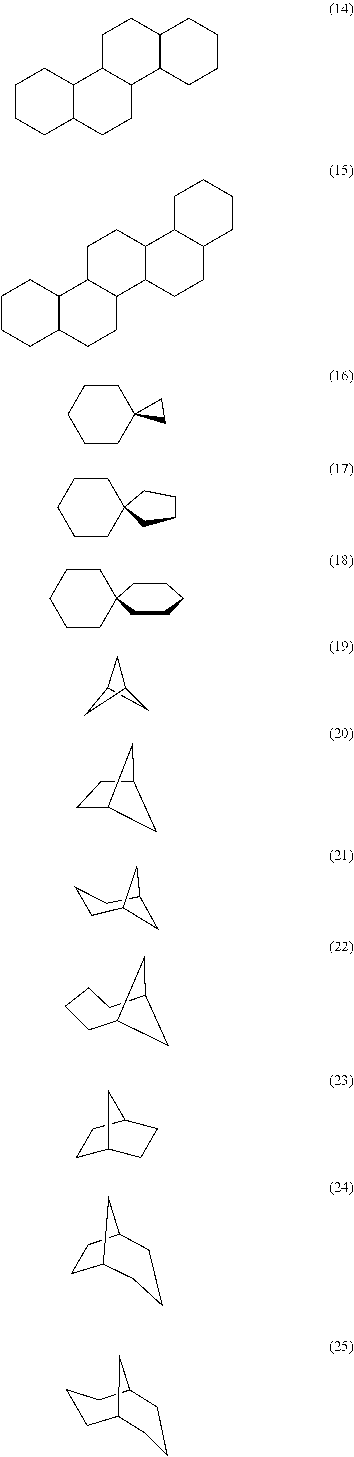

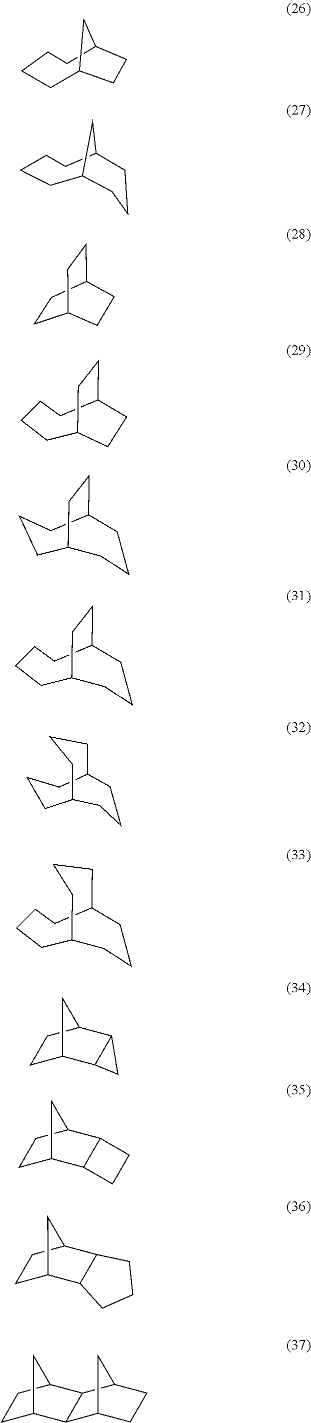

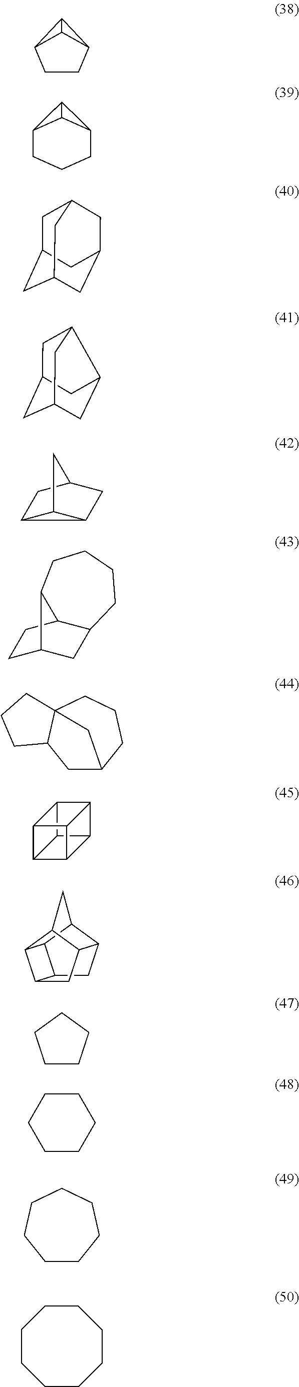

Preferable examples of the alicyclic moiety include an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group, and a cyclododecanyl group. An adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group are more preferred.

The substituent of the alicyclic structure includes an alkyl group, a halogen atom, a hydroxyl group, an alkoxy group, a carboxyl group and an alkoxycarbonyl group. The alkyl group is preferably a lower alkyl group such as a methyl group, an ethyl group, a propyl group, an isopropyl group, a butyl group, and the like, and more preferably a methyl group, an ethyl group, a propyl group or an isopropyl group. The alkoxy group is preferably an alkoxy group having 1 to 4 carbon atoms, such as a methoxy group, an ethoxy group, a propoxy group, a butoxy group, and the like. Examples of the substituent which the alkyl group and alkoxy group may have include a hydroxyl group, a halogen atom, an alkoxy group (preferably having 1 to 4 carbon atoms), and the like.

Furthermore, the groups above may further have a substituent, and examples of the further substituent include a hydroxyl group, a halogen atom (for example, fluorine, chlorine, bromine, and iodine), a nitro group, a cyano group, the above-described alkyl group, an alkoxy group such as a methoxy group, an ethoxy group, a hydroxyethoxy group, a propoxy group, a hydroxypropoxy group, an n-butoxy group, an isobutoxy group, a sec-butoxy group, a t-butoxy group, and the like, an alkoxycarbonyl group such as a methoxycarbonyl group, an ethoxycarbonyl group, and the like, an aralkyl group such as a benzyl group, a phenethyl group, a cumyl group, and the like, an acyl group such as an aralkyloxy group, a formyl group, an acetyl group, a butyryl group, a benzoyl group, a cinnamyl group, a valeryl group, and the like, an acyloxy group such as a butyryloxy group and the like, the above-described alkenyl group, an alkenyloxy group such as a vinyloxy group, a propenyloxy group, an allyloxy group, a butenyloxy group, and the like, the above-described aryl group, an aryloxy group such as a phenoxy group and the like, and an aryloxycarbonyl group such as a benzoyloxy group and the like.

It is preferable that X in the general formula (KA-1) be a carboxylic ester group and the partial structure represented by the general formula (KA-1) be a lactone ring, and preferably a 5- to 7-membered lactone ring.

Incidentally, it is preferable that as in (KA-1-1) to (KA-1-17) shown below, another ring structure is condensed to a 5- to 7-membered lactone ring as the partial structure represented by the general formula (KA-1) in the form of forming a bicyclo or spiro structure.

Examples of the peripheral ring structure with which the ring structure represented by the general formula (KA-1) may be combined include those in (KA-1-1) to (KA-1-17) shown below and structures based on these structures.

The structure containing a lactone ring structure represented by the general formula (KA-1) is more preferably a structure represented by any one of the following (KA-1-1) to (KA-1-17). Further, the lactone structure may be bonded directly to the main chain. Preferred structures are (KA-1-1), (KA-1-4), (KA-1-5), (KA-1-6), (KA-1-13), (KA-1-14), and (KA-1-17).

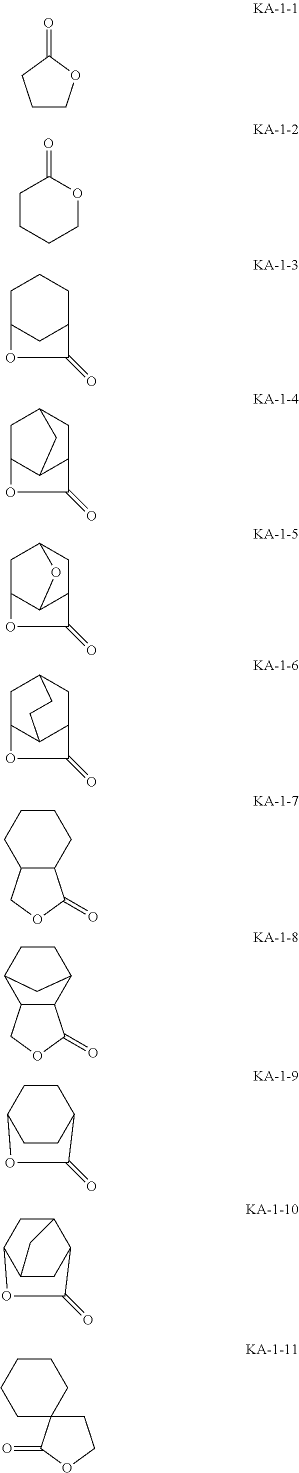

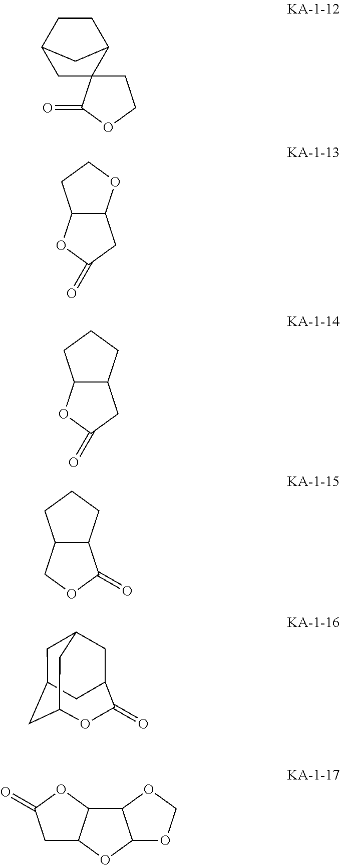

The structure containing the above-described lactone ring structure may or may not have a substituent. Preferable examples of the substituent are the same as those of the substituent Zₖₐ₁ which may be contained in the ring structure represented by the general formula (KA-1)

In the general formula (KB-1), X preferably includes a carboxylic ester group (—COO—).

In the general formula (KB-1), each of Y¹ and Y² independently represents an electron-withdrawing group.

The electron-withdrawing group is a partial structure represented by the following formula (EW). In the formula (EW), * represents a bond directly bonded to (KA-1) or a bond directly bonded to X in (KB-1).

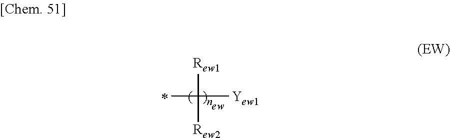

In the formula (EW),
n_{ew} is a repetition number of the linking group represented by —C(R_{ew1})(R_{ew2})—, and represents an integer of 0 or 1. In the case where n_{ew} is 0, this indicates bonding by a single bond and direct bonding of Y_{ew1}.

Y_{ew1} is a halogen atom, a cyano group, a nitrile group, a nitro group, a halo(cyclo)alkyl, a haloaryl group represented by —C(R_{f1})(R_{f2})—R_{f3}, an oxy group, a carbonyl group, a sulfonyl group, a sulfinyl group, or a combination thereof. Further, the electron-withdrawing group may be, for example, a structure shown below. The “halo(cyclo)alkyl group” indicates an alkyl or cycloalkyl group that is at least partially halogenated. The term “haloaryl group” indicates an aryl group that is at least partially halogenated. In the structural formulae below, each of R_{ew3} and R_{ew4} independently represents an arbitrary structure. The partial structure represented by the general formula (EW) has an electron-withdrawing property irrespective of structures of R_{ew3} and R_{ew4} and may be combined with, for example, the main chain of the resin, but is preferably an alkyl group, a cycloalkyl group, or an alkyl fluoride group.

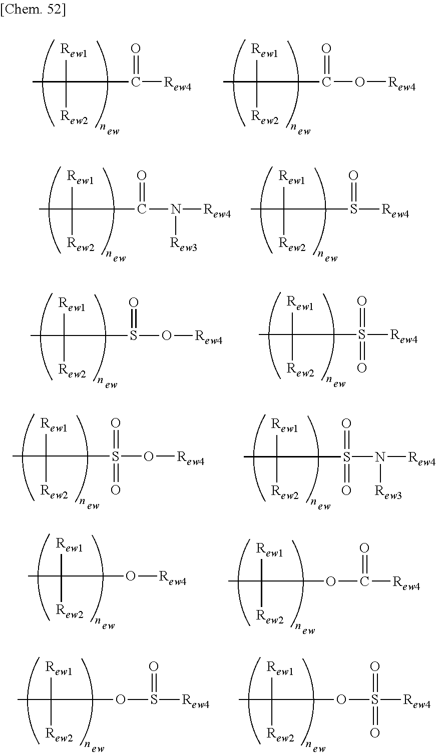

In the case where Y_{ew1} is a divalent or higher-valent group, the remaining bond forms bonding to an arbitrary atom or substituent. At least any one group of Y_{ew1}, R_{ew1}, and R_{ew2} may be combined with the main chain of a resin (C) through a further substituent.

Y_{ew1} is preferably a halogen atom, or a halo(cyclo)alkyl or haloaryl group represented by —C(R_{f1})(R_{f2})—R_{f3}.

Each of R_{ew1} and R_{ew2} independently represents an arbitrary substituent, and represents, for example, a hydrogen atom, an alkyl group, a cycloalkyl group, or an aryl group.

At least two of R_{ew1}, R_{ew2}, and Y_{ew1} may be combined with each other to form a ring.

Here, R_{f1} represents a halogen atom, a perhaloalkyl group, a perhalocycloalkyl group or a perhaloaryl group and is preferably a fluorine atom, a perfluoroalkyl group, or a perfluorocycloalkyl group, and more preferably a fluorine atom or a trifluoromethyl group.

Each of R_{f2} and R_{f3} independently represents a hydrogen atom, a halogen atom or an organic group, and R_{f2} and R_{f3} may be combined with each other to form a ring. Examples of the organic group include an alkyl group, a cycloalkyl group, an alkoxy group, and the like. R_{f2} preferably represents the same group as R_{f1} or is combined with R_{f3} to form a ring.

R_{f1} to R_{f3} may be combined with each other to form a ring, and examples of the ring formed include a (halo)cycloalkyl ring, a (halo)aryl ring, and the like.

Examples of the (halo)alkyl group in R_{f1} to R_{f3} include the alkyl groups in Zₖₐ₁ and halogenated structures thereof.

Examples of the (per)halocycloalkyl group and the (per)haloaryl group in the ring formed by combination of R_{f2} and R_{f3} in R_{f1} to R_{f3} include structures resulting from halogenation of cycloalkyl groups in Zₖₐ₁, and a fluoroalkyl group represented by —C₍ₙ₎F₍₂ₙ₋₂₎H and a perfluoroaryl group represented by —C₍ₙ₎F₍ₙ₋₁₎ are preferable, where the carbon number n is not particularly limited but is preferably from 5 to 13, and more preferably 6.

The ring which may be formed by combination of at least two of R_{ew1}, R_{ew2}, and Y_{ew1} with each other is preferably a cycloalkyl group or a heterocyclic group, and the heterocyclic group is preferably a lactone ring group. Examples of the lactone ring include structures represented by the formulae (KA-1-1) to (KA-1-17).

Incidentally, the repeating unit (by) may have a plurality of partial structures represented by the general formula (KA-1), a plurality of partial structures represented by the general formula (KB-1), or both a partial structure represented by the general formula (KA-1) and a partial structure represented by the general formula (KB-1).

Further, the partial structure of the general formula (KA-1) may partially or entirely serve also as the electron-withdrawing group of Y¹ or Y² in the general formula (KB-1). For example, in the case where X in the general formula (KA-1) is a carboxylic ester group, the carboxylic ester group may function as the electron-withdrawing group of Y¹ or Y² in the general formula (KB-1).

Moreover, in the case where the repeating unit (by) comes under the repeating unit (b*) or the repeating unit (b″) and has a partial structure represented by the general formula (KA-1), the partial structure represented by the general formula (KA-1) is more preferably a partial structure where the polarity converting group is —COO— in the structure represented by the general formula (KA-1). The repeating unit (by) is more preferably a repeating unit having a partial structure shown below.

The repeating unit (by) may be a repeating unit having a partial structure represented by the general formula (KY-0)

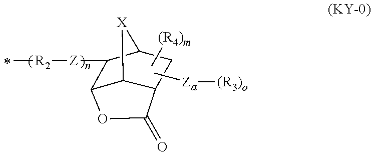

In the general formula (KY-0),
R₂ represents a chained or cyclic alkylene group and when a plurality of R₂'s are present, they may be the same as or different from each other,
R₃ represents a linear, branched, or cyclic hydrocarbon group where a part or all of hydrogen atoms on the constituent carbons are substituted with a fluorine atom,
R₄ represents a halogen atom, a cyano group, a hydroxyl group, an amido group, an alkyl group, a cycloalkyl group, an alkoxy group, a phenyl group, an acyl group, an alkoxycarbonyl group, or a group represented by R—C(═O)— or R—C(═O)O— (wherein R represents an alkyl group or a cycloalkyl group), and when a plurality of R₄'s are present, they may be the same as or different from each other, and two or more R₄'s may be bonded to each other to form a ring,
X represents an alkylene group, an oxygen atom, or a sulfur atom,
each of Z and Za represents a single bond, an ether bond, an ester bond, an amide bond, a urethane bond, or a urea bond, and when a plurality of Z's or Za's are present, they may be the same as or different from each other,
* represents a bond to the main chain or side chain of the resin.

o is the number of substituents and represents an integer of 1 to 7,
m is the number of substituents and represents an integer of 0 to 7, and
n is a repetition number and represents an integer of 0 to 5.

The structure of —R₂—Z— is preferably a structure represented by —(CH₂)₁—COO— (wherein 1 represents an integer of 1 to 5).

The preferable range of carbon number and specific examples of the chained or cyclic alkylene group as R₂ are the same as those described for the chained alkylene group and cyclic alkylene group in Z₂ of the general formula (bb).

The carbon number of the linear, branched, or cyclic hydrocarbon group as R₃ is, in the case of a linear hydrocarbon group, preferably from 1 to 30, and more preferably from 1 to 20, in the case of a branched hydrocarbon group, preferably from 3 to 30, and more preferably from 3 to 20, and in the case of a cyclic hydrocarbon group, from 6 to 20. Specific examples of R₃ include specific examples of the alkyl group and a cycloalkyl group as Zₖₐ₁.

The preferable carbon numbers and specific examples of the alkyl group and a cycloalkyl group as R₄ and R are the same as those described with respect to the alkyl group and the cycloalkyl group as Zₖₐ₁.

The acyl group as R₄ is preferably an acyl group having 1 to 6 carbon atoms, and examples thereof include a formyl group, an acetyl group, a propionyl group, a butyryl group, an isobutyryl group, a valeryl group, a pivaloyl group, and the like.

The alkyl moiety in the alkoxy group and the alkoxycarbonyl group as R₄ include a linear, branched, or cyclic alkyl moiety, and the preferable carbon number and specific examples of the alkyl moiety are the same as those described for the alkyl group and the cycloalkyl group of Zₖₐ₁.

The alkylene group as X includes a chained or cyclic alkylene group, and the preferable carbon number and specific examples thereof are the same as those described for the chained alkylene group and the cyclic alkylene group as R₂.

Further, the specific structure of the repeating unit (by) also contains a repeating unit having a partial structure shown below.

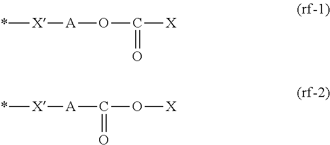

In the general formula (rf-1) and (rf-2),
X′ represents an electron-withdrawing substituent and is preferably a carbonyloxy group, an oxycarbonyl group, a fluorine atom-substituted alkylene group, or a fluorine atom-substituted cycloalkylene group,
A represents a single bond, a divalent linking group represented by —C(Rx)(Ry)-, wherein each of Rx and Ry independently represents a hydrogen atom, a fluorine atom, an alkyl group (preferably having 1 to 6 carbon atoms, which may be substituted with a fluorine atom or the like), or a cycloalkyl group (preferably having 5 to 12 carbon atoms, which may be substituted with a fluorine atom or the like), and each of Rx and Ry is preferably a hydrogen atom, an alkyl group, or a fluorine atom-substituted alkyl group,
X represents an electron-withdrawing group and specific examples thereof include the electron-withdrawing groups as Y¹ and Y², and X is preferably an alkyl fluoride group, a cycloalkyl fluoride group, an aryl group substituted with fluorine or an alkyl fluoride group, an aralkyl group substituted with fluorine or an alkyl fluoride group, a cyano group, or a nitro group, and
* represents a bond to the main chain or side chain of the resin, that is, a bond which is bonded to the main chain of the resin through a single bond or a linking group.

Incidentally, when X′ is a carbonyloxy group or an oxycarbonyl group, A is not a single bond.

The polarity converting group decomposes by the action of an alkaline developer to effect polarity conversion, whereby the receding contact angle with water of the resist film after alkali development can be decreased. Decrease in the receding contact angle with water of the film after alkali development is preferable from the viewpoint of suppressing the development defect.

The receding contact angle with water of the resist film after alkali development is preferably 50° or less, more preferably 40° or less, still more preferably 35° or less, and most preferably 30° or less, at a temperature of 23±3° C. and a humidity of 45±5%.

The receding contact angle is a contact angle measured when a contact line recedes on the liquid droplet-substrate interface, and this is generally known to be useful in simulating the mobility of a liquid droplet in the dynamic state. In a simple manner, the receding contact angle can be defined as a contact angle at the time of the liquid droplet interface receding when a liquid droplet ejected from a needle tip is landed on a substrate and then the liquid droplet is again suctioned into the needle. In general, the receding contact angle can be measured by a contact angle measuring method called an expansion/contraction method.

The receding contact angle of the film after alkali development is a contact angle measured when a film shown below is measured by the expansion/contraction method described in Examples as described later. That is, it is a contact angle of a film obtained as follows by measurement by an expansion/contraction method: ARC29SR (available from Nissan Chemical Industries, Ltd.) for forming an organic antireflection film was applied onto a silicon wafer (8-inch opening) and baked at 205° C. for 60 seconds, thereby forming an antireflection film having a film thickness of 98 nm. The actinic-ray-sensitive or radiation-sensitive resin composition of the present invention was applied thereonto and baked at 120° C. for 60 seconds, thereby forming a film having a film thickness of 120 nm. This film was developed in an aqueous tetramethylammonium hydroxide solution (2.38% by mass) for 30 seconds, rinsed with pure water, and then spin-dried, thereby obtaining a film.

The hydrolysis rate of the resin (C) for an alkaline developer is preferably 0.001 nm/sec or more, more preferably 0.01 nm/sec or more, still more preferably 0.1 nm/sec or more, and most preferably 1 nm/sec or more.

The hydrolysis rate of the resin (C) for an alkaline developer as used herein is the rate at which the thickness of a resin film formed only of the resin (C) decreases when treated with TMAH (an aqueous tetramethylammonium hydroxide solution) (2.38% by mass) at 23° C.

The repeating unit (by) is more preferably a repeating having at least two or more polarity converting groups.

In the case where the repeating unit (by) has at least two polarity converting groups, the repeating unit preferably has a group containing a partial structure having two polarity converting groups represented by the following general formula (KY-1). Incidentally, when the structure represented by the general formula (KY-1) does not have a bond, this is a group containing a monovalent or higher valent group formed by removing at least one arbitrary hydrogen atom in the structure.

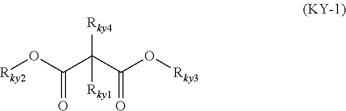

In the general formula (KY-1),
each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group, or an aryl group. Alternatively, R_{ky1} and R_{ky4} may be bonded to the same atom to form a double bond. For example, R_{ky1} and R_{ky4} may be bonded to the same oxygen atom to form a part (═O) of a carbonyl group.

Each of R_{ky2} and R_{ky3} independently represents an electron-withdrawing group, or while R_{ky1} and R_{ky2} are combined to form a lactone ring, R_{ky3} is an electron-withdrawing group. The lactone ring formed is preferably a structure of (KA-1-1) to (KA-1-17). Examples of the electron-withdrawing group are the same as those for Y₁ and Y₂ in the general formula (KB-1), and a halogen atom and a halo(cyclo)alkyl or haloaryl group represented by —C(R_{f1})(R_{f2})—R_{f3} are preferable. Preferably, R_{ky3} is a halogen atom or a halo(cyclo)alkyl or haloaryl group represented by —C(R_{f1})(R_{f2})—R_{f3}, and R_{ky2} is combined with R_{ky1} to form a lactone ring or is an electron-withdrawing group containing no halogen atom.

R_{ky1}, R_{ky2}, and R_{ky4} may be combined with each other to form a monocyclic or polycyclic structure.

Specific examples of R_{ky1} and R_{ky4} include the same as those for Zₖₐ₁ in the formula (KA-1).

The lactone ring formed by combination of R_{ky1} and R_{ky2} is preferably a structure of (KA-1-1) to (KA-1-17). Examples of the electron-withdrawing group are the same as those for Y₁ and Y₂ in the general formula (KB-1).

The structure represented by the general formula (KY-1) is preferably a structure represented by the following general formula (KY-2). Here, the structure represented by the general formula (KY-2) is a group having a monovalent or higher valent group formed by removing at least one arbitrary hydrogen atom in the structure.

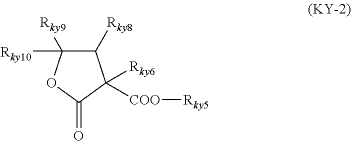

In the formula (KY-2),
each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group, or an aryl group.

two or more members of R_{ky6} to R_{ky10} may be combined with each other to form a monocyclic or polycyclic structure, and
R_{ky5} represents an electron-withdrawing group, and examples of the electron-withdrawing group are the same as those for Y₁ and Y₂, with a halogen atom and a halo(cyclo)alkyl or haloaryl group represented by —C(R_{f1})(R_{f2})—R_{f3} being preferred.

Specific examples of R_{ky5} to R_{ky10} include the same as those for Zₖₐ₁ in the formula (KA-1).

The structure represented by the formula (KY-2) is more preferably a partial structure represented by the following general formula (KY-3).

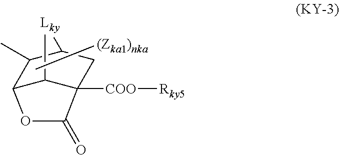

In the formula (KY-3), Zₖₐ₁ and nₖₐ have the same meanings as in the general formula (KA-1). R_{ky5} has the same meaning as in the formula (KY-2).

L_{ky} represents an alkylene group, an oxygen atom, or a sulfur atom. Examples of the alkylene group of L_{ky} include a methylene group, an ethylene group, and the like. L_{ky} is preferably an oxygen atom or a methylene group, and more preferably a methylene group.

The repeating unit (b) is not limited as long as it is a repeating unit obtained by polymerization such as addition polymerization, condensation polymerization and addition condensation, but a repeating unit obtained by addition polymerization of a carbon-carbon double bond is preferable. Examples thereof include an acrylate-based repeating unit (including a system having a substituent at the α- or β-position), a styrene-based repeating unit (including a system having a substituent at the α- or β-position), a vinyl ether-based repeating unit, a norbornene-based repeating unit, a maleic acid derivative (such as maleic anhydride or a derivative thereof, maleimide, and the like) repeating unit, and the like. An acrylate-based repeating unit, a styrene-based repeating unit, a vinyl ether-based repeating unit and a norbornene-based repeating unit are preferable, an acrylate-based repeating unit, a vinyl ether-based repeating unit and a norbornene-based repeating unit are more preferable, and an acrylate-based repeating unit is most preferable.

In the case where the repeating unit (by) is a repeating unit having at least either a fluorine atom or a silicon atom (that is, a repeating unit corresponding to the repeating unit (b′) or (b″)), examples of the fluorine atom-containing partial structure in the repeating unit (by) are the same as those in the above-described repeating unit having at least either a fluorine atom or a silicon atom, and the groups represented by the general formulae (F2) to (F4) are preferable. Further, examples of the silicon atom-containing partial structure in the repeating unit (by) are the same as those in the above-described repeating unit having at least either a fluorine atom or a silicon atom, and the groups represented by the general formulae (CS-1) to (CS-3) are preferable.

The content of the repeating unit (by) in the resin (C) is preferably from 10 to 100 mol %, more preferably from 20 to 99 mol %, still more preferably from 30 to 97 mol %, and most preferably from 40 to 95 mol %, based on all the repeating units in the resin (C).

Specific examples of the repeating unit (by) having a group capable of increasing the solubility in an alkaline developer are illustrated below, but the present invention is not limited thereto. Specific examples of the repeating unit (by) also include those described as specific examples of the repeating unit (a3) of the resin (A).

Ra represents a hydrogen atom, a fluorine atom, a methyl group, or a trifluoromethyl group.

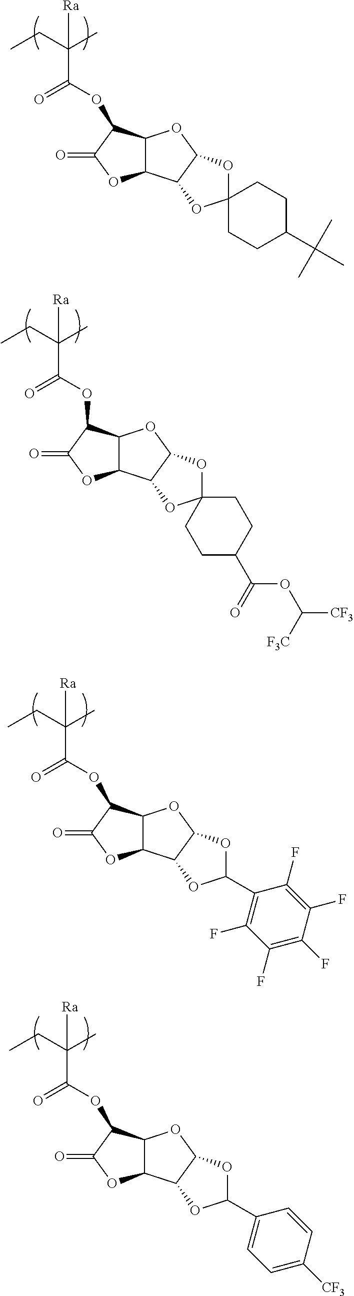

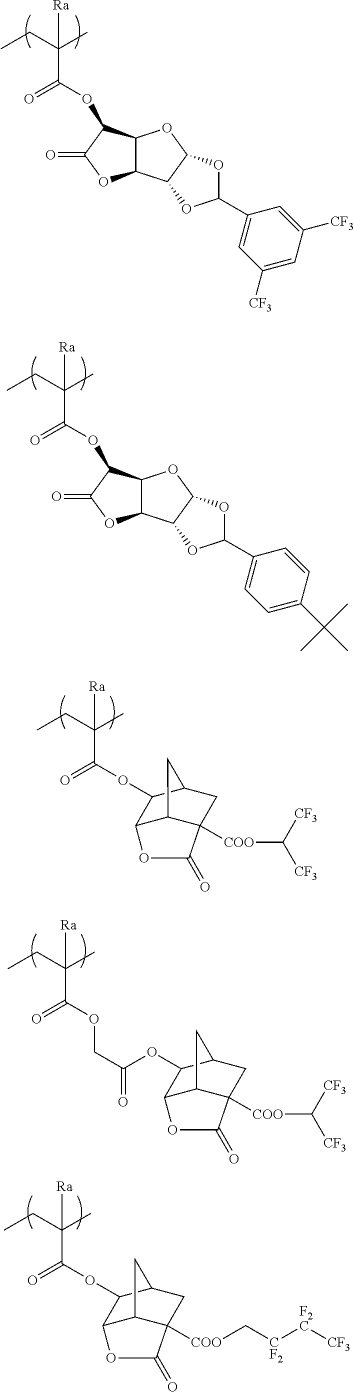

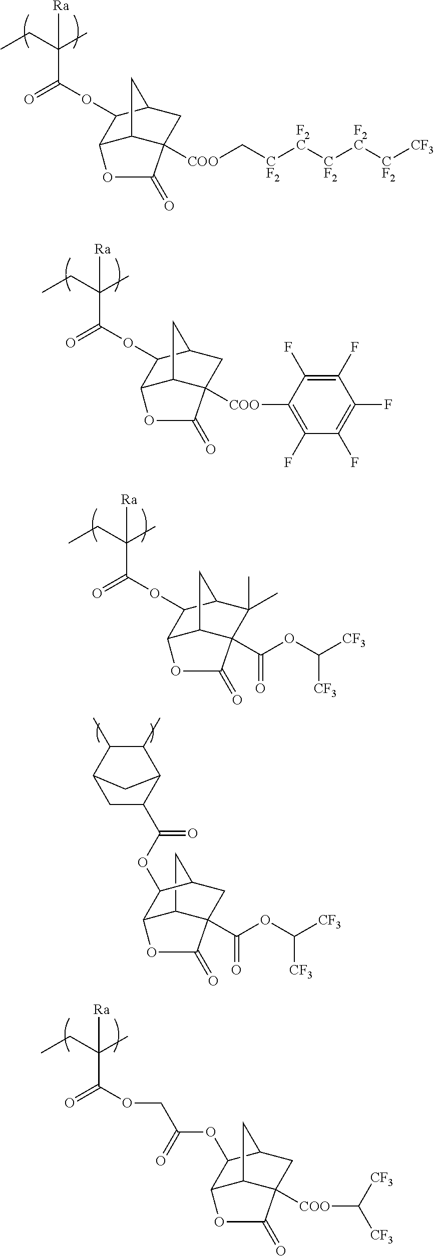

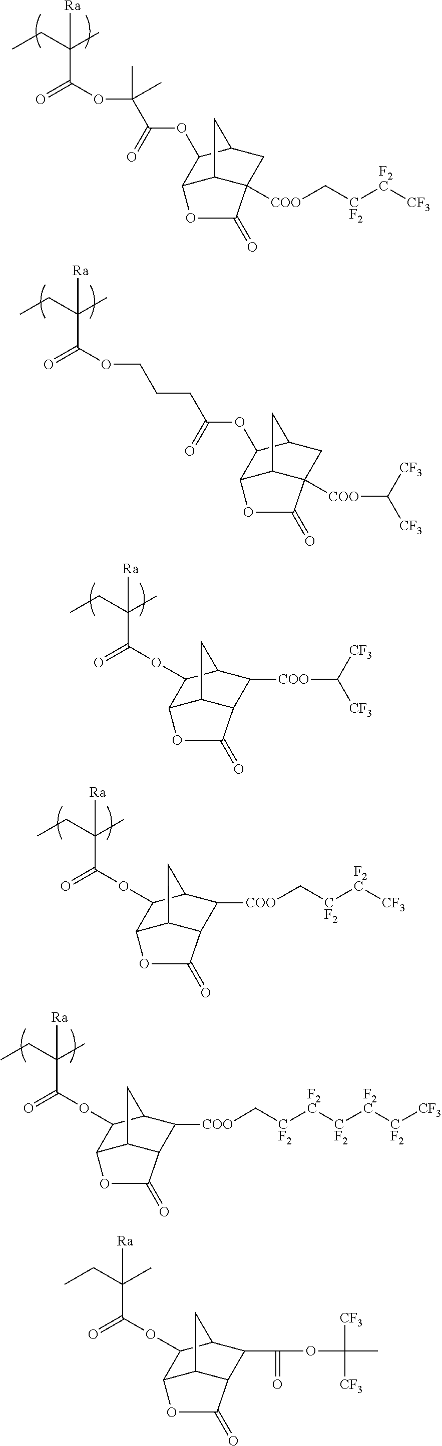

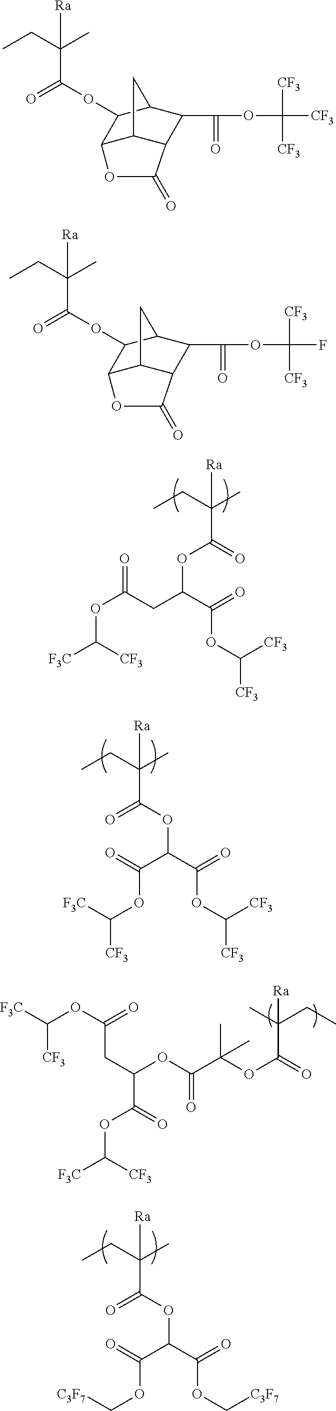

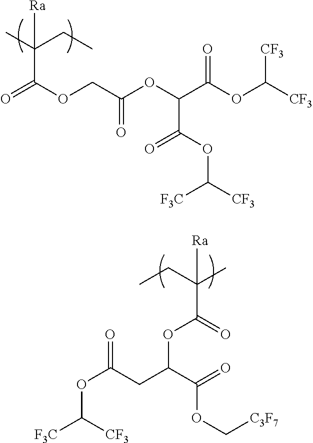

Examples of the repeating unit (bz) having (z) a group which decomposes by the action of an acid in the resin (C) are the repeating units having an acid-decomposable group.

The acid-decomposable group preferably has a structure in which the alkali-soluble group is protected with a group which decomposes and is cleaved by the action of an acid.

Examples of the alkali-soluble group include a phenolic hydroxyl group, a carboxyl group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group, and the like.

Preferable examples of the alkali-soluble group include a carboxyl group, a fluorinated alcohol group (preferably a hexafluoroisopropanol group), and a sulfonic acid group.

The acid-decomposable group is preferably a group as obtained by substituting the hydrogen atom of any of these alkali-soluble groups with an acid-cleavable group.

Examples of the acid-cleavable group include —C(R₃₆)(R₃₇)(R₃₈), —C(R₃₆)(R₃₇)(OR₃₉), —C(R₀₁)(R₀₂)(OR₃₉), and the like.

In the formulae, each of R₃₆ to R₃₉ independently represents an alkyl group, a cycloalkyl group, an aryl group, an aralkyl group, or an alkenyl group. R₃₆ and R₃₇ may be bonded to each other to form a ring.

Each of R₀₁ to R₀₂ independently represents a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, and the like, and more preferably a tertiary alkyl ester group.

In the case where the repeating unit (bz) is a repeating unit having at least either a fluorine atom or a silicon atom (that is, a repeating unit corresponding to the repeating unit (b′) or (b″)), examples of the fluorine atom-containing partial structure in the repeating unit (bz) are the same as those in the above-described repeating unit having at least either a fluorine atom or a silicon atom, and the groups represented by the general formulae (F2) to (F4) are preferred. Further, examples of the silicon atom-containing partial structure in the repeating unit (bz) include the same as those in the above-described repeating unit having at least either a fluorine atom or a silicon atom, and the groups represented by the general formulae (CS-1) to (CS-3) are preferred.

The content of the repeating unit (bz) having (z) an alkali-soluble group in the resin (C) is preferably from 1 to 80 mol %, more preferably from 10 to 80 mol %, and still more preferably from 20 to 60 mol %, based on all the repeating units in the resin (C).

While the repeating unit (b) having at least one group selected from the group consisting of (x) to (z) is described above, the content of the repeating unit (b) in the resin (C) is preferably from 1 to 98 mol %, more preferably from 3 to 98 mol %, still more preferably from 5 to 97 mol %, and most preferably from 10 to 95 mol %, based on all the repeating units in the resin (C).

The content of the repeating unit (b′) is preferably from 1 to 100 mol %, more preferably from 3 to 99 mol %, still more preferably from 5 to 97 mol %, and most preferably from 10 to 95 mol %, based on all the repeating units in the resin (C).

The content of the repeating unit (b*) is preferably from 1 to 90 mol %, more preferably from 3 to 80 mol %, still more preferably from 5 to 70 mol %, and most preferably from 10 to 60 mol %, based on all the repeating units in the resin (C). The content of the repeating unit having at least either a fluorine atom or a silicon atom, which is used together with the repeating unit (b*), is preferably from 10 to 99 mol %, more preferably from 20 to 97 mol %, still more preferably from 30 to 95 mol %, and most preferably from 40 to 90 mol %, based on all the repeating units in the resin (C).

The content of the repeating unit (b″) is preferably from 1 to 100 mol %, more preferably from 3 to 99 mol %, still more preferably from 5 to 97 mol %, and most preferably from 10 to 95 mol %, based on all the repeating units in the resin (C).

The resin (C) may contain a repeating unit represented by the following general formula (CIII).

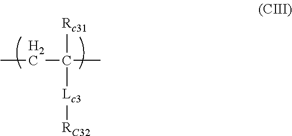

In the general formula (CIII),
R_{c31} represents a hydrogen atom, an alkyl group, an alkyl group which may be substituted with fluorine, a cyano group, or a —CH₂—O—R_{ac2} group, wherein R_{ac2} represents a hydrogen atom, an alkyl group, or an acyl group, and R_{c31} is preferably a hydrogen atom, a methyl group, a hydroxymethyl group, or a trifluoromethyl group, and particularly preferably a hydrogen atom or a methyl group,
R_{c32} represents a group having an alkyl group, a cycloalkyl group, an alkenyl group, or a cycloalkenyl group, and each of these groups may be substituted with a fluorine atom- or silicon atom-containing group, or the like, and
L_{c3} represents a single bond or a divalent linking group.

The alkyl group of R_{c32} in the general formula (CIII) is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably a phenyl group or a naphthyl group, having 6 to 20 carbon atoms, and the group may have a substituent.

R_{c32} is preferably an unsubstituted alkyl group or a fluorine atom-substituted alkyl group.

The divalent linking group of L_{c3} is preferably an alkylene group (preferably having 1 to 5 carbon atoms), an oxy group, a phenylene group, or an ester bond (a group represented by —COO—).

The resin (C) preferably further contains a repeating unit represented by the following general formula (BII-AB).

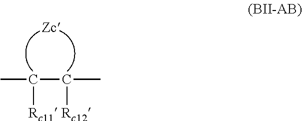

In the formula (BII-AB),
each of R_{c11}′ and R_{c12}′ independently represents a hydrogen atom, a cyano group, a halogen atom, or an alkyl group, and
Z_{c}′ represents an atomic group for forming an alicyclic structure containing two carbon atoms (C—C) to which Z_{c}′ is bonded.

In the case where each group in the repeating units represented by the general formulae (III) and (BII-AB) are substituted with a fluorine atom- or silicon atom-containing group, the repeating unit corresponds also to the above-described repeating unit having at least either a fluorine atom or a silicon atom.

Specific examples of the repeating units represented by the general formulae (III) and (BII-AB) are shown below, but the present invention is not limited thereto. In the formulae, Ra represents H, CH₃, CH₂OH, CF₃, or CN. Incidentally, the repeating unit where Ra is CF₃ corresponds also to the above-described repeating unit having at least either a fluorine atom or a silicon atom.

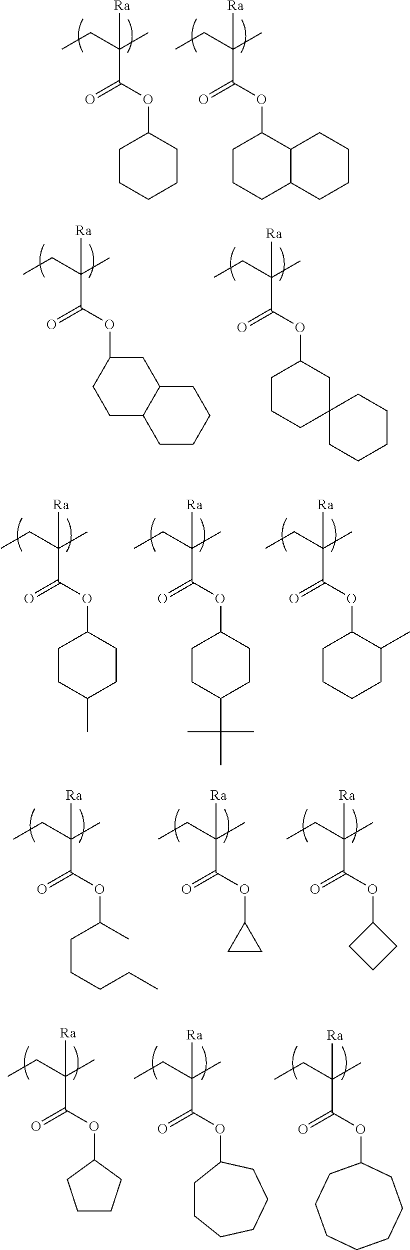

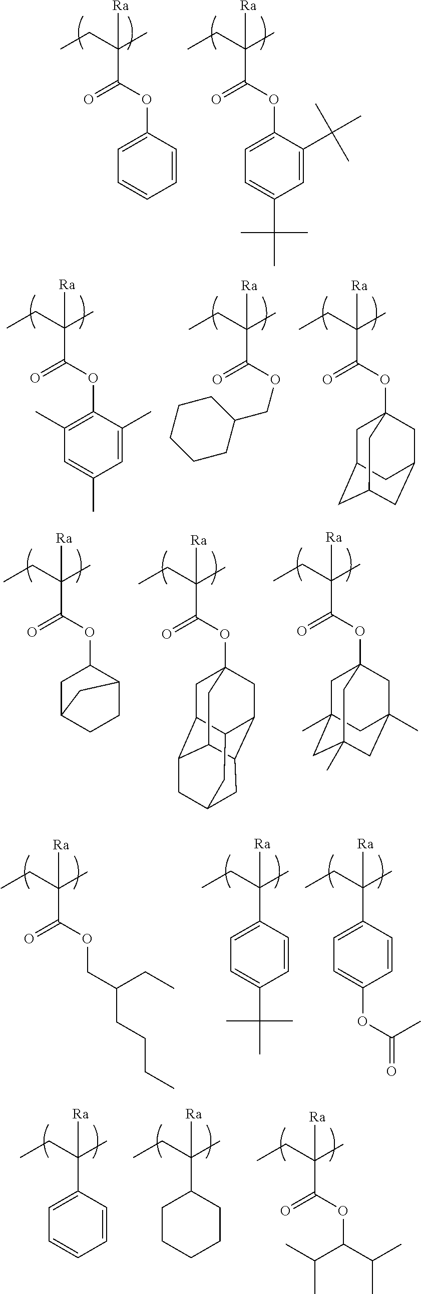

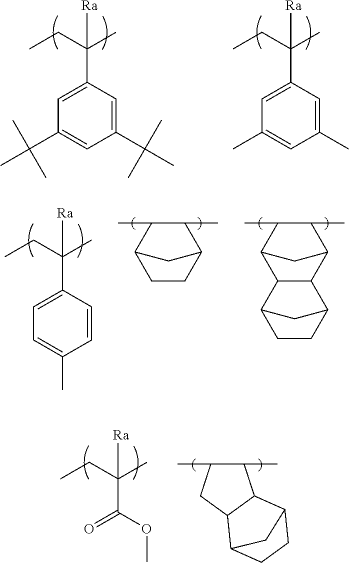

In the resin (C), similarly to the resin (A), it is of course preferable that the content of impurities such as a metal and the like is small, but also, the content of residual monomers or oligomer components is preferably from 0 to 10% by mass, more preferably from 0 to 5% by mass, still more preferably from 0 to 1% by mass. When these conditions are satisfied, a resist composition free from extraneous substances in a liquid or change with aging of sensitivity or the like can be obtained. Furthermore, in view of resolution, resist profile, side wall of resist pattern, roughness, and the like, the molecular weight distribution (Mw/Mn, also referred to as “polydispersity”) is preferably in the range of 1 to 3, more preferably 1 to 2, still more preferably 1 to 1.8, and most preferably 1 to 1.5.

As for the resin (C), various commercially available products may be used, or the resin may be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours, and the like. A dropping polymerization method is preferred.

The reaction solvent, the polymerization initiator, the reaction conditions (for example, a temperature, a concentration, and the like), and the purification method after reaction are the same as those described for the resin (A).

Specific examples of the resin (C) will be shown below. Further, the molar ratio of repeating units (corresponding to repeating units starting from the left), the weight average molecular weight, and the polydispersity of each resin are shown in the Table below.

TABLE 1

| | Compositional ratio | | |
|---|---|---|---|
| Polymer | (mol %) | Mw | Mw/Mn |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 30/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

(B-1) 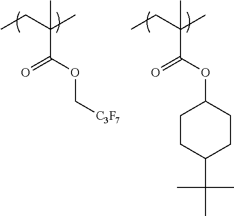
(B-2) 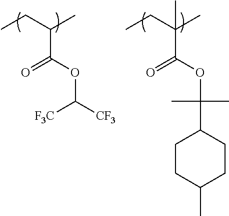
(B-3) 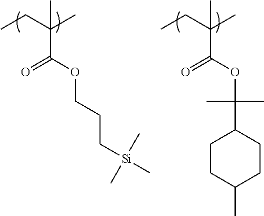
(B-4) 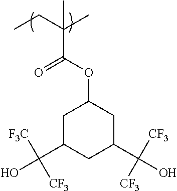
(B-5) 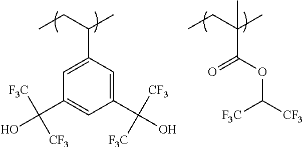
(B-6) 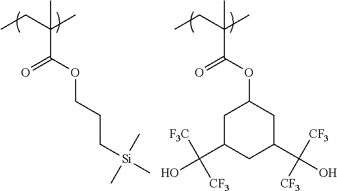
(B-7) 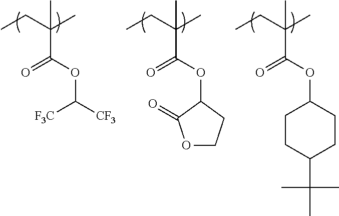
(B-8) 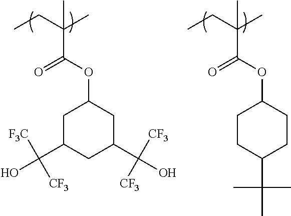
(B-9) 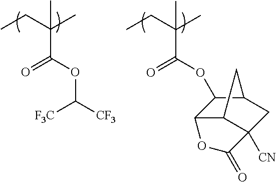
(B-10) 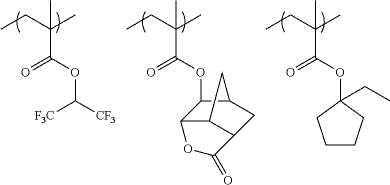
(B-11) 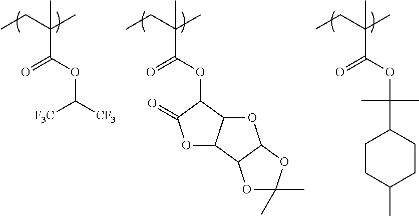
(B-12) 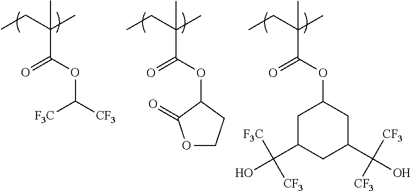
(B-13) 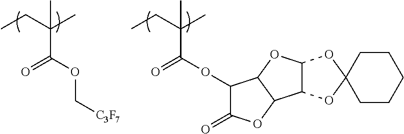
(B-14) 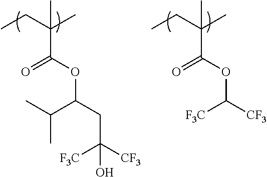
(B-15) 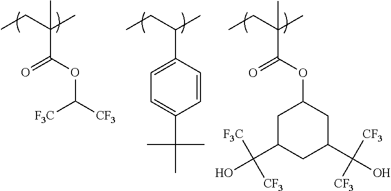
(B-16) 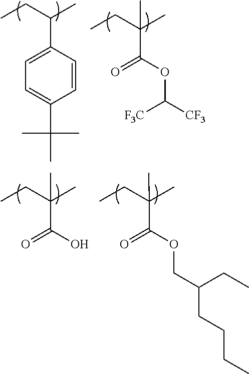
(B-17) 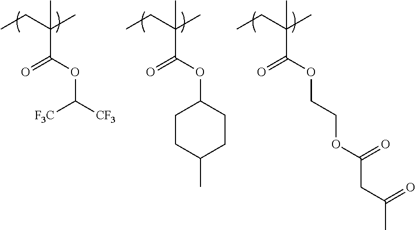
(B-18) 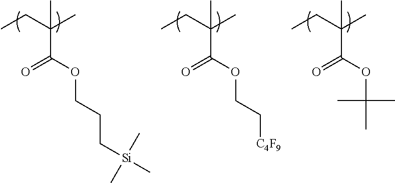
(B-19) 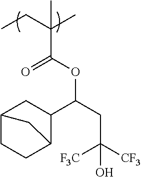
(B-20) 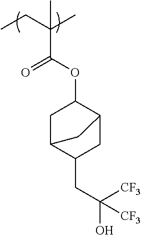
(B-21) 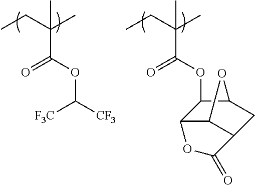
(B-22) 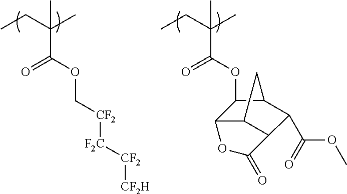
(B-23) 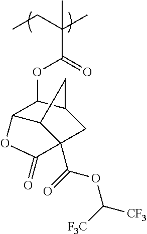
(B-24) 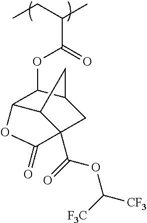
(B-25) 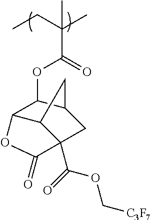
(B-26) 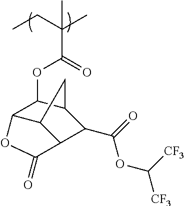
(B-27) 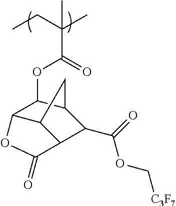
(B-28) 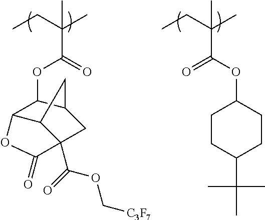
(B-29) 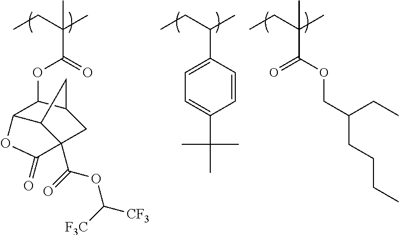
(B-30) 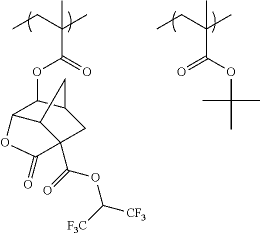
(B-31) 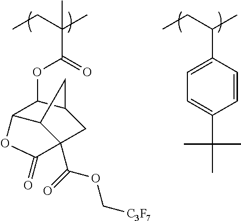
(B-32) 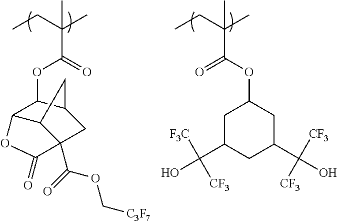
(B-33) 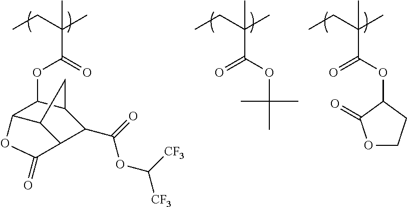
(B-34) 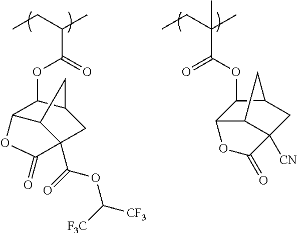
(B-35) 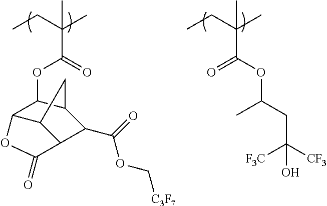
(B-36) 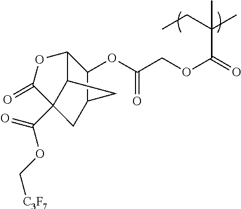
(B-37) 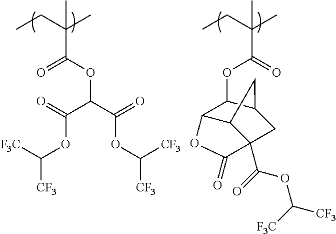
(B-38) 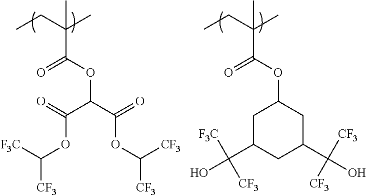
(B-39) 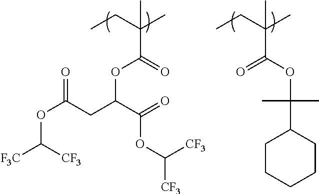
(B-40) 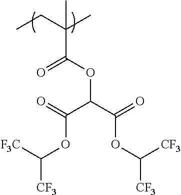
(B-41) 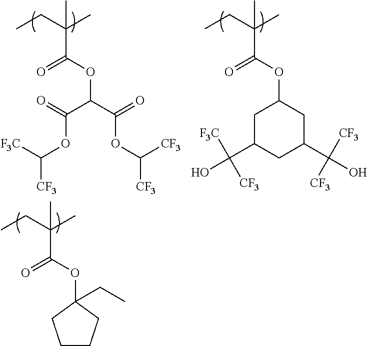
(B-42) 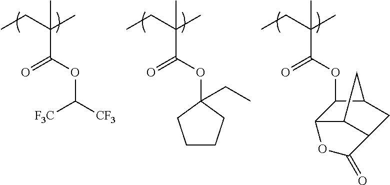
(B-43) 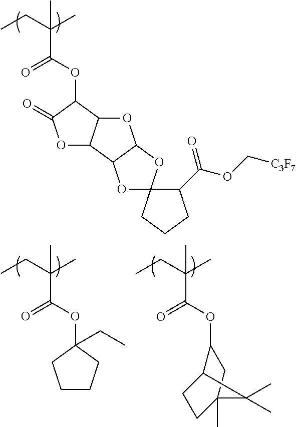
(B-44) 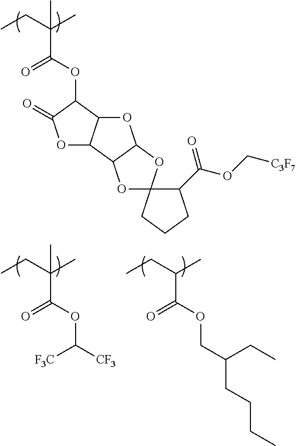
(B-45) 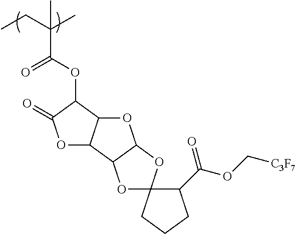
(B-46) 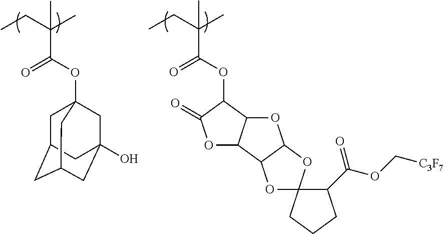
(B-47) 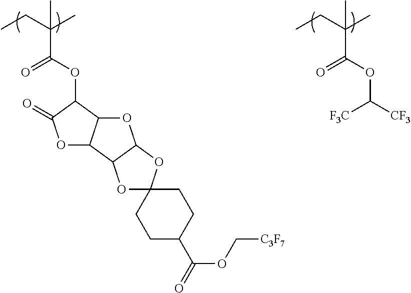
(B-48) 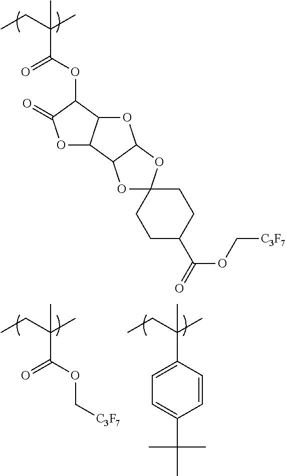
(B-49) 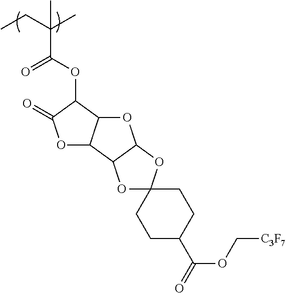
(B-50) 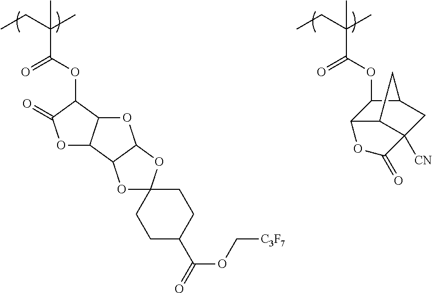
(B-51) 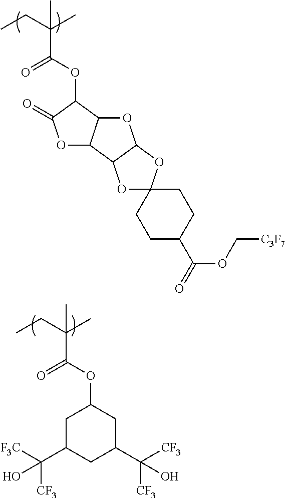
(B-52) 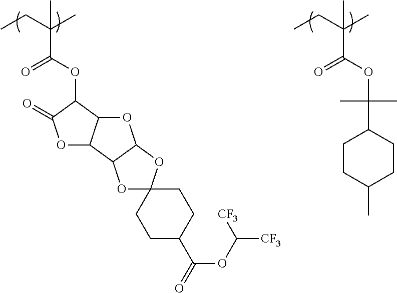
(B-53) 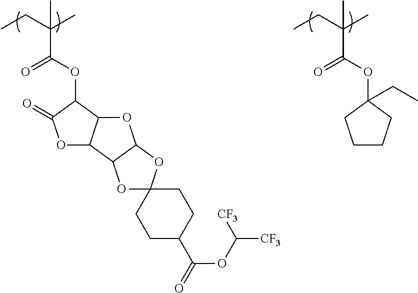
(B-54) 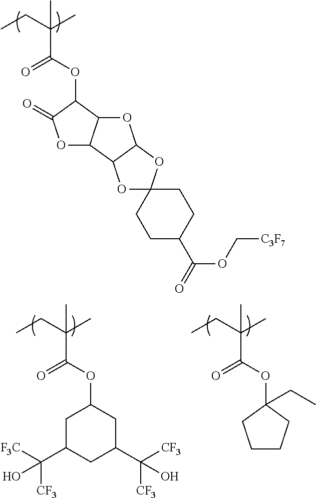
(B-55)

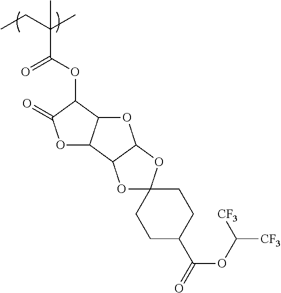

The actinic-ray-sensitive or radiation-sensitive resin composition of the present invention contains a hydrophobic resin (C) containing at least either a fluorine atom or a silicon atom, and the resin (C) is unevenly distributed to the surface layer of a film formed of the actinic-ray-sensitive or radiation-sensitive resin composition, so that in the case where the liquid for liquid immersion is water, the receding contact angle for water on the film surface as well as the traceability of the immersion liquid can be enhanced.

The receding contact angle of a film after baking a coating composed of the actinic-ray-sensitive or radiation-sensitive resin composition of the present invention of the present invention but before exposure is preferably from 60 to 90°, more preferably 65° or more, still more preferably 70° or more, and particularly preferably 75° or more, at the temperature during exposure (usually room temperature 23±3° C.), and a humidity of 45±5%.

The resin (C) is, as described above, unevenly distributed to the interface but unlike a surfactant, need not have necessarily a hydrophilic group in the molecule and may not contribute to uniform mixing of polar/nonpolar substances.

In the liquid immersion exposure step, the liquid for liquid immersion must move on a wafer following the movement of an exposure head that is scanning the wafer at a high speed and forming an exposure pattern. Therefore, the contact angle of the liquid for liquid immersion with the resist film in a dynamic state is important, and the resist is required to have a performance of allowing a liquid droplet to follow the high-speed scanning of an exposure head with no remaining.

The resin (C) is hydrophobic and therefore, liable to worsen the development residue (scum) and BLOB defect after alkali development, but by virtue of having three or more polymer chains through at least one branch part, the alkali dissolution rate is enhanced as compared with a linear chain-type resin and in turn, the performance in terms of development residue (scum) and the BLOB defect is improved.

In the case where the resin (C) contains a fluorine atom, the fluorine atom content is preferably from 5 to 80% by mass, and more preferably from 10 to 80% by mass, based on the molecular weight of the resin (C). Further, the fluorine atom-containing repeating unit preferably accounts for 10 to 100 mol %, and more preferably 20 to 100 mol %, based on all the repeating units in the resin (C).

In the case where the resin (C) contains a silicon atom, the silicon atom content is preferably from 2 to 50% by mass, and more preferably from 2 to 30% by mass, based on the weight average molecular weight of the resin (C). Further, the silicon atom-containing repeating unit preferably accounts for 10 to 90 mol %, and more preferably from 20 to 80 mol %, based on all the repeating units in the resin (C).

The weight average molecular weight of the resin (C) is preferably from 1,000 to 100,000, more preferably from 2,000 to 50,000, and still more preferably from 3,000 to 30,000. Here, the weight average molecular weight of the resin indicates a molecular weight in terms of polystyrene measured by GPC (carrier: tetrahydrofuran (THF)).

The resin (C) in the actinic-ray-sensitive or radiation-sensitive resin composition may be used by appropriately adjusting its content to give an actinic-ray-sensitive or radiation-sensitive resin film having a receding contact angle in the range above, but the content thereof is preferably from 0.01 to 20% by mass, more preferably from 0.1 to 15% by mass, still more preferably from 0.1 to 10% by mass, and particularly preferably from 0.5 to 8% by mass, based on the total solids of the actinic-ray-sensitive or radiation-sensitive resin composition.

The resin (C) may be used singly or in combination of two or more kinds thereof.

[4] Basic Compound

For the purpose of reducing changes in performance with a lapse of time from exposure to heating, it is preferable that a basic compound be contained in the actinic-ray-sensitive or radiation-sensitive resin composition of the present invention.

Examples of the basic compound include compounds having structures represented by the following general formulae (A) to (E).

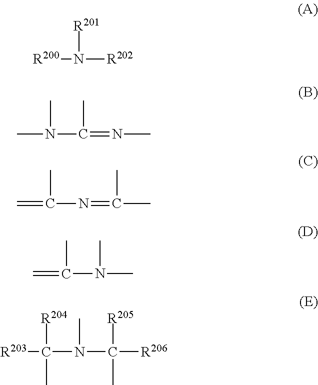

In the general formulae (A) and (E),
R²⁰⁰, R²⁰¹, and R²⁰² may be the same as or different from each other, and each of them represents a hydrogen atom, an alkyl group (preferably having 1 to 20 carbon atoms), and a cycloalkyl group (preferably having 3 to 20 carbon atoms) or an aryl group (having 6 to 20 carbon atoms), wherein ²⁰¹ and R²⁰² may be bonded to each other to form a ring, and
R²⁰³, R²⁰⁴, R²⁰⁵, and R²⁰⁶ may be the same as or different from each other, and each of them represents an alkyl group having 1 to 20 carbon atoms.

As for the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms is preferred.

The alkyl group in any of the general formulae (A) and (E) is preferably unsubstituted.

Preferable examples of the compound include guanidine, aminopyrrolidine, pyrazole, pyrazoline, piperazine, aminomorpholine, aminoalkyl morpholines, piperidine, and the like; and these compounds may contain a substituent, and more preferable examples of such a compound include compounds having an imidazole structure, a diazabicyclo structure, an onium hydroxide structure, an onium carboxylate structure, a trialkylamine structure, an aniline structure, or a pyridine structure; alkylamine derivatives containing a hydroxyl group and/or an ether bond; aniline derivatives containing a hydroxyl group and/or an ether bond; and the like.

Examples of the compound having an imidazole structure include imidazole, 2,4,5-triphenylimidazole, benzimidazole, 2-phenylbenzoimidazole, and the like. Examples of the compound having a diazabicyclo structure include 1,4-diazabicyclo[2,2,2]octane, 1,5-di-azabicyclo[4,3,0]non-5-ene, 1,8-diazabicyclo[5,4,0]undec-7-ene, and the like. Examples of the compound having an onium hydroxide structure include triarylsulfonium hydroxides, phenacylsulfonium hydroxides, and sulfonium hydroxides containing a 2-oxoalkyl group; and specific examples thereof include triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide, and the like. Examples of the compound having an onium carboxylate structure include compounds in which an anion moiety of a compound having an onium hydroxide structure is replaced by a carboxylate, for example, acetate, adamantane-1-carboxylate, a perfluoroalkyl carboxylate, and the like. Examples of the compound having a trialkylamine structure include tri(n-butyl)amine, tri(n-octyl)amine, and the like. Examples of the aniline compound include 2,6-diisopropylaniline, N,N-dimethylaniline, N,N-dibutylaniline, N,N-dihexylaniline, and the like. Examples of the alkylamine derivative containing a hydroxyl group and/or an ether bond include ethanolamine, diethanolamine, triethanolamine, N-phenyldiethanolamine, tris(methoxyethoxyethyl)amine, and the like. Examples of the aniline derivative containing a hydroxyl group and/or an ether bond include N,N-bis(hydroxyethyl)aniline and the like.

Preferable examples of the basic compound include an amine compound having a phenoxy group, an ammonium salt compound having a phenoxy group, an amine compound having a sulfonic ester group, and an ammonium salt compound having a sulfonic ester group.

As the amine compound, a primary, secondary, or tertiary amine compound can be used, and an amine compound having its at least one alkyl group bonded to the nitrogen atom thereof is preferred. Among the amine compounds, a tertiary amine compound is more preferred. In the amine compounds, as long as at least one alkyl group (preferably having 1 to 20 carbon atoms) is bonded to the nitrogen atom, a cycloalkyl group (preferably having 3 to 20 carbon atoms), or an aryl group (preferably having 6 to 12 carbon atoms) besides the alkyl group may be bonded to the nitrogen atom. In the amine compounds, it is preferable for the alkyl chain to contain an oxygen atom so as to form an oxyalkylene group. The number of oxyalkylene groups in each molecule is 1 or more, preferably 3 to 9, and more preferably 4 to 6. The oxyalkylene group is preferably an oxyethylene group (—CH₂CH₂O—) or an oxypropylene group (—CH(CH₃)CH₂O— or —CH₂CH₂CH₂O—), and more preferably an oxyethylene group.

As the ammonium salt compound, a primary, secondary, tertiary, or quaternary ammonium salt compound can be used. An ammonium salt compound having at least one alkyl group bonded to the nitrogen atom thereof is preferred. Of the ammonium salt compounds, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. Of the ammonium salt compounds, it is preferable for the alkyl chain to contain an oxygen atom so as to form an oxyalkylene group. The number of oxyalkylene groups in each molecule is one or more, preferably 3 to 9, and still more preferably 4 to 6. The oxyalkylene group is preferably an oxyethylene group (—CH₂CH₂O—) or an oxypropylene group (—CH(CH₃)CH₂O— or —CH₂CH₂CH₂O—), and more preferably an oxyethylene group.

Examples of the anion of the ammonium salt compound include a halide atom, a sulfonate, a borate, a phosphate, and the like, and among these, a halide and a sulfonate are preferred. As the halogen atom, chloride, bromide, and iodide are particularly preferred, and as the sulfonate, an organic sulfonate having 1 to 20 carbon atoms is particularly preferred. Examples of the organic sulfonate include an aryl sulfonate and an alkyl sulfonate having 1 to 20 carbon atoms. The alkyl group of the alkyl sulfonate may have a substituent. Examples of the substituent include fluorine, chlorine, bromine, an alkoxy group, an acyl group, an aryl group, and the like. Specific examples of the alkyl sulfonate include methane sulfonate, ethane sulfonate, butane sulfonate, hexane sulfonate, octane sulfonate, benzyl sulfonate, trifluoromethane sulfonate, pentafluoroethane sulfonate, nonafluorobutane sulfonate, and the like. Examples of the aryl group of the aryl sulfonate include a benzene ring, a naphthalene ring, and an anthracene ring. The benzene ring, the naphthalene ring, or the anthracene ring may have a substituent. Preferable examples of the substituent include a linear or branched alkyl group having 1 to 6 carbon atoms and a cycloalkyl group having 3 to 6 carbon atoms. Specific examples of the linear or branched alkyl groups and cycloalkyl group include methyl, ethyl, n-propyl, isopropyl, n-butyl, i-butyl, t-butyl, n-hexyl, cyclohexyl, and the like. Examples of such other substituent include an alkoxy group having 1 to 6 carbon atoms, a halogen atom, cyano, nitro, an acyl group, an acyloxy group, and the like.

The amine compound having a phenoxy group and ammonium salt compound having a phenoxy group are those having a phenoxy group at the end of the alkyl group of the amine compound or ammonium salt compound opposed to the nitrogen atom. The phenoxy group may have a substituent. Examples of the substituent of the phenoxy group include an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group, and the like. The substitution position of the substituent may be any of 2- to 6-positions. The number of substituents may be any one within the range of 1 to 5.

It is preferable that at least one oxyalkylene group exist between the phenoxy group and the nitrogen atom. The number of oxyalkylene groups in each molecule is one or more, preferably from 3 to 9, and more preferably from 4 to 6. The oxyalkylene group is preferably an oxyethylene group (—CH₂CH₂O—) or an oxypropylene group (—CH(CH₃)CH₂O— or —CH₂CH₂CH₂O—), and more preferably an oxyethylene group.

The sulfonic ester group of the amine compound having a sulfonic ester group or ammonium salt compound having a sulfonic ester group may be any of an alkylsulfonic ester, a cycloalkylsulfonic ester and an arylsulfonic ester. In the alkylsulfonic ester, the alkyl group preferably has 1 to 20 carbon atoms. In the cycloalkylsulfonic ester, the cycloalkyl group preferably has 3 to 20 carbon atoms. In the arylsulfonic ester, the aryl group preferably has 6 to 12 carbon atoms. The alkylsulfonic ester, cycloalkylsulfonic ester and arylsulfonic ester may have substituents. Preferable examples of the substituent include a halogen atom, a cyano group, a nitro group, a carboxyl group, a carboxylic ester group and a sulfonic ester group.

It is preferable that at least one oxyalkylene group exist between the sulfonic ester group and the nitrogen atom. The number of oxyalkylene groups in each molecule is 1 or more, preferably 3 to 9, and more preferably 4 to 6. The oxyalkylene group is preferably an oxyethylene group (—CH₂CH₂O—) or an oxypropylene group (—CH(CH₃)CH₂O— or —CH₂CH₂CH₂O—), and more preferably an oxyethylene group.

Furthermore, the compound is also preferred as a basic compound.

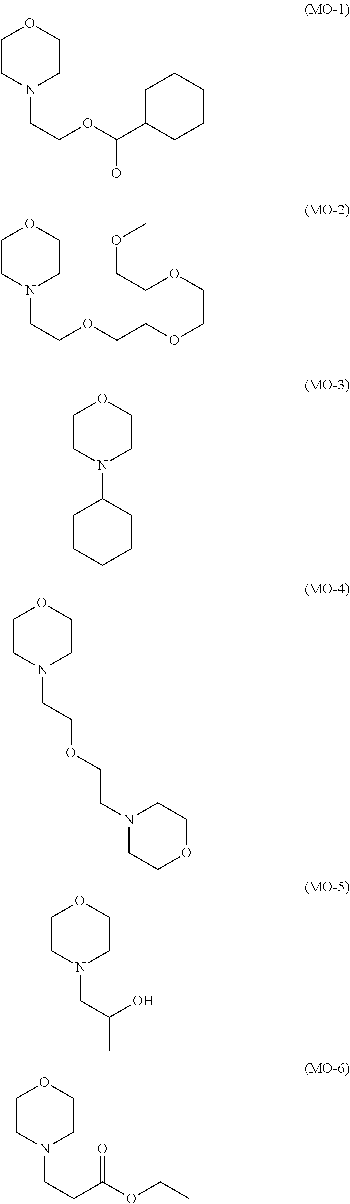

These basic compounds are used singly or in combination of two or more kinds thereof.

The actinic-ray-sensitive or radiation-sensitive resin composition of the present invention may or may not contain a basic compound. In the case where the composition contains the basic compound, the amount of the basic compound to be used is usually from 0.001 to 10% by mass, and preferably from 0.01 to 5% by mass, based on the solids of the actinic-ray-sensitive or radiation-sensitive resin composition of the present invention.

As for the ratio of the acid generator and the basic compound to be used in the composition, the acid generator/basic compound (molar ratio) is preferably 2.5 to 300. That is, the molar ratio of 2.5 or more is preferred from the viewpoint of sensitivity and resolution, and 300 or less is preferred from the viewpoint of inhibition of the reduction of resolution by the thickening of the pattern in aging after exposure until heat treatment. The ratio of the acid generator/basic compound (molar ratio) is more preferably 5.0 to 200, and still more preferably 7.0 to 150.

The basic compound is preferably used with respect to the (D) low-molecular-weight compound containing a nitrogen atom and containing a group which is cleaved by the action of an acid, with a ratio thereof with the (D) low-molecular-weight compound containing a nitrogen atom and containing a group which is cleaved by the action of an acid/basic compound (molar ratio)=100/0 to 10/90; preferably a ratio thereof with the (D) low-molecular-weight compound containing a nitrogen atom and containing a group which is cleaved by the action of an acid/basic compound (molar ratio)=100/0 to 30/70; and particularly preferably a ratio thereof with the (D) low-molecular-weight compound containing a nitrogen atom and containing a group which is cleaved by the action of an acid/basic compound (molar ratio)=100/0 to 50/50.

Further, the basic compound as used herein does not include a (D) low-molecular-weight compound containing a nitrogen atom and containing a group which is cleaved by the action of an acid, which is also a basic compound.

[5] (D) Low-Molecular-Weight Compound Containing Nitrogen Atom and Containing Group that is Cleaved by Action of Acid

The actinic-ray-sensitive or radiation-sensitive resin composition of the present invention can include a low-molecular-weight compound containing a nitrogen atom and a group that is cleaved by the action of an acid (which is also referred to as a “low-molecular-weight compound (D)” or a “compound (D)”).

The group that is cleaved by the action of an acid is not particularly limited, but an acetal group, a carbonate group, a carbamate group, a tertiary ester group, a tertiary hydroxyl group, and a hemiaminal ether group are preferred, and a carbamate group and a hemiaminal ether group are particularly preferred.

The molecular weight of the low-molecular-weight compound (D) containing a group that is cleaved by the action of an acid is preferably 100 to 1000, more preferably 100 to 700, and particularly preferably 100 to 500.

As the compound (D), an amine derivative containing group that is cleaved by the action of an acid on a nitrogen atoms is preferred.

The compound (D) may contain a carbamate group having a protecting group on a nitrogen atom. The protecting group constituting the carbamate group can be represented by the following general formula (d-1).

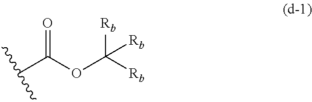

In the general formula (d-1),
each Rb independently represents a hydrogen atom, an alkyl group, a cycloalkyl group, an aryl group, an aralkyl group, or an alkoxyalkyl group, and Rb's may be bonded to each other to form a ring.

The alkyl group, the cycloalkyl group, the aryl group, or the aralkyl group represented by Rb may be substituted with a functional group such as a hydroxyl group, a cyano group, an amino group, a pyrrolidino group, a piperidino group, a morpholino group, an oxo group, and the like, an alkoxy group, or a halogen atom. This case comes under the alkoxyalkyl group represented by Rb.

Examples of the alkyl group, the cycloalkyl group, the aryl group, or the aralkyl group of Rb above (the alkyl group, the cycloalkyl group, the aryl group, and the aralkyl group may be substituted with the above-described functional group, an alkoxy group, or a halogen atom) include:
a group derived from a linear or branched alkane such as methane, ethane, propane, butane, pentane, hexane, heptane, octane, nonane, decane, undecane, dodecane, and the like, or a group where the group derived from an alkane is substituted with one or more kinds of or one or more groups of cycloalkyl groups such as a cyclobutyl group, a cyclopentyl group, a cyclohexyl group, and the like;
a group derived from a cycloalkane such as cyclobutane, cyclopentane, cyclohexane, cycloheptane, cyclooctane, norbornane, adamantane, noradamantane, and the like, or a group where the group derived from a cycloalkane is substituted with one or more kinds of or one or more groups of linear or branched alkyl group such as a methyl group, an ethyl group, an n-propyl group, an i-propyl group, an n-butyl group, a 2-methylpropyl group, a 1-methylpropyl group, a t-butyl group, and the like;
a group derived from an aromatic compound such as benzene, naphthalene, anthracene, and the like, or a group where the group derived from an aromatic compound is substituted with one or more kinds of or one or more groups of linear or branched alkyl group such as a methyl group, an ethyl group, an n-propyl group, an i-propyl group, an n-butyl group, a 2-methylpropyl group, a 1-methylpropyl group, a t-butyl group, and the like;
a group derived from a heterocyclic compound such as pyrrolidine, piperidine, morpholine, tetrahydrofuran, tetrahydropyran, indole, indoline, quinoline, perhydroquinoline, indazole, benzimidazole, and the like, or a group where the group derived from a heterocyclic compound is substituted with one or more kinds of or one or more groups of linear or branched alkyl group or aromatic compound-derived group;
a group where the group derived from a linear or branched alkane or the group derived from a cycloalkane is substituted with one or more kinds of or one or more groups of aromatic compound-derived group such as a phenyl group, a naphthyl group, an anthracenyl group, and the like;
a group where the substituent above is substituted with a functional group such as a hydroxyl group, a cyano group, an amino group, a pyrrolidino group, a piperidino group, a morpholino group, an oxo group, and the like; etc.

Rb is preferably a linear or branched alkyl group, a cycloalkyl group, or an aryl group, and more preferably a linear or branched alkyl group or a cycloalkyl group.

Examples of the ring formed by the mutual bonding of two Rb's include an alicyclic hydrocarbon group, an aromatic hydrocarbon group, a heterocyclic hydrocarbon group, and derivatives thereof.

Specific structures of the group represented by the general formula (d-1) will be shown below.

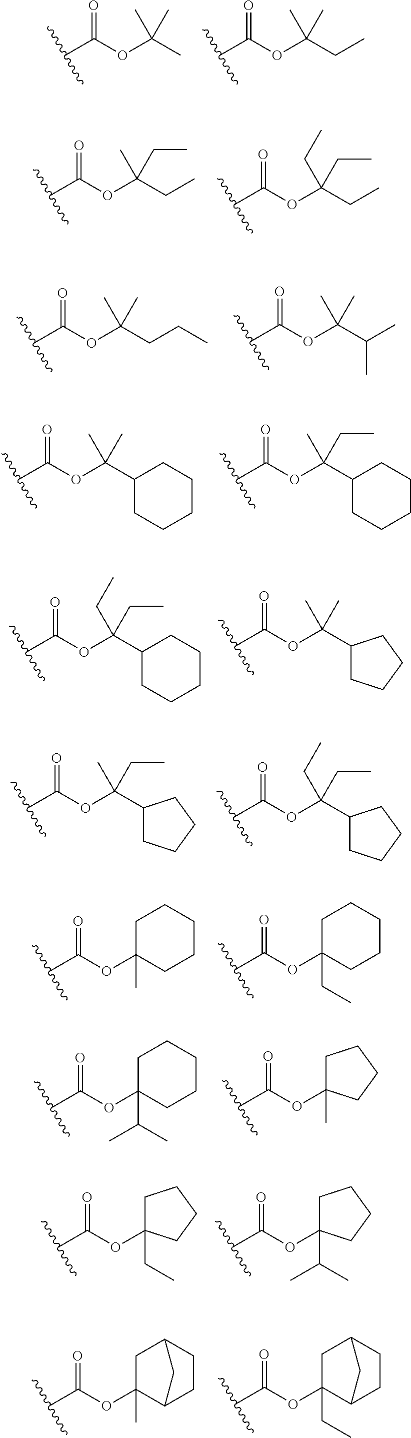

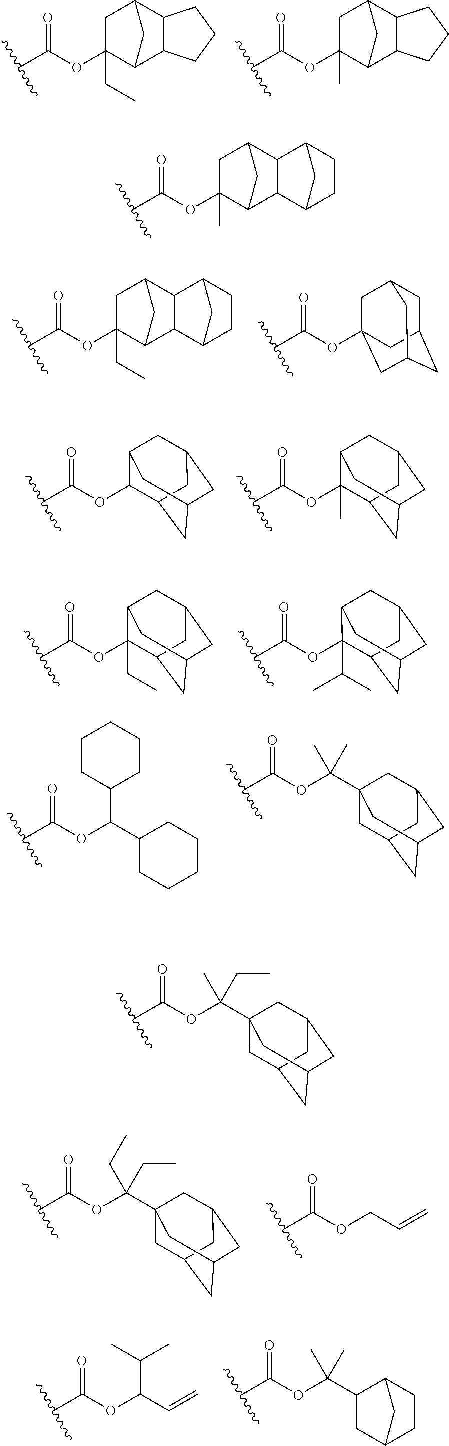

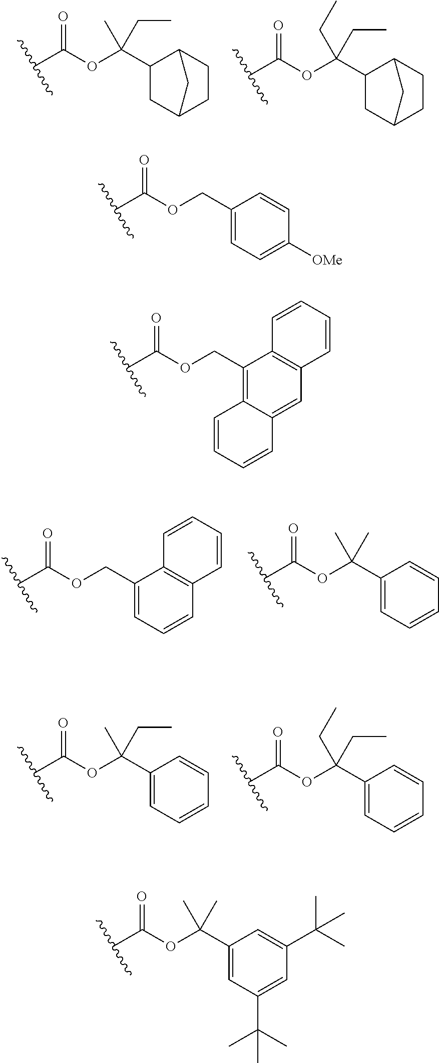

The compound (D) can be formed by any combination of the basic compound and a structure represented by the general formula (d-1).

The compound (D) is particularly preferably one having a structure represented by the following general formula (A).

Further, the compound (D) may correspond to the basic compound as long as it is a low-molecular-weight compound containing group which is cleaved by the action of an acid.

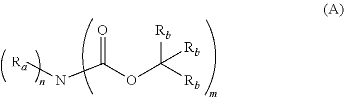

In the general formula (A), Ra represents a hydrogen atom, an alkyl group, a cycloalkyl group, an aryl group, or an aralkyl group. Further, with n=2, two Ra's may be the same as or different from each other, or the two Ra's may be bonded to each other to form a divalent heterocyclic hydrocarbon group (preferably having 20 or less carbon atoms) or a derivative thereof.

Rb has the same meaning as Rb in the general formula (d-1), and preferable examples thereof are also the same. However, in —C(Rb)(Rb)(Rb), when one or more Rb's are hydrogen atoms, at least one of the remaining Rb's is a cyclopropyl group, a 1-alkoxyalkyl group, or an aryl group.

n represents an integer of 0 to 2, and m represents an integer of 1 to 3, with n+m=3.

In the general formula (A), the alkyl group, the cycloalkyl group, the aryl group, or the aralkyl group represented by Ra may be the same substituent as one which substitutes the alkyl group, the cycloalkyl group, the aryl group, or the aralkyl group represented by Rb.

Specific examples of the alkyl group, the cycloalkyl group, the aryl group, or the aralkyl group of Ra (the alkyl group, the cycloalkyl group, the aryl group, or the aralkyl group may be substituted with the above-described group) are the same as those described with respect to Rb.

Furthermore, examples of the divalent heterocyclic hydrocarbon group (preferably having 1 to 20 carbon atoms) formed by the mutual bonding of Ra's or a derivative thereof include a group derived from a heterocyclic compound, such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, 1,5,9-triazacyclododecane, and the like; a group as obtained by substituting the above heterocyclic-compound-derived group with at least one or at least one type of linear or branched-alkane-derived group, cycloalkane-derived group, aromatic-compound-derived group, heterocyclic-compound-derived group or functional group, such as a hydroxyl group, a cyano group, an amino group, a pyrrolidino group, a piperidino group, a morpholino group, an oxo group, and the like; etc.

Specific particularly preferable examples of the compound (D) will be shown below, but the present invention is not limited thereto.

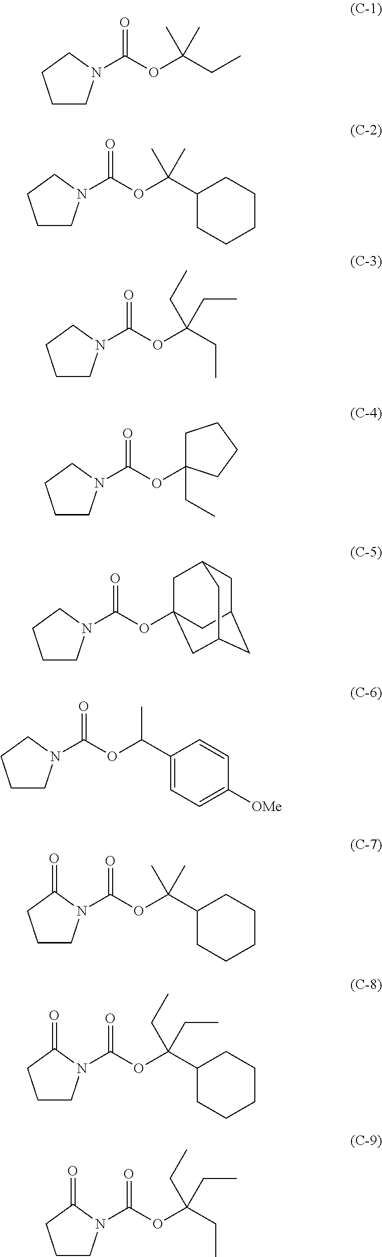

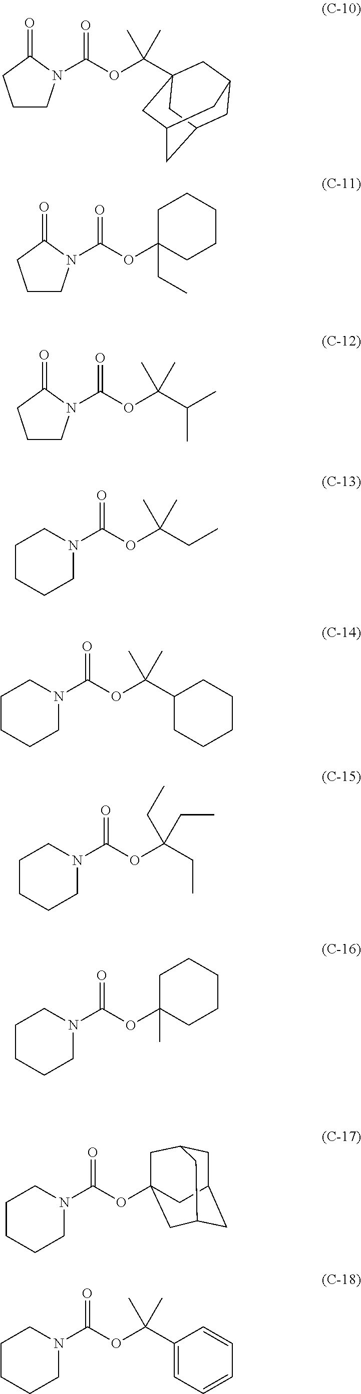

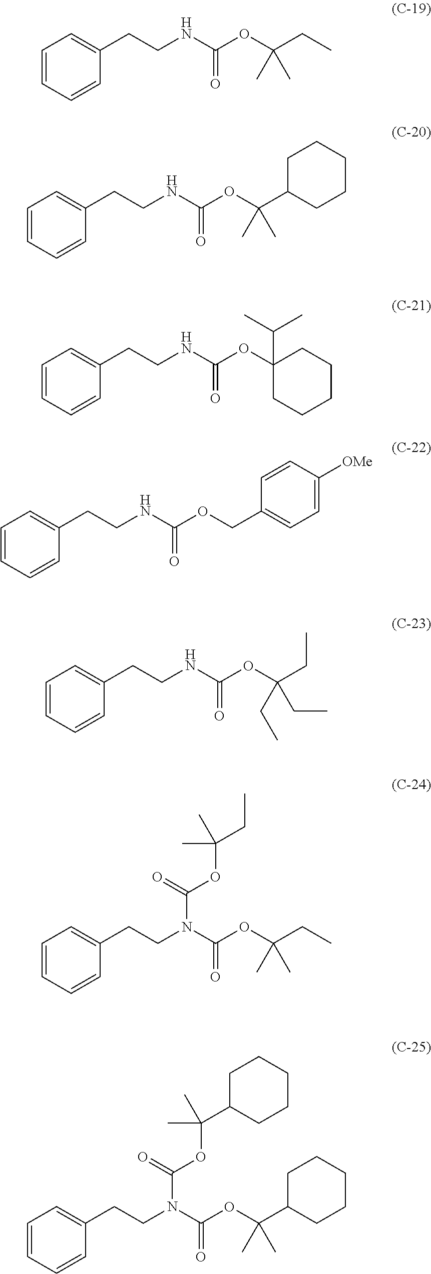

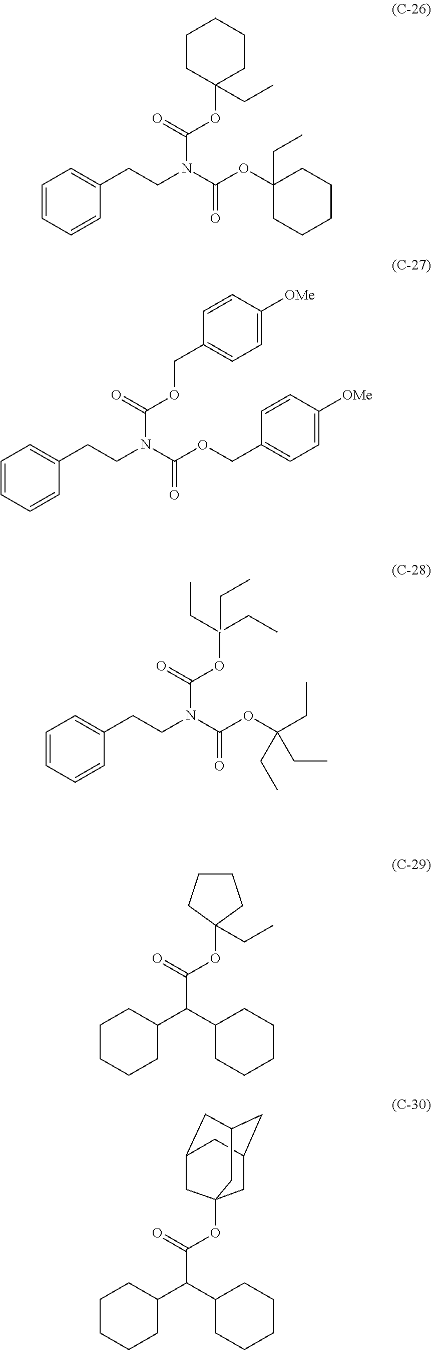

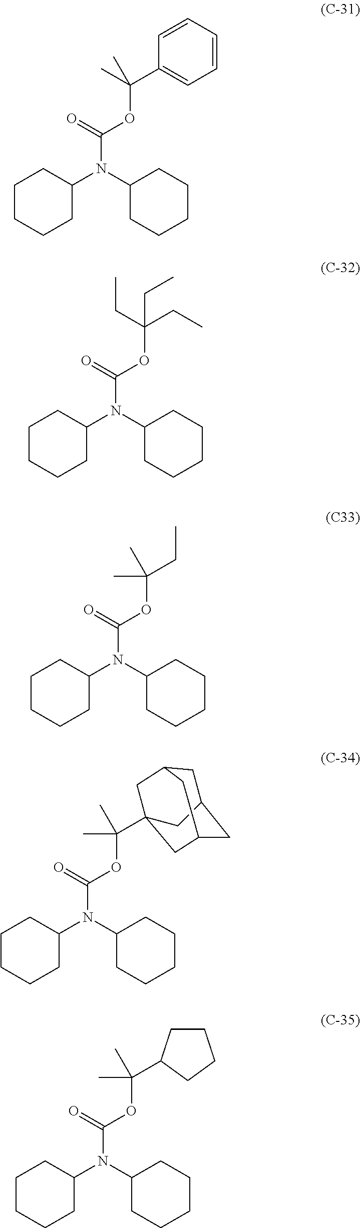

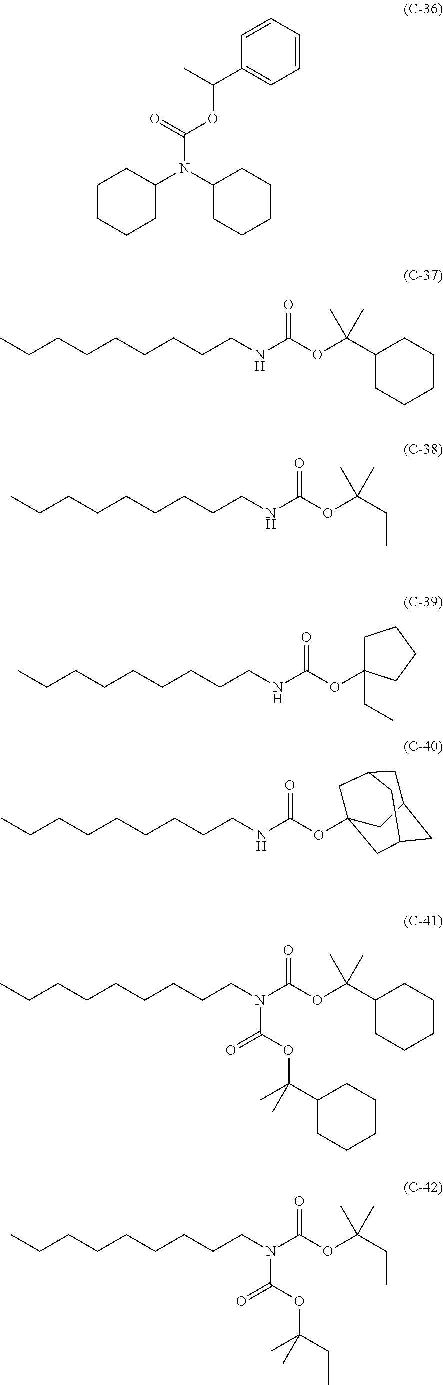

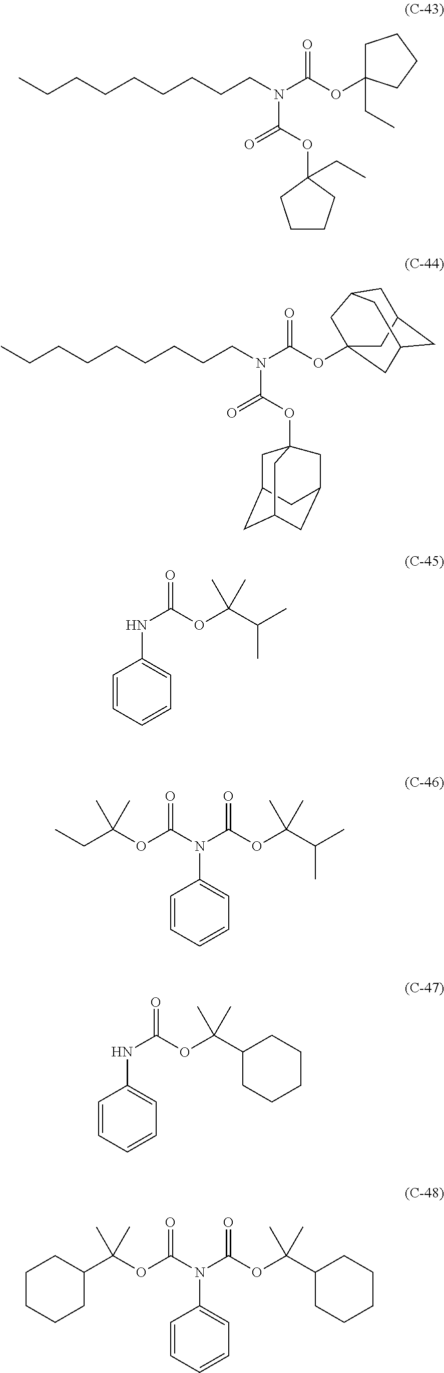

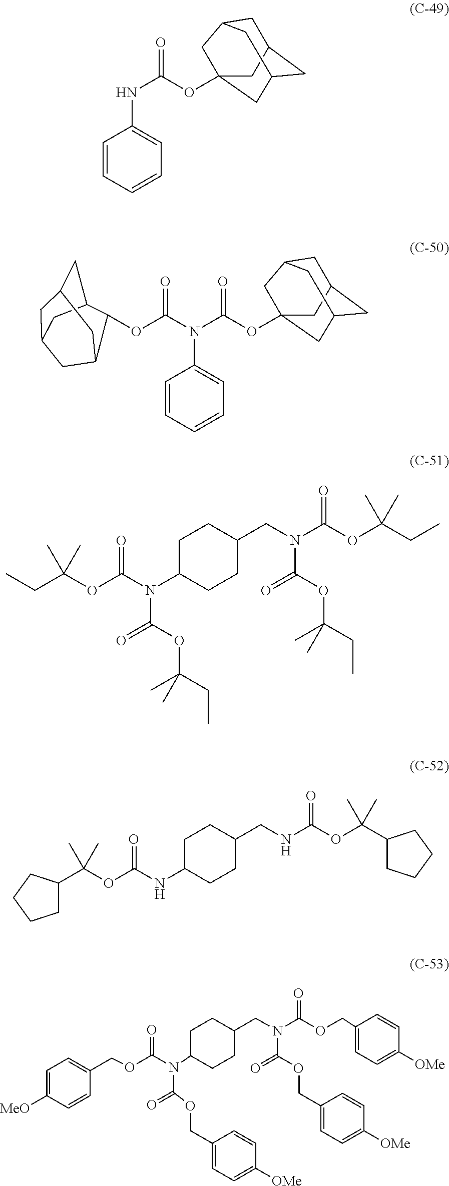

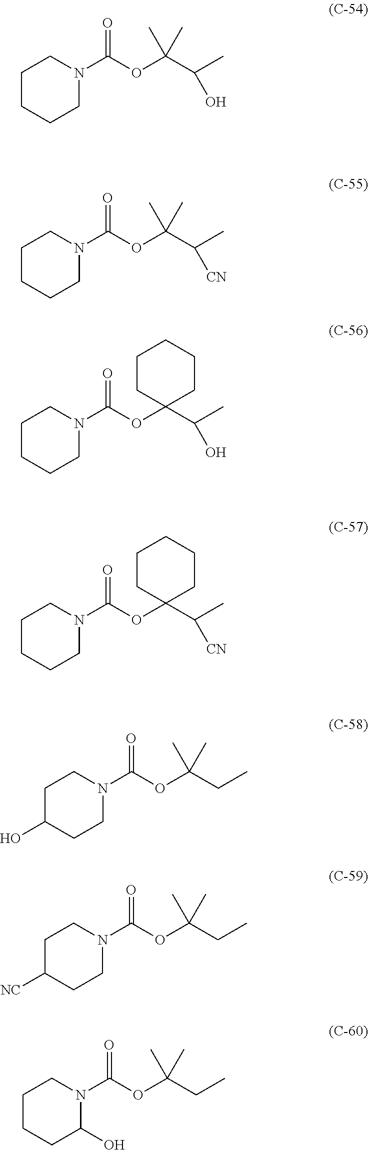

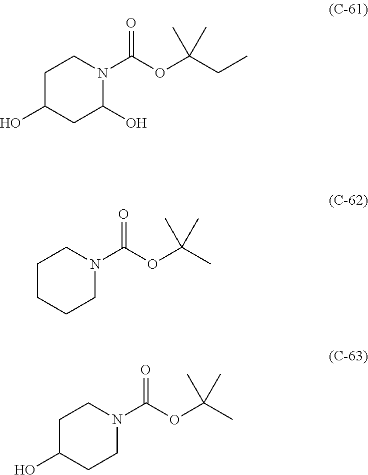

The compound represented by the general formula (A) can be synthesized according to JP2007-298569A, JP2009-199021A, or the like.

In the present invention, the low-molecular-weight compound (D) containing a nitrogen atom and containing a group that is cleaved by the action of an acid may be used singly or used after mixing two or more kinds thereof.

The actinic-ray-sensitive or radiation-sensitive resin composition of the present invention may not include the low-molecular-weight compound (D) containing a nitrogen atom and containing a group that is cleaved by the action of an acid, but if included, the content of the compound (D) is usually from 0.001 to 20% by mass, preferably from 0.001 to 10% by mass, and more preferably from 0.01 to 5% by mass, based on all the solids of the composition combined with the basic compound.

With respect to the ratio of the acid generator to the compound (D) to be used in the resin composition, the acid generator/[compound (D)+the basic compound] (molar ratio) is preferably 2.5 to 300. The reason for this is that the molar ratio is preferred to be 2.5 or more from the viewpoint of sensitivity and resolving power. The molar ratio is preferred to be 300 or less from the viewpoint of the inhibition of any resolving power deterioration due to thickening of resist pattern over time from exposure to heating treatment. The acid generator/[the compound (D)+the basic compound] (molar ratio) is more preferably from 5.0 to 200, and still more preferably from 7.0 to 150.

[6] Solvent

Examples of a solvent which can be used in dissolving the foregoing respective components therein to prepare the actinic-ray-sensitive or radiation-sensitive resin composition include an alkylene glycol monoalkyl ether carboxylate, an alkylene glycol monoalkyl ether, a lactic acid alkyl ether, an alkyl alkoxypropionate, a cyclic lactone (having 4 to 10 carbon atoms), a monoketone compound which may contain a ring (having 4 to 10 carbon atoms), an alkylene carbonate, an alkyl alkoxyacetate, an alkyl pyruvate, and the like.

Preferable examples of the alkylene glycol monoalkyl ether carboxylate include propylene glycol monomethyl ether acetate, propylene glycol monoethyl ether acetate, propylene glycol monopropyl ether acetate, propylene glycol monobutyl ether acetate, propylene glycol monomethyl etherpropionate, propylene glycol monoethyl etherpropionate, ethylene glycol monomethyl ether acetate, and ethylene glycol monoethyl ether acetate.

Preferable examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferable examples of the lactic acid alkyl ester include methyl lactate, ethyl lactate, propyl lactate, and butyl lactate.

Preferable examples of the alkyl alkoxypropionate include ethyl 3-ethoxypropionate, methyl 3-methoxypropionate, methyl 3-ethoxypropionate, and ethyl 3-methoxypropionate.

Preferable examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolatone.

Preferable examples of the ketone compound which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexecen-2-one, 3-penten-2-one, cyclopentanone, 2-methylcyclopentanone, 3-methyl cyclopentanone, 2,2-dimethyl-cyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferable examples of the alkylene carbonate include propylene carbonate, vinylene carbonate, ethylene carbonate, and butylene carbonate.

Preferable examples of the alkyl alkoxyacetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferable examples of the alkyl pyruvate include methyl pyruvate, ethyl pyruvate, and propyl pyruvate.

Examples of the solvent which can be preferably used include solvents having a boiling point of 130° C. or higher at the ordinary temperature under an atmospheric pressure. Specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate, and propylene carbonate.

In the present invention, these solvents may be used singly or in combination of two or more kinds thereof.

In the present invention, a mixed solvent of a solvent containing a hydroxyl group in a structure thereof and a hydroxyl group-free solvent may be used as the organic solvent.

Examples of the hydroxyl group-containing solvent include ethylene glycol, ethylene glycol monomethyl ether, ethylene glycol monoethyl ether, propylene glycol, propylene glycol monomethyl ether, propylene glycol monoethyl ether, ethyl lactate, and the like, with propylene glycol monomethyl ether and ethyl lactate being more preferred. Further, as the hydroxyl group-free solvent, alkylene glycol monoalkyl ether acetate, alkylalkoxypropionate, a monoketone compound which may contain a ring, cyclic lactone, alkyl acetate, and the like are preferred, and among these, propylene glycol monomethyl ether acetate, ethyl ethoxy propionate, 2-heptanone, γ-butyrolactone, cyclohexanone and butyl acetate are particularly preferred, and propylene glycol monomethyl ether acetate, ethylethoxypropionate, and 2-heptanone are most preferred.

A mixing ratio (by weight) of the hydroxyl group-containing solvent to the hydroxyl group-free solvent is from 1/99 to 99/1, preferably from 10/90 to 90/10, and more preferably from 20/80 to 60/40. A mixed solvent containing 50% by weight or more of the hydroxyl group-free solvent is particularly preferable in view of coating uniformity.

The solvent is preferably a mixture of two or more kinds of solvents, including propylene glycol monomethyl ether acetate.

[7] Surfactant

The actinic-ray-sensitive or radiation-sensitive resin composition of the present invention may or may not further contain a surfactant. If the composition contains the surfactant, it is preferable that the composition contain any one, or two or more members, of fluorinated and/or siliconized surfactants (fluorinated surfactant, siliconized surfactant and surfactant containing both fluorine and silicon atoms).

The actinic-ray-sensitive or radiation-sensitive resin composition of the present invention when containing the above surfactant would, in the use of an exposure light source of 250 nm or less, and particularly 220 nm or less, realize favorable sensitivity and resolving power and produce a resist pattern with less adhesion and development defects.

Examples of the fluorinated and/or siliconized surfactant include those described in in the specification of U.S. Patent Application Publication No. 2008/0248425. Any of the following commercially available surfactants can be used as is. Examples of the useful commercially available surfactant include fluorinated surfactants/siliconized surfactants, such as Eftop EF301 and EF303 (available from Shin-Akita Kasei Co., Ltd.), Fluorad FC 430, 431 and 4430 (available from Sumitomo 3M Limited.), Megafac F171, F173, F176, F189, F113, F110, F177, F120, and R08 (available from Dainippon Ink & Chemicals, Inc.), Surflon S-382, SC101, 102, 103, 104, 105, and 106 (available from Asahi Glass Co., Ltd.), Troysol S-366 (available from Troy Chemical Co., Ltd.), GF-300 and GF-150 (available from Toagosei Co., Ltd.), Surflon S-393 (available from Seimi Chemical Co., Ltd.), Eftop EF121, EF122A, EF122B, RF122C, EF125M, EF135M, EF351, EF352, EF801, EF802, and EF601 (available from JEMCO Inc.), PF636, PF656, PF6320, and PF6520 (available from OMNOVA Solutions Inc.), FTX-204G; 208G, 218G, 230G, 204D, 208D, 212D, 218D, and 222D (available from NEOS), and the like. Further, a polysiloxane polymer KP-341 (available from Shin-Etsu Chemical Co., Ltd.) can be employed as the siliconized surfactant.

As the surfactant, besides the publicly known surfactants as shown above, a surfactant based on a polymer having a fluorinated aliphatic group derived from a fluorinated aliphatic compound, produced by a telomerization technique (also called a telomer process) or an oligomerization technique (also called an oligomer process) can be used. The fluorinated aliphatic compound can be synthesized by the method described in JP2002-90991A.

The polymer having a fluorinated aliphatic group is preferably a copolymer from a monomer having a fluorinated aliphatic group and a poly(oxyalkylene)acrylate and/or poly(oxyalkylene)methacrylate, which copolymer may have an irregular distribution or may result from block copolymerization. Examples of the poly(oxyalkylene) group include a poly(oxyethylene) group, a poly(oxypropylene) group, a poly(oxybutylene) group, and the like. Further, a unit having alkylene groups of different chain lengths in a single chain, such as poly(oxyethylene-oxypropyl ene-oxyethylene block concatenation) and poly(oxyethylene-oxypropylene block concatenation) may be used. Moreover, the copolymer from a monomer having a fluorinated aliphatic group and a poly(oxyalkylene) acrylate (or methacrylate) is not limited to two-monomer copolymers and may be a three or more monomer copolymer obtained by simultaneous copolymerization of two or more different monomers having a fluorinated aliphatic group, two or more different poly(oxyalkylene)acrylates (or methacrylates), and the like.

Examples thereof include, as a commercially available surfactant, Megafac F178, F-470, F-473, F-475, F-476, and F-472 (available from Dainippon Ink & Chemicals, Inc.), and further a copolymer from an acrylate (or methacrylate) having a C₆F₁₃ group and a poly(oxyalkylene)acrylate (or methacrylate), a copolymer from an acrylate (or methacrylate) having a C₃F₇ group, poly(oxyethylene)acrylate (or methacrylate) and poly(oxypropylene)acrylate (or methacrylate), and the like.

Furthermore, in the present invention, a surfactant other than the fluorinated and/or siliconized surfactant described in [0280] in the specification of U.S. Patent Application Publication No. 2008/0248425, may also be used.

These surfactants may be used singly or in combination of two or more kinds thereof.

The actinic-ray-sensitive or radiation-sensitive resin composition of the present invention may or may not contain a surfactant, but in the case where the composition contains a surfactant, the content of the surfactant is preferably from 0 to 2% by mass, still more preferably from 0.0001 to 2% by mass, and particularly preferably from 0.0005 to 1% by mass, based on the total solids (total amount excluding the solvent) of the actinic-ray-sensitive or radiation-sensitive resin composition.

On the other hand, it is preferable to set the amount of the surfactant to be added to 10 ppm or less. By this, the hydrophobic resin is more unevenly distributed to the surface, so that the resist film surface can be made more hydrophobic and the traceability of water at the liquid immersion exposure can be enhanced.

[8] Onium Carboxylate

The actinic-ray-sensitive or radiation-sensitive resin composition of the present invention may contain an onium carboxylate. The onium carboxylate is preferably an iodonium salt or a sulfonium salt. The anion moiety is preferably a linear, branched, monocyclic, or polycyclic alkylcarboxylate anion having 1 to 30 carbon atoms, more preferably the carboxylate anion above with the alkyl group being partially or entirely fluorine-substituted. The alkyl chain may contain an oxygen atom. Thanks to such a configuration, the transparency to light at 220 nm or less is ensured, the sensitivity and resolution are enhanced, and the iso/dense bias and exposure margin are improved.

Examples of the fluorine-substituted carboxylate anion include anions of fluoroacetate, difluoroacetate, trifluoroacetate, pentafluoropropionate, heptafluorobutyrate, nonafluoropentanoate, perfluorododecanoate, perfluorotridecanoate, perfluorocyclohexanecarboxylate, 2,2-bistrifluoromethylpropionate, and the like.

The content of the onium carboxylate in the composition is generally from 0.1 to 20% by mass, preferably from 0.5 to 10% by mass, and more preferably from 1 to 7% by mass, based on the total solids of the composition.

[9] Dissolution-Suppressing Compound Having Molecular Weight of 3000 or Less, Which Decomposes by Action of Acid to Increase Solubility in Alkaline Developer

The actinic-ray-sensitive or radiation-sensitive resin composition of the present invention may contain a dissolution-suppressing compound having a molecular weight of 3000 or less, which decomposes by the action of an acid to increase a solubility in an alkaline developer (which is also referred to as a “dissolution-suppressing compound”). Since the dissolution-suppressing compound does not suppress the penetration at 220 nm or less, it is preferably an alicyclic or aliphatic compound containing an acid-decomposable group, such as acid-decomposable group-containing cholic acid derivative described in Proceeding of SPIE, 2724, 355 (1996), so as not to reduce the transmittance at 220 nm or less. Examples of the acid-decomposable group and alicyclic structure are the same as those described above with respect to the resin (A).

In the case where the actinic-ray-sensitive or radiation-sensitive resin composition of the present invention is exposed to KrF excimer laser or irradiated with an electron beam, the dissolution-suppressing compound preferably has a structure where a phenolic hydroxyl group of a phenol compound is substituted with an acid-decomposable group. The phenol compound is preferably a compound containing from 1 to 9 phenol skeleton, and more preferably from 2 to 6 phenol skeleton.

The amount of the dissolution-suppressing compound added is preferably from 3 to 50% by mass, and more preferably from 5 to 40% by mass, based on the total solids of the actinic-ray-sensitive or radiation-sensitive resin composition.

Specific examples of the dissolution-suppressing compound are shown below, but the present invention is not limited thereto.

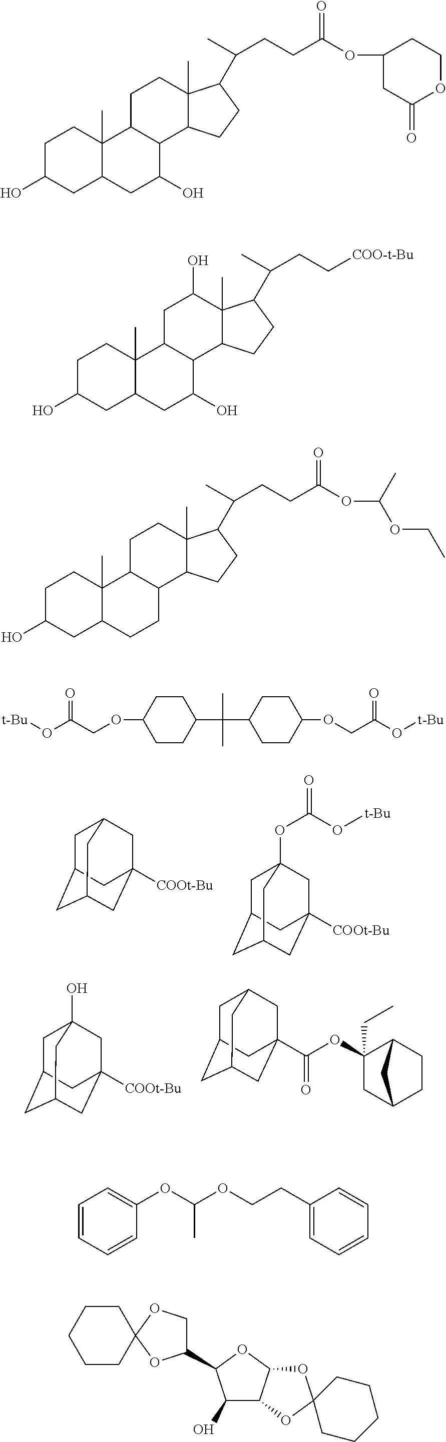

[10] Other Additives

The actinic-ray-sensitive or radiation-sensitive resin composition of the present invention may further contain, for example, a dye, a plasticizer, a photosensitizer, a light absorber, a compound for accelerating dissolution in a developer (for example, a phenol compound having a molecular weight of 1000 or less, or a carboxyl group-containing alicyclic or aliphatic compound), or the like, if desired. Further, it is ensured that the content of the solids in the composition of the present invention (based on the solids) is no more than 100% by mass in total.

The phenol compound having a molecular weight of 1000 or less can be easily synthesized by one skilled in the art by referring to the method described, for example, in JP4-122938A, JP2-28531A, U.S. Pat. No. 4,916,210, European Patent 219294, and the like.

Specific examples of the carboxyl group-containing alicyclic or aliphatic compound include, but are not limited to, a carboxylic acid derivative having a steroid structure, such as cholic acid, deoxycholic acid, lithocholic acid, and the like, an adamantanecarboxylic acid derivative, an adamantanedicarboxylic acid, a cyclohexanecarboxylic acid, a cyclohexanedicarboxylic acid, and the like.

### <Pattern Forming Method>

The pattern forming method of the present invention includes steps of exposing and developing the resist film.

The resist film is formed from the above-described actinic-ray-sensitive or radiation-sensitive resin composition of the present invention, and more specifically, it is preferably formed on a substrate. The pattern forming method of the present invention can be carried out by a generally known method, including forming a film from the resist composition on a substrate, exposing the film, and developing the film.

The actinic-ray-sensitive or radiation-sensitive resin composition of the present invention is preferably used in a film thickness of 30 to 250 nm, and more preferably from 30 to 200 nm, from the viewpoint of enhancing the resolving power. Such a film thickness can be obtained by setting the solid concentration in the actinic-ray-sensitive or radiation-sensitive resin composition to an appropriate range, thereby imparting an appropriate viscosity and enhancing the coatability and the film-forming property.

The total solid concentration in the actinic-ray-sensitive or radiation-sensitive resin composition is generally from 1 to 10% by mass, preferably from 1 to 8.0% by mass, and more preferably from 1.0 to 6.0% by mass.

The actinic-ray-sensitive or radiation-sensitive resin composition of the present invention is used by dissolving the components above in a predetermined organic solvent, preferably in the above-described solvent mixture, filtering the solution, and coating it on a predetermined support as follows. The filter used for filtration is preferably a polytetrafluoroethylene-, polyethylene-, or nylon-made filter having a pore size of 0.1 μm or less, more preferably 0.05 μm or less, and still more preferably 0.03 μm or less. Further, two or more kinds of the filters can be connected serially or in parallel, and then used. Further, the composition may be filtered two or more times. Further, before and after the filtration with a filter, the composition may be subjected to a deaeration treatment, or the like.

For example, the actinic-ray-sensitive or radiation-sensitive resin composition can be applied onto a substrate, such as one for use in the production of integrated circuit elements (for example, silicon/silicon dioxide coating), by appropriate application means, such as a spinner, a coater, and the like, and dried to obtain a resist film.

This resist film is irradiated with an actinic-ray or a radiation through a predetermined mask, preferably baked (heated), developed, and rinsed. Thus, a favorable pattern can be obtained.

After preparing the film and before the exposure step, a prebake process (PB; Prebake) is also preferably included.

In addition, after the exposure step and before the development step, a heating step (PEB; Post Exposure Bake) is also preferably included.

As for the heating temperature, heating of any of PB and PEB is preferably at a temperature of 70 to 120° C., and more preferably at a temperature of 80 to 110° C.

The heat time is preferably 30 to 300 seconds, more preferably 30 to 180 seconds, and still more preferably 30 to 90 seconds.

Heating may be carried out by a unit included in an exposure/development apparatus, and may also be carried out using a hot plate or the like.

By the baking, the reaction of the exposed portion is accelerated and the sensitivity or pattern profile is improved.

Examples of the actinic-ray or the radiation include infrared rays, visible light, ultraviolet rays, far ultraviolet rays, X-rays, an electron beam, and the like. Far ultraviolet rays having a wavelength of preferably 250 nm or shorter, more preferably 220 nm or shorter, and particularly preferably 1 to 200 nm, specifically, for example, a KrF excimer laser (248 nm), an ArF excimer laser (193 nm), an F₂ excimer laser (157 nm), X-rays, EUV (13 nm), an electron beam, and the like are preferred, and an ArF excimer laser, a F₂ excimer laser, EUV (13 nm), and an electron beam are more preferred.

Prior to the formation of a resist film, an antireflection film may also be coated.

As the antireflection film, not only an inorganic film of titanium, titanium oxide, titanium nitride, chromium oxide, carbon, amorphous silicon and the like but also an organic film composed of a light absorber and a polymer substance can be used. Further, as the organic antireflection film, commercially available organic antireflection films, such as the DUV30 Series and DUV40 Series available from Brewer Science Inc., AR-2, AR-3, and AR-5 available from Shipley Co., L.L.C., and the like can also be used.

As the alkaline developer in the development step, a quaternary ammonium salt, typically such as tetramethylammonium hydroxide is used, but an inorganic alkali, a primary amine, a secondary amine, a tertiary amine, an alcoholamine, a cycloamine, and the like can also be used.

In addition, to the above alkaline developer, appropriate amounts of an alcohol and a surfactant may be further added.

The alkali concentration of the alkaline developer is generally from 0.1 to 20% by mass.

The pH value of the alkaline developer is generally from 10.0 to 15.0.

Further, an alcohol or a surfactant can be added to the aqueous basic solution, and the mixture can be used.

Pure water can be used as the rinse liquid, and an appropriate amount of a surfactant may be added thereto and then used.

As the development method, use can be made of, for example, a method in which the substrate is dipped in a tank filled with a developer for a given period of time (dip method), a method in which a developer is mounded on the surface of the substrate by its surface tension and allowed to stand still for a given period of time to thereby effect development (puddle method), a method in which a developer is sprayed onto the surface of the substrate (spray method), a method in which a developer is continuously applied onto the substrate rotating at a given speed while scanning a developer application nozzle at a given speed (dynamic dispense method), or the like.

Furthermore, the developer or rinsing liquid attached on a pattern after the development step or rinsing step can be subjected to a removal treatment by a supercritical fluid.

The film formed using the actinic-ray-sensitive or radiation-sensitive resin composition of the present invention may be subjected to liquid immersion exposure. That is, the interstice between the film and a lens may be filled with a liquid whose refractive index is higher than that of air during irradiation with an actinic-ray or a radiation. This would bring about an enhancement of the resolution.

A liquid for liquid immersion which is used in the liquid immersion exposure will be described below.

As the liquid for liquid immersion, a liquid which is transparent to the exposure wavelength and which has a temperature coefficient of refractive index as small as possible for the purpose of controlling a strain of an optical image to be projected on the actinic-ray-sensitive or radiation-sensitive film in the minimum level is preferred. In particular, when the exposure light source is ArF excimer laser (wavelength: 193 nm), water is preferably used in view of easy availability and easy handling in addition to the foregoing viewpoints.

Moreover, a medium having a refractive index of 1.5 or more may also be used in view of attaining a shorter wavelength. This medium may be either an aqueous solution or an organic solvent.

When water is used as the liquid for liquid immersion, for the purposes of not only reducing a surface tension of water but also increasing a surface-active power, an additive (liquid) which does not dissolve the resist layer on a wafer and whose influences against an optical coat on a lower face of a lens element can be neglected may be added in a little proportion.

As such an additive, an aliphatic alcohol having a refractive index substantially equal to water is preferable. Specific examples thereof include methyl alcohol, ethyl alcohol, isopropyl alcohol, and the like. By adding an alcohol having a refractive index substantially equal to water, even when the alcohol component in water is evaporated, whereby the concentration of the alcohol changes, an advantage such that the change in refractive index as the whole liquid can be made extremely small. On the other hand, when a substance opaque to the 193-nm light or an impurity having a refractive index largely different from water is incorporated, a strain of an optical image to be projected on the actinic-ray-sensitive or radiation-sensitive film is generated. Accordingly, the water to be used is preferably distilled water. Further, pure water obtainable by carrying out filtration of the distilled water through an ion exchanging filter may also be used.

With the water to be used as a liquid for liquid immersion, the electrical resistance is preferably 18.3 MΩcm or more, and the TOC (total organic carbon) is preferably 20 ppb or less. Further, the water has been preferably subjected to a deaeration treatment.

Furthermore, by increasing the refractive index of the liquid for liquid immersion, it is possible to enhance a lithography performance. From such viewpoints, an additive capable of increasing a refractive index may be added to the water, or heavy water (D₂O) may be used in place of the water.

In order that the resist film may not come into direct contact with the liquid for liquid immersion, a layer which is sparingly soluble in the liquid for liquid immersion (hereinafter referred to as “top coat”) may be provided between the resist film (photosensitive layer) according to the positive composition of the invention and the liquid for liquid immersion. Examples of the function necessary as a top coat include coating aptitude for a resist film, transparence against a radioactive ray, especially a radioactive ray at 193 nm, and sparing solubility in the liquid for liquid immersion. It is preferable that the top coat does not mix with the resist film and is able to be uniformly coated on the resist film.

With respect to the top coat, from the viewpoint of transparency against a radioactive ray at 193 nm, an aromatic ring-free polymer is preferable. Examples thereof include a hydrocarbon polymer, an acrylic ester polymer, a polymethacrylic acid, a polyacrylic acid, a polyvinyl ether, a silicon-containing polymer, and a fluorine-containing polymer. The above-described hydrophobic resin is also suitable as a top coat. From the viewpoint that when an impurity elutes from the top coat into the liquid for liquid immersion, it stains an optical lens, it is preferable that the amount of residual monomer components of the polymer contained in the top coat is small.

In stripping the top coat, the developer may be used, or a stripper may be separately used. As the stripper, a solvent having low penetration into the resist film is preferable. In view of the matter that the stripping step can be carried out simultaneously with the developing treatment step of the resist, it is preferable that stripping can be achieved by the alkaline developer. From the viewpoint that stripping is achieved by the alkaline developer, it is preferable that the top coat is acidic. However, from the viewpoint of non-intermixing properties with the resist, the top coat may also be neutral or basic.

The difference in refractive index between the top coat and the liquid for liquid immersion is preferably small or none, which brings about improvement of the resolving power. In the case where the exposure light source is ArF excimer laser (wavelength: 193 nm), water is preferably used as the liquid for liquid immersion. As a result, it is preferable that the top coat for ArF immersion exposure have a refractive index closed to that of water (1.44). In addition, the top coat is preferably a thin layer from the viewpoints of transparency and a refractive index.

Moreover, it is preferable that the top coat does not mix with the resist film and does not mix with the liquid for liquid immersion. Further, from this viewpoint, in the case where the liquid for liquid immersion is water, it is preferable that a solvent of the top coat is a medium which is sparingly soluble in the solvent used in the actinic-ray-sensitive or radiation-sensitive composition and insoluble in water. In addition, when the liquid for liquid immersion is an organic solvent, the top coat may be soluble in water or may be insoluble in water.

As the alkaline developer in the development step, a quaternary ammonium salt, typically such as tetramethylammonium hydroxide is used, but an inorganic alkali, a primary amine, a secondary amine, a tertiary amine, an alcoholamine, a cycloamine, and the like can also be used. To the alkaline developer, appropriate amounts of an alcohol and a surfactant may also be added.

The alkali concentration of the alkaline developer is generally from 0.1 to 20% by mass.

The pH value of the alkaline developer is generally from 10.0 to 15.0.

Pure water can be used as the rinse liquid, and an appropriate amount of a surfactant may be added thereto and then used. Further, the developer or rinsing liquid attached on a pattern after the development treatment or rinsing treatment may also be subjected to a removal treatment by a supercritical fluid.

### EXAMPLES

The present invention will be explained below in more detail by reference to Examples, but the present invention is not limited thereto.

The repeating units in the resin (A) used in Examples will be shown below.

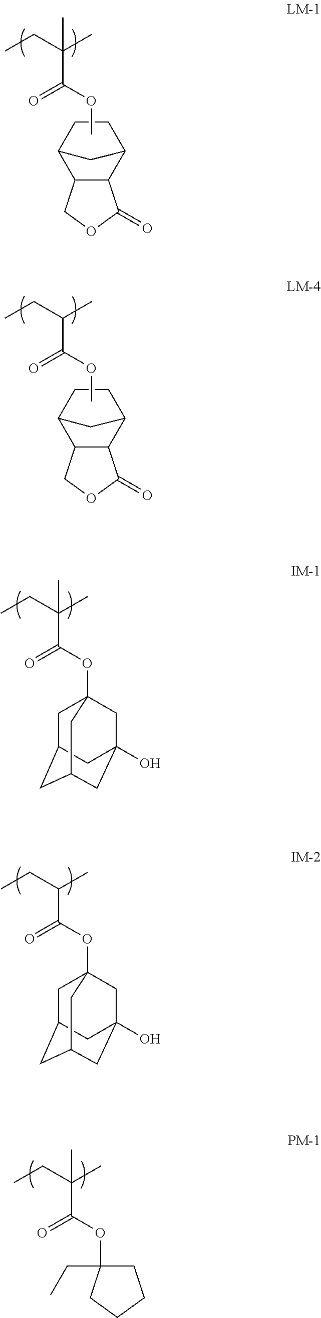

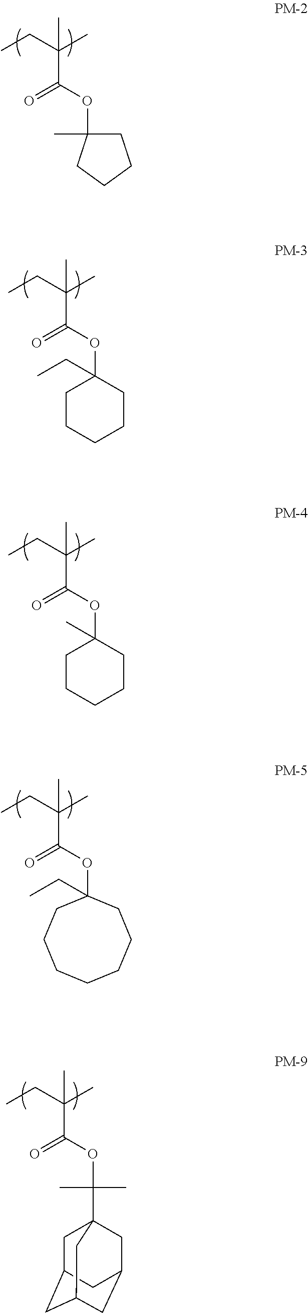

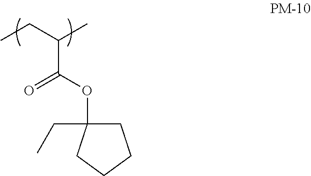

The repeating units in the resin used in Comparative Examples will be shown below.

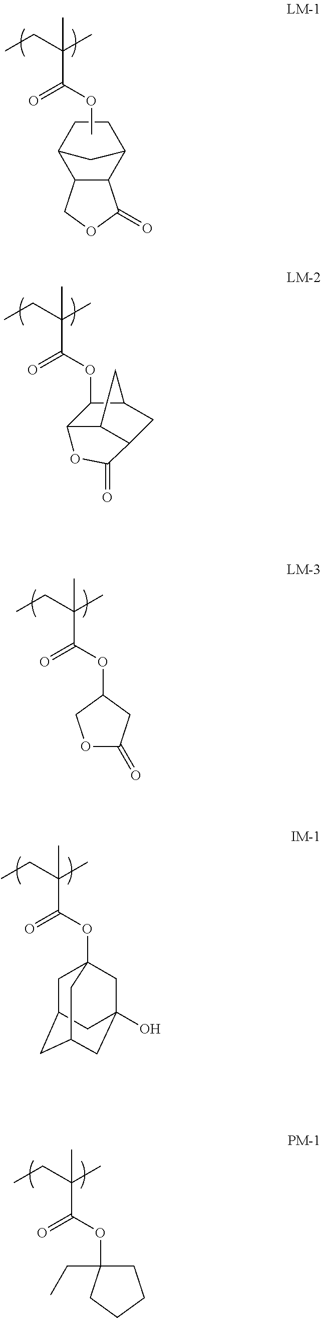

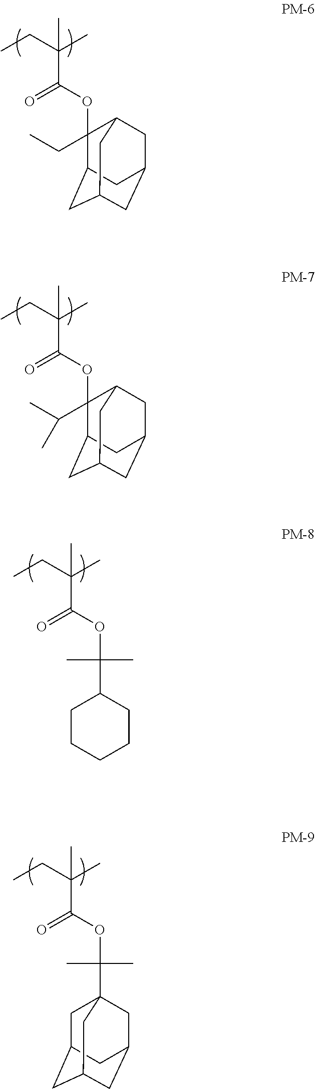

### Synthesis Example 1

### Synthesis of Resin (A)

### Synthesis of Resin (A-1)

Under a nitrogen air flow, 40 g of cyclohexanone was put into a three-neck flask, and heated at 80° C. (Solvent 1). The monomers corresponding to the respective repeating units were dissolved in cyclohexanone at a molar ratio of 40/10/50 to prepare a solution of 22% by mass of the monomer (400 g). Further, 7.2 mol % of a polymerization initiator (V-601, available from Wako Pure Chemical Industries, Ltd.) based on the monomer was added thereto and dissolved. The prepared solution was added dropwise to the Solvent 1 over 6 hours. After addition dropwise, the obtained solution was further subjected to a reaction at 80° C. for 2 hours. The obtained reaction liquid was left to be cooled, and then poured into 3600 ml of heptane/400 ml of ethyl acetate. The precipitated solid (powder) was collected by filtration, and dried to obtain 74 g of a resin (A-1). The polymer compositional ratio determined by NMR was 40/10/50 (molar ratio). Further, the weight average molecular weight and the dispersity (Mw/Mn) of the obtained resin (A-1) were 10200 and 1.53, respectively.

The same procedure as in Synthesis Example 1 was carried out to synthesize the resins (A-2) to (A-17) and (AA-1) to (AA-6).

Regarding the resins (A-1) to (A-17) and (AA-1) to (AA-6), the repeating units, the compositional ratios (molar ratios), the weight average molecular weights, and the dispersities are shown in Tables 2 and 3. The compositional ratios sequentially correspond to the respective repeating units from the left side.

TABLE 2

| Synthesis | | | | | Compositional | Molecular | |
|---|---|---|---|---|---|---|---|
| Example | LM | IM | PM | | ratio | weight | Dispersity |
| A-1 | LM-1 | IM-1 | PM-1 | — | 40/10/50 | 10200 | 1.53 |
| A-2 | LM-1 | IM-1 | PM-1 | PM-3 | 40/10/35/15 | 9500 | 1.54 |
| A-3 | LM-1 | IM-1 | PM-2 | — | 40/10/50 | 8400 | 1.52 |
| A-4 | LM-1 | IM-1 | PM-3 | — | 40/10/50 | 10000 | 1.49 |
| A-5 | LM-1 | IM-1 | PM-4 | — | 40/10/50 | 9200 | 1.56 |
| A-6 | LM-1 | IM-1 | PM-5 | — | 40/10/50 | 10500 | 1.51 |
| A-7 | LM-1 | IM-1 | PM-1 | — | 50/10/40 | 9300 | 1.53 |
| A-8 | LM-1 | IM-1 | PM-1 | — | 30/10/60 | 8700 | 1.60 |
| A-9 | LM-1 | IM-1 | PM-1 | — | 55/5/40 | 10300 | 1.52 |
| A-10 | LM-1 | IM-1 | PM-5 | — | 50/10/40 | 9200 | 1.55 |
| A-11 | LM-1 | IM-1 | PM-1 | PM-3 | 40/10/25/25 | 9000 | 1.53 |
| A-12 | LM-1 | — | PM-1 | — | 40/60 | 9700 | 1.56 |
| A-13 | LM-1 | — | PM-2 | — | 40/60 | 10100 | 1.57 |
| A-14 | LM-1 | — | PM-1 | PM-3 | 50/25/25 | 9400 | 1.54 |
| A-15 | LM-1 | — | PM-1 | PM-5 | 40/40/20 | 9600 | 1.53 |
| A-16 | LM-1 | IM-1 | PM-1 | PM-9 | 40/10/35/15 | 9700 | 1.53 |
| A-17 | LM-4 | IM-2 | PM-10 | — | 40/10/50 | 9900 | 1.54 |

TABLE 3

| | | | | | Composi- | | |
|---|---|---|---|---|---|---|---|
| Synthesis | | | | | tional | Molecular | Disper- |
| Example | NM | IM | PM | | ratio | weight | sity |
| AA-1 | LM-2 | IM-1 | PM-1 | — | 40/10/50 | 8900 | 1.57 |
| AA-2 | LM-3 | IM-1 | PM-1 | | 40/10/50 | 9200 | 1.56 |
| AA-3 | LM-1 | IM-1 | PM-6 | — | 40/10/50 | 9500 | 1.52 |
| AA-4 | LM-1 | IM-1 | PM-7 | — | 40/10/50 | 8800 | 1.54 |
| AA-5 | LM-1 | IM-1 | PM-8 | — | 40/10/50 | 9300 | 1.56 |
| AA-6 | LM-1 | IM-1 | PM-9 | — | 40/10/50 | 9000 | 1.54 |

### Synthesis Example 2

### Synthesis of Hydrophobic Resin r1

The monomers corresponding to the following repeating units were dissolved in propylene glycol monomethyl ether acetate (PGMEA) each at a ratio of 50/50 (molar ratio) to prepare 450 g of a solution having a solid concentration of 15% by mass. To this solution was added 1 mol % of a polymerization initiator (V-60, available from Wako Pure Chemical Industries, Ltd.) and added dropwise to 50 g of PGMEA that had been heated at 100° C. over 6 hours under nitrogen atmosphere. After dropwise addition, the reaction liquid was stirred for 2 hours. After completion of the reaction, the reaction liquid was cooled to room temperature, and crystallized with 5 L of methanol. The precipitated white powder was collected by filtration to recover a hydrophobic resin r1 as a desired product.

The polymer compositional ratio determined by NMR was 50/50. Further, the weight average molecular weight and the dispersity were 4000 and 1.4, respectively, as measured by GPC in terms of a polystyrene standard.

In the same manner as in Synthesis Example 2 except that the monomers corresponding to the respective repeating units were used at the predetermined compositional ratios (molar ratios), hydrophobic resins r2 to r8 were synthesized.

The structures of the hydrophobic resins r1 to r8 are shown below. Further, the compositional ratios (molar ratios), the weight average molecular weights, and the dispersities of the hydrophobic resins r1 to r8 are shown in Table 4.

TABLE 4

| | Compositional ratio | | |
|---|---|---|---|
| Resin | (molar ratio) | Mw | Dispersity |
| r1 | 50/50 | 4000 | 1.4 |
| r2 | 50/50 | 5500 | 1.6 |
| r3 | 50/50 | 6500 | 1.6 |
| r4 | 90/8/2 | 13000 | 1.5 |
| r5 | 39/57/2/2 | 4200 | 1.4 |
| r6 | 40/40/15/5 | 4800 | 1.5 |
| r7 | 20/80 | 6000 | 1.4 |
| r8 | 50/50 | 5200 | 1.5 |

r1 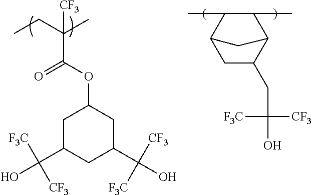
r2 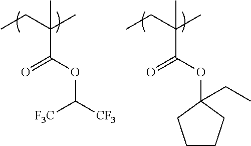
r3 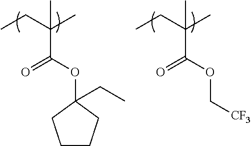
r4 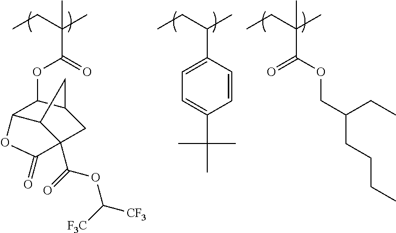
r5 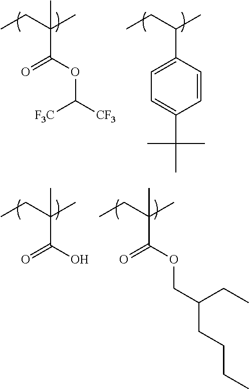
r6 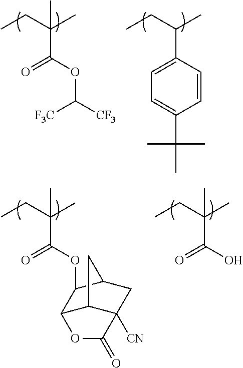
r7 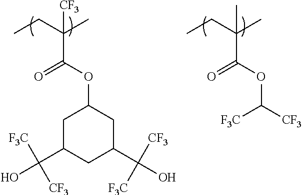
r8

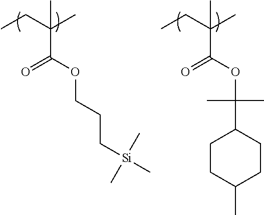

### Synthesis Example 3

### Synthesis of Compound (b39)

In accordance with [0316] of JP2004-139014A, as the compound represented by the general formula (ZI-3), the compound (b39) described above was synthesized.

Similarly, as the compound represented by the general formula (ZI-3), the compounds (b11), (b13), (b21), (b31), (b36) to (b39), (b41), (b43), and (b45) to (b50) described above, and the acid generators (J1), (J3), (J7), and (J8) represented by the following formulae were synthesized.

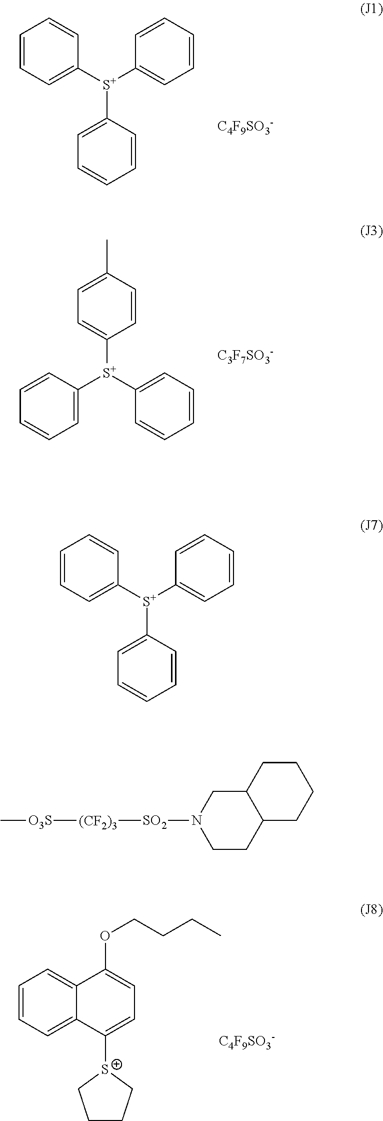

The abbreviations in Tables 5 and 6 are as follows.

The compounds (b11), (b13), (b21), (b31), (b36) to (b39), (b41), (b43), (b45) to (b50), (J1), (J3), (J7), and (J8) are as shown above.

N-1: 2,6-Diisopropylaniline
N-2: Tetrabutylammoniumhydroxide
N-3: Tris(methoxyethoxyethyl)amine
N-4: N-Phenyldiethanolamine
N-5: Trioctylamine
N-6: 2-Phenylbenzoimidazole
N-7: N,N-Dihexylaniline
N-8: Triethanolamine
N-9: N,N-Dibutylaniline
C-13 and C-58 are as shown above.

AD-1 to AD-3: Each of them represents the following compound.

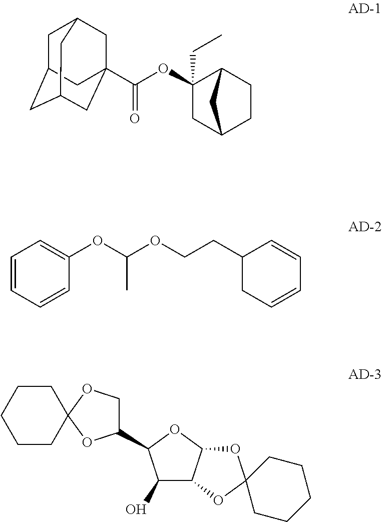

W-1: PolyFox™ PF-6320 (available from OMNOVA Solutions Inc.) (fluorinated)
W-2: Troysol S-336 (available from Troy Chemical Co., Ltd.)
W-3: Polysiloxane polymer KP-341 (available from Shin-Etsu Chemical Co., Ltd) (siliconized)

SL-1: Propylene glycol monomethyl ether acetate (PGMEA)
SL-2: Cyclohexanone
SL-3: Propylene glycol monomethyl ether (PGME)
SL-4: γ-Butyrolactone
SL-5: Propylene carbonate

[Preparation of Actinic-Ray-Sensitive or Radiation-Sensitive Resin Composition]

The components shown in Tables 5 and 6 below were dissolved in a solvent to prepare each of the resist solutions, and the solutions were filtered through a polyethylene filter having a pore size of 0.03 μm to prepare an actinic-ray-sensitive or radiation-sensitive resin composition. The prepared actinic-ray-sensitive or radiation-sensitive resin composition was evaluated by the following method, and the results are shown in the Table.

[Image Performance Test]

ARC29SR for forming an organic antireflection film (available from Nissan Chemical Industries, Ltd.) was coated on a silicon wafer and baked at 205° C. for 60 seconds to form an antireflection film having a film thickness of 86 nm. The actinic-ray-sensitive or radiation-sensitive resin composition prepared above was coated thereon and baked at 100° C. for 60 seconds to form a resist film having a film thickness of 90 nm. The obtained wafer was subjected to exposure through a 6% halftone mask with a line width of 48 nm and a pattern of line:space=1:1, using an ArF excimer laser liquid immersion scanner (available from ASML, XT1700i, NA1.20, C-Quad, outer sigma 0.981, inner sigma 0.895, XY deflection). Ultrapure water was used as the liquid for liquid immersion. Thereafter, the resist film was heated at 105° C. for 60 seconds, then developed with an aqueous tetramethylammonium hydroxide solution (2.38% by mass) for 30 seconds, rinsed with pure water, and then spin-dried to obtain a resist pattern.

The compositions of Examples 1 to 29 and Comparative Examples 1 to 8 shown in Table 5 were subjected to patterning by liquid immersion exposure as described above and evaluated, and the results are shown in Table 5.

Further, in the column of “Addition Configuration” in Table 5, the addition configuration of the hydrophobic resin is described as “Added” or “TC”. In the examples in which “Added” is described, the hydrophobic resin is included in the resist solution. In the examples in which “TC” is described, a resist film is formed using a resist solution including no hydrophobic resin, and then a top coat (TC) protective film including a hydrophobic resin is formed on the upper layer.

In the case where the addition configuration of the hydrophobic resin is “TC”, after the resist film was formed, the following procedure was carried out. In addition, the solvents mentioned in the column of the “Solvent in the case of TC” are as follows.

SL-6: 2-Ethylbutanol
SL-7: Perfluorobutyltetrahydrofuran

<Method for Forming Top Coat>

The hydrophobic resin was dissolved in a solvent, and the obtained solution was coated on the resist film using a spin coater. Thereafter, this was heated and dried at 115° C. for 60 seconds to form a top coat layer having a film thickness of 0.05 μm. After forming the top coat layer, the coating deviation of the top coat layer was observed, and it was thus confirmed that the top coat layer was coated uniformly.

Furthermore, regarding the compositions of Examples 30 to 33 and Comparative Examples 9 and 10 show in Table 6, evaluation was carried out in the same manner as for patterning by liquid immersion exposure above except that a liquid for liquid immersion was not used and a 1:1 line-and-space pattern having a line width of 75 nm was formed by dry exposure (ArF excimer laser scanner, NA 0.75). The results are shown in Table 6.

[Method for Evaluating Critical Dimension Uniformity (CDU) in Line Width]

At an exposure amount when the line width with a 1:1 line-and-space pattern was 48 nm in the liquid immersion exposure and 75 nm in the dry exposure respectively, 100 values of line width (CD) amount the respective line patterns were measured, and a value of three times (3σ) of the standard deviation (σ) of an average value calculated from the measured results were determined to evaluate the critical dimension uniformity (CDU) of the CD. The results in the case of the liquid immersion exposure and the results in the case of the dry exposure are shown in Tables 5 and 6, respectively. For the 3σ determined as above, a smaller value of the 3σ indicates a higher critical dimension uniformity (CDU) of each line CD formed in the resist film.

TABLE 5

| | Composition | | | | | | | | | |
|---|---|---|---|---|---|---|---|---|---|---|
| | | Acid | Basic | | Surfac- | | | | | |
| | | generator | compound or | Additive | tant | Hydrophobic | Addition | | | |
| | Resin A | (parts | compound | (parts | (parts | resin | configu- | | | |
| | (parts | by | (D) (parts by | by | by | (parts by | ration | Solvent in | Solvent (parts | Test results |
| | by mass) | mass) | mass) | mass) | mass) | mass) | (Added/TC) | case of TC | by mass) | CDU (nm) |
| Ex. 1 | A-1 | b38 | N-1 | | W-1 | r1 | Added | | SL-1/SL-3 | 5.3 |
| | (90.48) | (7.1) | (0.42) | | (0.50) | (1.0) | | | (1140/760) | |
| Ex. 2 | A-2 | b39 | N-6 | | W-1 | r1 | TC | SL-6 | SL-1/SL-3 | 5.5 |
| | (76.78) | (20.6) | (1.12) | | (0.50) | (1.0) | | | (1140/760) | |
| Ex. 3 | A-10 | b41 | N-2 | | W-2 | r2 | Added | | SL-1 (1900) | 5.2 |
| | (83.30) | (14.4) | (0.80) | | (0.50) | (1.0) | | | | |
| Ex. 4 | A-14 | b36 | N-2 | AD-1 | W-3 | r3 | Added | | SL-1/SL-2/SL-3 | 5.1 |
| | (80.19) | (16.7) | (1.11) | (0.5) | (0.50) | (1.0) | | | (1641/244/15) | |
| Ex. 5 | A-1 | b49 | N-5 | AD-1 | W-1 | r4 | Added | | SL-1/SL-3/SL-4 | 5.3 |
| | (74.74) | (20.2) | (1.06) | (0.5) | (0.50) | (3.0) | | | (1438/442/20) | |
| Ex. 6 | A-4 | b45 | N-9 | | W-3 | r3 | Added | | SL-1 (1900) | 5.2 |
| | (83.05) | (14.5) | (0.95) | | (0.50) | (1.0) | | | | |
| Ex. 7 | A-3 | b46 | N-1 | AD-2 | W-1 | r5 | Added | | SL-1/SL-2/SL-5 | 5.6 |
| | (78.05) | (18.0) | (1.45) | (0.7) | (0.50) | (1.0) | | | (1354/531/15) | |
| Ex. 8 | A-1 | b47 | N-2 | | W-1 | r2 | Added | | SL-1/SL-3 | 5.4 |
| | (82.51) | (15.0) | (0.99) | | (0.50) | (1.0) | | | (1140/760) | |
| Ex. 9 | A-7 | b49 | N-8 | AD-2 | W-2 | r6 | Added | | SL-1/SL-3 | 5.1 |
| | (75.26) | (21.1) | (1.44) | (0.7) | (0.50) | (1.0) | | | (1140/760) | |
| Ex. 10 | A-8 | b48 | N-7 | | W-3 | r1 | Added | | SL-1/SL-3 | 5.3 |
| | (83.75) | (14.0) | (0.75) | | (0.50) | (1.0) | | | (1140/760) | |
| Ex. 11 | A-3 | b49 | N-2 | | W-1 | r5 | Added | | SL-1/SL-3 | 5.4 |
| | (82.14) | (15.8) | (0.56) | | (0.50) | (1.0) | | | (1140/760) | |
| Ex. 12 | A-2 | b50 | N-4 | AD-1 | W-1 | r5 | TC | SL-7 | SL-1/SL-3 | 5.6 |
| | (77.99) | (19.1) | (0.91) | (0.5) | (0.50) | (1.0) | | | (1140/760) | |
| Ex. 13 | A-6 | b38/J7 | N-4 | | W-2 | r4 | Added | | SL-1 (1900) | 5.2 |
| | (82.89) | (7.0/6.1) | (0.51) | | (0.50) | (3.0) | | | | |
| Ex. 14 | A-1 | b49 | N-3 | | W-3 | r1 | Added | | SL-1/SL-2/SL-3 | 5.3 |
| | (82.05) | (15.5) | (0.95) | | (0.50) | (1.0) | | | (1641/244/15) | |
| Ex. 15 | A-11 | b46 | N-5 | AD-1 | W-1 | r5 | Added | | SL-1/SL-3/SL-4 | 5.5 |
| | (78.49) | (18.3) | (1.21) | (0.5) | (0.50) | (1.0) | | | (1438/442/20) | |
| Ex. 16 | A-12 | b39/J1 | N-3 | AD-1 | W-1 | r7 | Added | | SL-1/SL-3 | 5.4 |
| | (80.64) | (10.0/6.4) | (0.96) | (0.5) | (0.50) | (1.0) | | | (1140/760) | |
| Ex. 17 | A-1 | b45 | N-9 | | W-1 | r4/r5 | Added | | SL-1/SL-3 | 5.3 |
| | (77.42) | (18.6) | (1.18) | | (0.50) | (2.0/0.3) | | | (1140/760) | |
| Ex. 18 | A-9 | b45 | N-1 | | | r1 | Added | | SL-1 (1900) | 5.2 |
| | (82.75) | (15.2) | (1.05) | | | (1.0) | | | | |
| Ex. 19 | A-3 | b49/J7 | N-4 | | W-1 | r5 | Added | | SL-1/SL-3 | 5.4 |
| | (75.00) | (18.0/3.9) | (1.60) | | (0.50) | (1.0) | | | (1140/760) | |
| Ex. 20 | A-1 | b50 | N-1 | | | r5 | Added | | SL-1/SL-3 | 5.5 |
| | (81.85) | (16.2) | (0.95) | | | (1.0) | | | (1140/760) | |
| Ex. 21 | A-2 | b41 | N-8 | | W-1 | r1 | TC | SL-6 | SL-1/SL-3 | 5.6 |
| | (87.60) | (10.2) | (0.70) | | (0.50) | (1.0) | | | (1140/760) | |
| Ex. 22 | A-5 | b47 | N-3 | AD-1 | W-2 | r5 | Added | | SL-1 (1900) | 5.4 |
| | (83.03) | (14.5) | (0.47) | (0.5) | (0.50) | (1.0) | | | | |
| Ex. 23 | A-15 | b36 | C-13 | | W-1 | r4 | Added | | SL-1 (1900) | 5.3 |
| | (71.28) | (24.7) | (0.52) | | (0.50) | (3.0) | | | | |
| Ex. 24 | A-13 | b38 | C-58 | AD-1 | W-1 | r5 | Added | | SL-1 (1900) | 5.2 |
| | (85.38) | (12.3) | (0.32) | (0.5) | (0.50) | (1.0) | | | | |
| Ex. 25 | A-16 | b11/J1 | N-3 | | W-1 | r4/r5 | Added | | SL-1/SL-3 | 5.5 |
| | (75.70) | (12.0/8.5) | (1.00) | | (0.50) | (2.0/0.3) | | | (1140/760) | |
| Ex. 26 | A-1 | b13 | C-13 | AD-1 | | r8 | Added | | SL-1 (1900) | 5.5 |
| | (74.88) | (22.4) | (1.22) | (0.5) | | (1.0) | | | | |
| Ex. 27 | A-17 | b21 | N-1 | | W-1 | r4 | Added | | SL-1/SL-3 | 5.6 |
| | (78.71) | (16.9) | (0.89) | | (0.50) | (3.0) | | | (1140/760) | |
| Ex. 28 | A-1/A-3 | b45 | N-4 | AD-1 | W-1 | r5 | Added | | SL-1 (1900) | 5.3 |
| | (35.15/35.15) | (26.2) | (1.50) | (0.5) | (0.50) | (1.0) | | | | |
| Ex. 29 | A-1/AA-1 | b49 | N-2 | | | r1 | Added | | SL-1/SL-3 | 5.4 |
| | (38.90/38.90) | (20.1) | (1.11) | | | (1.0) | | | (1140/760) | |
| Comp. | AA-1 | b31 | N-9 | | W-1 | r1 | TC | SL-7 | SL-1/SL-3 | 6.5 |
| Ex. 1 | (92.28) | (6.1) | (0.12) | | (0.50) | (1.0) | | | (1140/760) | |
| Comp. | AA-2 | b36 | N-5 | AD-1 | W-1 | r4 | Added | | SL-1/SL-3 | 6.5 |
| Ex. 2 | (87.78) | (7.9) | (0.32) | (0.5) | (0.50) | (3.0) | | | (1140/760) | |
| Comp. | AA-3 | b37 | N-3 | | W-1 | r3 | Added | | SL-1/SL-3 | 6.4 |
| Ex. 3 | (89.11) | (9.1) | (0.29) | | (0.50) | (1.0) | | | (1140/760) | |
| Comp. | AA-4 | b38 | N-2 | AD-1 | W-1 | r1 | Added | | SL-1/SL-3 | 6.4 |
| Ex. 4 | (85.69) | (11.1) | (1.21) | (0.5) | (0.50) | (1.0) | | | (1140/760) | |
| Comp. | AA-5 | b39 | N-1 | AD-1 | W-3 | r1 | Added | | SL-1/SL-3 | 6.3 |
| Ex. 5 | (87.20) | (10.0) | (0.8) | (0.5) | (0.50) | (1.0) | | | (1140/760) | |
| Comp. | AA-6 | b47 | C-58 | | W-1 | r4 | Added | | SL-1/SL-3 | 6.1 |
| Ex. 6 | (79.96) | (15.5) | (1.04) | | (0.50) | (3.0) | | | (1140/760) | |
| Comp. | A-1 | J8 | N-2 | | W-1 | r1 | Added | | SL-1/SL-3 | 6.2 |
| Ex. 7 | (86.88) | (10.4) | (1.22) | | (0.50) | (1.0) | | | (1140/760) | |
| Comp. | A-1 | J1 | N-1 | | W-3 | r1 | Added | | SL-1/SL-3 | 6.3 |
| Ex. 8 | (92.10) | (6.0) | (0.40) | | (0.50) | (1.0) | | | (1140/760) | |

As clearly shown from Table 5, it can be seen that any of Comparative Examples 1 and 2 in which the resins having no repeating unit represented by the general formula (A-I) were used, Comparative Examples 3 to 6 in which the resins having no repeating unit represented by the general formula (1) were used, and Comparative Examples 7 and 8 in which the acid generators other than the compound represented by the general formula (ZI-3) were used, showed poor results with high CDU.

With this regard, it can be seen that Examples 1 to 29 in which the resins having both of the repeating unit represented by the general formula (A-I) and the repeating unit represented by the general formula (1), and the compound represented by the general formula (ZI-3) were used, showed excellent results with low CDU in the liquid immersion exposure.

TABLE 6

| | Composition | | | | | | |
|---|---|---|---|---|---|---|---|
| | | Acid | Basic | | | | |
| | Resin A | generator | compound or | Additive | Surfactant | | Test |
| | (parts by | (parts by | compound (D) | (parts by | (parts by | Solvent | results |
| | mass) | mass) | (parts by mass) | mass) | mass) | (parts by mass) | CDU (nm) |
| Ex. 30 | A-1 | b49 (8.1) | N-3 (0.43) | | W-1 (0.50) | SL-1/SL-3 | 4.3 |
| | (90.97) | | | | | (1140/760) | |
| Ex. 31 | A-2 | b46 (22.8) | N-5 (1.33) | | | SL-1/SL-3 | 3.8 |
| | (75.87) | | | | | (1140/760) | |
| Ex. 32 | A-5 | b39 (13.4) | N-1 (0.75) | | W-2 (0.50) | SL-1 (1900) | 4.4 |
| | (85.35) | | | | | | |
| Ex. 33 | A-12 | b48 (17.6) | N-9 (1.44) | AD-3 (0.5) | W-3 (0.50) | SL-1/SL-2/SL-3 | 3.9 |
| | (79.96) | | | | | (1641/244/15) | |
| Comp. | AA-6 | b43 (13.6) | N-5 (0.80) | | W-1 (0.50) | SL-1/SL-3 | 5.2 |
| Ex. 9 | (85.10) | | | | | (1140/760) | |
| Comp. | A-4 | J3 (7.4) | N-1 (0.25) | | W-1 (0.50) | SL-1/SL-3 | 5.1 |
| Ex. 10 | (91.85) | | | | | (1140/760) | |

As clearly shown from Table 6, it can be seen that any of Comparative Example 9 in which a resin having no repeating unit represented by the general formula (1) was used and Comparative Example 10 in which an acid generator other than the compound represented by the general formula (ZI-3) was used, showed poor results with high CDU.

With this regard, it can be seen that Examples 30 to 33 in which resins having both of the repeating unit represented by the general formula (A-I) and the repeating unit represented by the general formula (1) and the compound represented by the general formula (ZI-3) were used, showed excellent results in the liquid immersion exposure with low CDU.

What is claimed is:

1. An actinic-ray-sensitive or radiation-sensitive resin composition comprising:
(A) a resin containing a repeating unit represented by the following general formula (A-I) and a repeating unit represented by the following general formula (1), which increases a solubility in an alkaline developer by the action of an acid, and
(B) a compound represented by the following general formula (ZI-3), which generates an acid upon irradiation with an actinic-ray or a radiation. 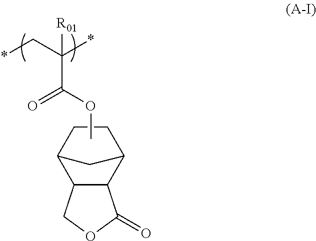
(In the general formula (A-I),
R₀₁ represents a hydrogen atom or an alkyl group) 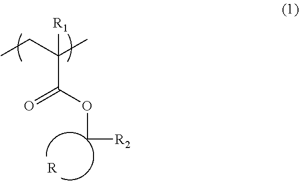
(In the general formula (1),
R₁ represents a hydrogen atom or an alkyl group,
R₂ represents an alkyl group or a cycloalkyl group, and
R represents an atomic group required for forming a monocyclic alicyclic structure in cooperation with a carbon atom) 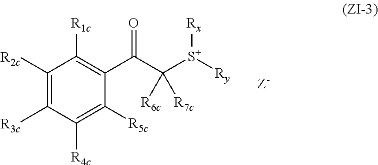
(In the general formula (ZI-3),
each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,
each of R_{6c} and R_{7c} independently represents a hydrogen atom, an alkyl group, a cycloalkyl group, a halogen atom, a cyano group, or an aryl group,
each of Rₓ and R_{y} independently represents an alkyl group, a cycloalkyl group, a 2-oxoalkyl group, a 2-oxocycloalkyl group, an alkoxycarbonylalkyl group, an allyl group or vinyl group,
any two or more of R_{1c} to R_{5c}, R_{5c} and R_{6c}, R_{6c}, and R_{7c}, R_{5c} and Rₓ, and Rₓ and R_{y} may be bonded to each other to form a ring structure, and the ring structure may contain an oxygen atom, a sulfur atom, a ketone group, an ester bond, or an amide bond, and
Z⁻ represents a sulfonate anion).

2. The actinic-ray-sensitive or radiation-sensitive resin composition according to claim 1, further comprising a hydrophobic resin (C).

3. The actinic-ray-sensitive or radiation-sensitive resin composition according to claim 1, further comprising a low-molecular-weight compound (D) containing a nitrogen atom and containing a group which is cleaved by the action of an acid.

4. The actinic-ray-sensitive or radiation-sensitive resin composition according to claim 1, further comprising a compound which generates an acid upon irradiation with an actinic-ray or a radiation, which is different from the compound represented by the general formula (ZI-3).

5. The actinic-ray-sensitive or radiation-sensitive resin composition according to claim 1, wherein the repeating unit represented by the general formula (1) is a repeating unit represented by the following general formula (1-1). 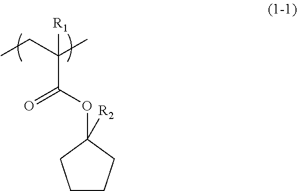
(In the general formula (I-1),
R₁ represents a hydrogen atom or an alkyl group, and
R₂ represents an alkyl group or a cycloalkyl group)

6. The actinic-ray-sensitive or radiation-sensitive resin composition according to claim 1, wherein the resin which increases a solubility in an alkaline developer by the action of an acid further contains a repeating unit having an alicyclic hydrocarbon structure substituted with a hydroxyl group.

7. A resist film formed using the actinic-ray-sensitive or radiation-sensitive resin composition according to claim 1.

8. A pattern forming method comprising:
exposing the resist film according to claim 7, and
developing the exposed resist film.

9. The pattern forming method according to claim 8, wherein the exposure is liquid immersion exposure.

10. The actinic-ray-sensitive or radiation-sensitive resin composition according to claim 2, further comprising a low-molecular-weight compound (D) containing a nitrogen atom and containing a group which is cleaved by the action of an acid.

11. The actinic-ray-sensitive or radiation-sensitive resin composition according to claim 2, further comprising a compound which generates an acid upon irradiation with an actinic-ray or a radiation, which is different from the compound represented by the general formula (ZI-3).

12. The actinic-ray-sensitive or radiation-sensitive resin composition according to claim 3, further comprising a compound which generates an acid upon irradiation with an actinic-ray or a radiation, which is different from the compound represented by the general formula (ZI-3).

13. The actinic-ray-sensitive or radiation-sensitive resin composition according to claim 2, wherein the repeating unit represented by the general formula (1) is a repeating unit represented by the following general formula (1-1). 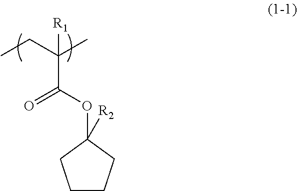
(In the general formula (1-1),
R₁ and R₂ are the same as R₁ and R₂ above)

14. The actinic-ray-sensitive or radiation-sensitive resin composition according to claim 3, wherein the repeating unit represented by the general formula (1) is a repeating unit represented by the following general formula (1-1). 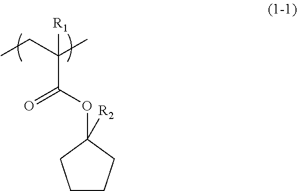
(In the general formula (1-1),
R₁ and R₂ are the same as R₁ and R₂ above)

15. The actinic-ray-sensitive or radiation-sensitive resin composition according to claim 4, wherein the repeating unit represented by the general formula (1) is a repeating unit represented by the following general formula (1-1). 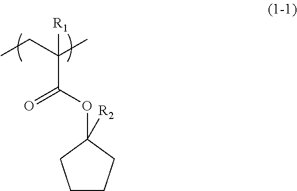
(In the general formula (1-1),
R₁ and R₂ are the same as R₁ and R₂ above)

16. The actinic-ray-sensitive or radiation-sensitive resin composition according to claim 2, wherein the resin which increases a solubility in an alkaline developer by the action of an acid further contains a repeating unit having an alicyclic hydrocarbon structure substituted with a hydroxyl group.

17. The actinic-ray-sensitive or radiation-sensitive resin composition according to claim 3, wherein the resin which increases a solubility in an alkaline developer by the action of an acid further contains a repeating unit having an alicyclic hydrocarbon structure substituted with a hydroxyl group.

18. The actinic-ray-sensitive or radiation-sensitive resin composition according to claim 4, wherein the resin which increases a solubility in an alkaline developer by the action of an acid further contains a repeating unit having an alicyclic hydrocarbon structure substituted with a hydroxyl group.

19. The actinic-ray-sensitive or radiation-sensitive resin composition according to claim 5, wherein the resin which increases a solubility in an alkaline developer by the action of an acid further contains a repeating unit having an alicyclic hydrocarbon structure substituted with a hydroxyl group.
